(19) United States
(12) Patent Application Publication
(10) Pub. No.: US 2025/0338703 A1
(43) Pub. Date: Oct. 30, 2025

(54) VERTICALLY STACKED MICRO-LED PIXELS, METHODS OF MANUFACTURING THE SAME, DISPLAY DEVICE INCLUDING MICRO-LED PIXELS, AND ELECTRONIC APPARATUS INCLUDING MICRO-LED PIXELS AND/OR LED DISPLAY

(71) Applicant: SAMSUNG ELECTRONICS CO., LTD., Suwon-si (KR)

(72) Inventors: Junhee Choi, Suwon-si (KR); Kiho Kong, Suwon-si (KR); Nakhyun Kim, Suwon-si (KR); Sunil Kim, Suwon-si (KR); Joosung Kim, Suwon-si (KR); Junghun Park, Suwon-si (KR); Dongchul Shin, Suwon-si (KR); Eunsung Lee, Suwon-si (KR); Joohun Han, Suwon-si (KR)

(73) Assignee: SAMSUNG ELECTRONICS CO., LTD., Suwon-si (KR)

(21) Appl. No.: 19/170,655

(22) Filed: Apr. 4, 2025

(30) Foreign Application Priority Data
Apr. 24, 2024 (KR) 10-2024-0054987

(51) Int. Cl. H10H 29/80; H10H 29/01; H10H 29/03; H10H 29/49; H10H 29/856

(52) U.S. Cl. CPC H10H 29/962; H10H 29/012; H10H 29/03; H10H 29/0363; H10H 29/0364; H10H 29/49; H10H 29/856

(57) ABSTRACT

Provided is a micro-light emitting diode (micro-LED) pixel including a first micro-LED, a second micro-LED on the first micro-LED, a level of the first micro-LED and a level of the second micro-LED being different from each other in a vertical direction, and a first reflective layer on the first micro-LED opposite to the second micro-LED, the first reflective layer being configured to reflect light incident from at least one of the first micro-LED and the second micro-LED in a direction opposite to the incident direction, wherein on a plane from a top plan view, a size of the first micro-LED and a size of the second micro-LED are different from each other in a horizontal direction, and wherein the first micro-LED and the second micro-LED are aligned in vertical direction corresponding to a main emission direction of light.

### CROSS-REFERENCE TO RELATED APPLICATION

This application claims priority to Korean Patent Application No. 10-2024-0054987, filed on Apr. 24, 2024, in the Korean Intellectual Property Office, the disclosure of which is incorporated by reference herein in its entirety.

### BACKGROUND

### 1. Field

Embodiments of the present disclosure relate to a pixel structure including a micro-LED and use thereof, and more particularly, to vertically stacked micro-LED pixels and manufacturing methods thereof, a display device including micro-LED pixels, and an electronic apparatus including micro-LED pixels and/or a micro-LED display.

### 2. Description of the Related Art

Advances in flat display technology and rising user expectations for displays, have created a broader market for displays that use quantum dot light-emitting diodes (QLEDs) or organic light-emitting diodes (OLEDs).

Recently, LED displays that directly use micro-LEDs as pixels have been introduced and have been commercialized to a limited extent.

The pixels of LED displays may be designed and configured in various ways, and recently, various technologies for vertically stacking a micro-LED (R-LED) that emits red light (R), a micro-LED (G-LED) that emits green light (G) and a micro-LED (B-LED) that emits blue light (B) have been introduced. However, so far, no satisfactory results in terms of efficiency and bonding have been obtained in a vertical stack process of micro-LEDs.

### SUMMARY

One or more embodiments provide a vertically stacked micro-LED pixel with increased light emission efficiency.

One or more embodiments also provide a vertically stacked micro-LED pixel that has a more simplified manufacturing process.

One or more embodiments also provide a vertically stacked micro-LED pixel with increased productivity (mass productivity).

One or more embodiments also provide a method of manufacturing such vertically stacked micro-LEDs.

One or more embodiments also provide a variety of apparatuses including micro-LEDs.

Additional aspects will be set forth in part in the description which follows and, in part, will be apparent from the description, or may be learned by practice of the example embodiments of the disclosure.

According to an aspect of one or more embodiments, there is provided a micro-light emitting diode (micro-LED) pixel including a first micro-LED, a second micro-LED on the first micro-LED, a level of the first micro-LED and a level of the second micro-LED being different from each other in a vertical direction, and a first reflective layer on the first micro-LED opposite to the second micro-LED, the first reflective layer being configured to reflect light incident from at least one of the first micro-LED and the second micro-LED in a direction opposite to the incident direction, wherein on a plane from a top plan view, a size of the first micro-LED and a size of the second micro-LED are different from each other in a horizontal direction, and wherein the first micro-LED and the second micro-LED are aligned in vertical direction corresponding to a main emission direction of light.

The micro-LED pixel may further include a first attachment layer on the first reflective layer opposite to the first micro-LED, a second attachment layer between the first micro-LED and the second micro-LED, a second reflective layer between the second micro-LED and the second attachment layer, the second reflective layer being in contact with a p-type compound semiconductor layer included in the second micro-LED, and a first transparent electrode layer between the second attachment layer and the first micro-LED, the first transparent electrode layer being in contact with an n-type compound semiconductor layer included in the first micro-LED.

At least one of a thickness of the first attachment layer and a thickness of the second attachment layer in the vertical direction may be greater than or equal to one of a thickness of the first micro-LED and a thickness of the second micro-LED or may be greater than the thickness of the thickest layer among the layers included in the first micro-LED and the second micro-LED.

The micro-LED pixel may further include a backplane including transistors corresponding to each of the first micro-LED and the second micro-LED, wherein the backplane further includes electrode pad layers spaced apart from each other and respectively connected to the transistors, wherein the first attachment layer includes through holes through which the electrode pad layers are exposed, wherein the second attachment layer includes a through hole through which the first transparent electrode layer is exposed, wherein the first reflective layer is in contact with the p-type compound semiconductor layer included in the first micro-LED, and wherein the micro-LED pixel further includes a first interconnection electrode layer connecting a portion of the first transparent electrode layer exposed through the second attachment layer, a grounded first electrode pad layer among the electrode pad layers, and an n-type compound semiconductor layer of the second micro-LED, a second interconnection electrode layer connecting a second electrode pad layer, connected to a transistor corresponding to the first micro-LED, among the electrode pad layers to the first reflective layer, and a third interconnection electrode layer connecting a third electrode pad layer, connected to a transistor corresponding to the second micro-LED, among the electrode pad layers to the second reflective layer, wherein the first interconnection electrode layer, the second interconnection electrode layer, and the third interconnection electrode layer are spaced apart from each other, and each of the first interconnection electrode layer, the second interconnection electrode layer, and the third interconnection electrode layers is a single layer and continuous transparent electrode film, and wherein the third interconnection electrode layer is spaced apart from a side surface of the first micro-LED and a side surface of the second micro-LED.

The micro-LED pixel may further include a third micro-LED at a level that is higher position than the level of the second micro-LED in the vertical direction, a third attachment layer between the third micro-LED and the second micro-LED, a third reflective layer between the third micro-LED and the third attachment layer, and a second transparent electrode layer between the third attachment layer and the second micro-LED, wherein a thickness of the third attachment layer is same as the thickness of the first attachment layer or the thickness of the second attachment layer, wherein the micro-LED pixel further includes an interconnection electrode layer configured to connect the first micro-LED and the third micro-LED to a power source among the first micro-LED, the second micro-LED, and the third micro-LEDs, and wherein the interconnection electrode layer is a transparent electrode film that is continuous without disconnection.

A length of the second reflective layer, a length of the second micro-LED, a length of the second transparent electrode layer, a length of the third attachment layer, and a length of the third reflective layer in the horizontal direction may be same, and a geometric shape and an area of the second reflective layer, a geometric shape and an area of the second micro-LED, a geometric shape and an area of the second transparent electrode layer, a geometric shape and an area of the third attachment layer, and a geometric shape and an area of the third reflective layer in the plane may be same.

The micro-LED pixel may further include a third micro-LED at a level that is higher than the level of the second micro-LED in the vertical direction, a size of the third micro-LED being different from the a size of the first micro-LED and a size of the second micro-LED on the plane, a third attachment layer between the third micro-LED and the second micro-LED, a third reflective layer between the third micro-LED and the third attachment layer, the third reflective layer being in contact with the p-type compound semiconductor layer included in the third micro-LED, and a second transparent electrode layer between the third attachment layer and the second micro-LED, wherein the first micro-LED, the second micro-LED, and the third micro-LED are sequentially stacked on a backplane in the vertical direction, wherein, on the plane, a size of the first micro-LED is greater than a size of the second micro-LED, the size of the second micro-LED is greater than a size of the third micro-LED, wherein the first reflective layer is in contact with the p-type compound semiconductor layer included in the first micro-LED, and wherein the micro-LED pixel further includes a first interconnection electrode layer configured to commonly connect n-type compound semiconductor layers of the first micro-LED, the second micro-LED, and the third micro-LED to a first terminal of a power source, a second interconnection electrode layer connecting the first reflective layer to a second terminal of the power source, a third interconnection electrode layer connecting the second reflective layer to the second terminal of the power source, and a fourth interconnection electrode layer connecting the third reflective layer to the second terminal of the power source, wherein each of the first interconnection electrode layer, the second interconnection electrode layer, the third interconnection electrode layer, and the fourth interconnection electrode layer is a single layer and a continuous transparent electrode film.

The micro-LED pixel may further include a first attachment layer at a level lower than a level of the first reflective layer in the vertical direction, a second attachment layer between the first micro-LED and the second micro-LED, a second reflective layer between the second micro-LED and the second attachment layer, the second reflective layer being in contact with the n-type compound semiconductor layer included in the second micro-LED, a first transparent electrode layer between the second attachment layer and the first micro-LED, the first transparent electrode layer being in contact with the p-type compound semiconductor layer included in the first micro-LED, a third micro-LED at a level different from the level of first micro-LED and the level of the second micro-LED in the vertical direction and having a size different from the size of first micro-LED and the size of the second micro-LED on the plane, a third attachment layer between the third micro-LED and the second micro-LED, a third reflective layer between the third micro-LED and the third attachment layer, the third reflective layer being in contact with the n-type compound semiconductor layer included in the third micro-LED, a second transparent electrode layer between the third attachment layer and the second micro-LED, the second transparent electrode layer being in contact with the p-type compound semiconductor layer included in the second micro-LED, a third transparent electrode layer in contact with the p-type compound semiconductor layer included in the third micro-LED, a first interconnection electrode layer commonly connecting n-type compound semiconductor layers of the first micro-LED, the second micro-LED, and the third micro-LED to a first terminal of a power source, a second interconnection electrode layer connecting the p-type compound semiconductor layer included in the first micro-LED to a second terminal of the power source, a third interconnection electrode layer connecting the p-type compound semiconductor layer included in the second micro-LED to the second terminal of the power source, and a fourth interconnection electrode layer connecting the p-type compound semiconductor layer included in the third micro-LED to the second terminal of the power source, wherein the first micro-LED, the second micro-LED, and the third micro-LED are sequentially stacked on a backplane, wherein a size of the first micro-LED is greater than a size of the second micro-LED, the size of the second micro-LED is greater than a size of the third micro-LED, wherein the first reflective layer is in contact with the n-type compound semiconductor layer included in the first micro-LED, and wherein each of the first interconnection electrode layer, the second interconnection electrode layer, the third interconnection electrode layer, and the fourth interconnection electrode layer is a transparent electrode film that is continuous without disconnection.

A horizontal length of the third attachment layer and a horizontal length of the third reflective layer may be equal to each other and may be less than a horizontal length of the second transparent electrode layer, an entire portion of third attachment layer may be on the second transparent electrode layer, and the third attachment layer may be spaced apart from the second micro-LED.

A horizontal length of the second attachment layer and a horizontal length of the second reflective layer may be equal to each other and may be less than a horizontal length of the first transparent electrode layer, an entire portion of second attachment layer may be on the first transparent electrode layer, and the second attachment layer may be spaced apart from the first micro-LED.

The horizontal length of the second attachment layer and the horizontal length of the second reflective layer may be equal to each other and may be greater than the horizontal length of the first transparent electrode layer, and the second attachment layer may contact the first micro-LED.

The horizontal length of the third attachment layer and the horizontal length of the third reflective layer may be equal to each other and may be greater than a horizontal length of the second transparent electrode layer, and the third attachment layer may contact the second micro-LED.

The horizontal length of the second attachment layer and the horizontal length of the second reflective layer may be equal to each other and may be greater than the horizontal length of the first transparent electrode layer, and the second attachment layer may contact the first micro-LED.

According to another aspect of one or more embodiments, there is provided a method of manufacturing a micro-light emitting diode (micro-LED) pixel, the method including forming a first light emitting diode (LED) stack including a first reflective layer on a first substrate, separating the first LED stack from the first substrate, transferring the first LED stack onto a backplane, forming a second LED stack on a second substrate, separating the second LED stack from the second substrate, transferring the separated second LED stack onto the first LED stack, and patterning the transferred first LED stack and the second LED stack into first micro-LED and second micro-LED, respectively, wherein the first LED stack is transferred such that the first reflective layer is between the backplane and the first micro-LED.

The method may further include forming a third LED stack on a third substrate, separating the third LED stack from the third substrate, transferring the separated third LED stack onto the second LED stack, and patterning the first LED stack, the second LED stack, and the third LED stack into the first micro-LED, the second micro-LED, and third micro-LED, respectively.

The method may further include forming a second reflective layer on the second LED stack such that the second reflective layer is between the first micro-LED and the second micro-LED, wherein the first reflective layer may be formed to contact an n-type compound semiconductor layer included in the first micro-LED or a p-type compound semiconductor layer included in the first micro-LED, and wherein the second reflective layer may be formed to contact an n-type compound semiconductor layer included in the second micro-LED or a p-type compound semiconductor layer included in the second micro-LED.

The method may further include forming a second reflective layer on the second LED stack such that the second reflective layer is between the first micro-LED and the second micro-LED, and forming a third reflective layer on the third LED stack such that the third reflective layer is between the second micro-LED and the third micro-LED, wherein the first reflective layer may be formed to contact the n-type compound semiconductor layer included in the first micro-LED or the p-type compound semiconductor layer included in the first micro-LED, wherein the second reflective layer may be formed to contact the n-type compound semiconductor layer included in the second micro-LED or the p-type compound semiconductor layer included in the second micro-LED, and wherein the third reflective layer may be formed to contact an n-type compound semiconductor layer included in the third micro-LED or a p-type compound semiconductor layer included in the third micro-LED.

The method may further include forming an interconnection electrode layer connecting each of the first micro-LED, the second micro-LED, and the third micro-LED and the backplane, wherein the interconnection electrode layer may include a first interconnection electrode layer commonly connecting n-type compound semiconductor layers included in each of the first micro-LED, the second micro-LED, and the third micro-LED to a first electrode pad layer on the backplane, and a plurality of second interconnection electrode layers connecting the p-type compound semiconductor layers included in each of the first micro-LED, the second micro-LED, and the third micro-LED to different electrode pad layers on the backplane, wherein the plurality of second interconnection electrode layers may be spaced apart from each other and spaced apart from the first interconnection electrode layer, and wherein each of the first interconnection electrode layer and the second interconnection electrode layer may be a transparent electrode film that is continuous without disconnection.

The first reflective layer may be in contact with the n-type compound semiconductor layer included in the first micro-LED, the second reflective layer may be in contact with the n-type compound semiconductor layer included in the second micro-LED, and the third reflective layer may be in contact with the n-type compound semiconductor layer included in the third micro-LED, and wherein the method may further include forming a first attachment layer between the first reflective layer and the backplane, forming a first transparent electrode layer and a second attachment layer between the first micro-LED and the second reflective layer, and forming a second transparent electrode layer and a third attachment layer between the second micro-LED and the third reflective layer, wherein the method may further include at least one method among forming the first transparent electrode layer and the second attachment layer sequentially on the first micro-LED or forming both the first transparent electrode layer and the second attachment layer to contact the first micro-LED, and forming the second transparent electrode layer and the third attachment layer sequentially on the second micro-LED or forming both the second transparent electrode layer and the third attachment layer to contact the second micro-LED.

According to still another aspect of one or more embodiments, there is provided an electronic apparatus including an image display device, the image display device including a plurality of pixels respectively that includes a plurality of vertically stacked micro light emitting diodes (micro-LEDs), wherein each micro-LED of the plurality of micro-LEDs includes a first micro-LED, a second micro-LED at a level different from a level of the first micro-LED in a vertical direction, and a first reflective layer at a level lower than the level of the first micro-LED and the level of the second micro-LED in the vertical direction, wherein on a plane from a top plan view, a size of the first micro-LED and a size of the second micro-LED are different from each other, wherein the first micro-LED and the second micro-LED are aligned in the vertical direction corresponding to a main emission direction of light, and wherein the first reflective layer is configured to reflect light incident from at least one of the first micro-LED and the second micro-LED in a direction opposite to the incident direction.

### BRIEF DESCRIPTION OF THE DRAWINGS

The above and other aspects, features, and advantages of one or more embodiments of the disclosure will be more apparent from the following description taken in conjunction with the accompanying drawings, in which:

FIG. 1 is a cross-sectional view showing a first micro-LED pixel (non-flip structure) according to one or more embodiments;

FIGS. 2 and 3 are plan views of the first micro-LED pixel illustrated in FIG. 1;

FIGS. 4, 5, 6, 7, 8, 9, 10, 11, 12, 13, 14, 15, 16, 17, 18, 19, 20, 21, 22A, 22B, 23, 24, and 25 are cross-sectional views and plan views showing step by step a first manufacturing method for a first micro-LED pixel according to one or more embodiments;

FIGS. 26, 27, 28, 29, 30, and 31 are cross-sectional views showing a portion of a second manufacturing method for the first micro-LED pixel according to one or more embodiments;

FIG. 32 is a cross-sectional view showing a second micro-LED pixel (flip structure) according to one or more embodiments;

FIGS. 33, 34, 35, 36, 37, 38, 39, 40, 41, 42, 43, 44, 45, 46, and 47 are cross-sectional views and plan views sequentially showing a manufacturing method for the second micro-LED pixel according to one or more embodiments;

FIG. 48 is a cross-sectional view of a third micro-LED pixel (a first type of pentile pixel) according to one or more embodiments;

FIG. 49 is a cross-sectional view of a fourth micro-LED pixel (second type pentile pixel) according to one or more embodiments;

FIGS. 50, 51, 52, 53, 54, 55, 56, 57, 58, 59, 60, 61, 62, 63, 64, and 65 are cross-sectional views and plan views sequentially showing a manufacturing method for the third micro-LED pixel according to one or more embodiments;

FIGS. 66, 67, 68, 69, 70, and 71 are cross-sectional views sequentially showing a manufacturing method for the fourth micro-LED pixel according to one or more embodiments;

FIG. 72 is a schematic front view showing an LED display according to one or more embodiments;

FIG. 73 is a block diagram showing a display device according to one or more embodiments; and

FIG. 74 is a block diagram showing an electronic apparatus according to one or more embodiments.

### DETAILED DESCRIPTION

Reference will now be made in detail to embodiments, examples of which are illustrated in the accompanying drawings, wherein like reference numerals refer to like elements throughout. In this regard, the one or more embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, vertically stacked micro-LED pixels and manufacturing methods thereof, a display device including a micro-LED pixel, and an electronic apparatus including a micro-LED pixel and/or a micro-LED display will be described in detail with reference to the accompanying drawings. The drawings are not to scale, and thicknesses of layers and regions may be exaggerated for clarification of the specification.

The embodiments of the disclosure are capable of various modifications and may be embodied in many different forms. In a layer structure described below, when a position of an element is described using an expression “above” or “on”, the position of the element may include not only the element being “immediately in a contact manner” but also being in a non-contact manner”. In the drawings, like reference numerals refer to the like elements.

The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “ . . . modules” denote units or modules that process at least one function or operation, and may be realized by hardware, software, or a combination of hardware and software.

Connections or connection members of lines between components shown in the drawings illustrate functional connections and/or physical or circuit connections, and the connections or connection members may be represented by replaceable or additional various functional connections, physical connections, or circuit connections in an actual apparatus.

All examples or example terms are simply used to explain in detail the technical scope of the disclosure, and thus, the scope of the disclosure is not limited by the examples or the example terms as long as it is not defined by the claims.

First, a structure of a vertically stacked micro-LED pixel according to one or more embodiments will be described.

The vertically stacked micro-LED pixel may have a layer structure in which a plurality of micro-LEDs that emit light of different wavelengths are vertically stacked or may include such a layer structure. The vertically stacked micro-LED pixel may a pixel having or including the layer structure. For example, one vertically stacked micro-LED pixel may include a layer structure in which three micro-LEDs are vertically stacked. For example, one vertically stacked micro-LED pixel may include at least one layer structure in which two micro-LEDs are vertically stacked.

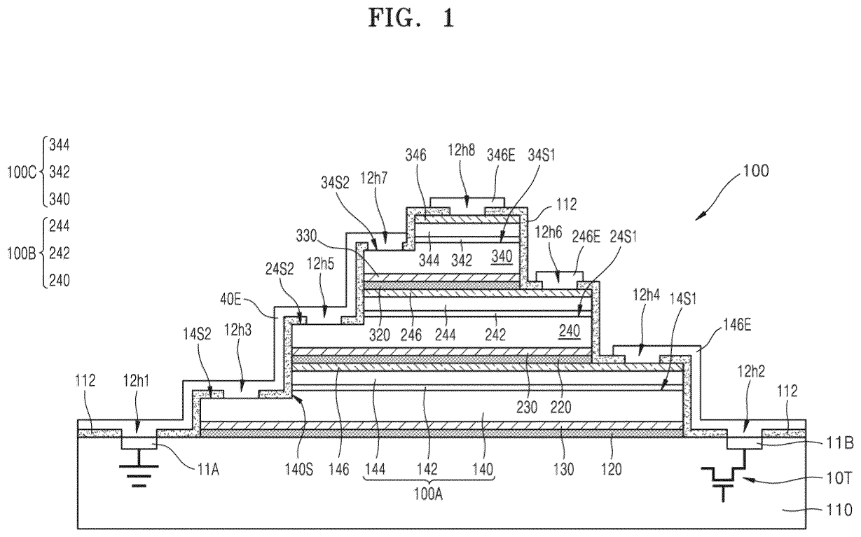

FIG. 1 shows a first type of a vertically stacked micro-LED pixel 100 (hereinafter referred to as a first micro-LED pixel) according to one or more embodiments.

Referring to FIG. 1, the first micro-LED pixel 100 includes a first LED 100A, a second LED 100B, and a third LED 100C sequentially stacked on a first backplane 110. The first backplane 110 may include a complementary metal oxide semiconductor (CMOS) backplane including transistors for driving an LED.

Each of the LEDs 100A, 100B, and 100C may be a micro-LED having a maximum diameter of less than 5 μm, 4 μm or less, or 3 μm or less on a plane from a top plan view, but the maximum diameter may be not limited thereto.

The first backplane 110 may include a first electrode pad layer 11A and a second electrode pad layer 11B spaced apart from each other in a horizontal direction, but embodiments are not limited thereto. As an example, the first backplane 110 may further include one or more electrode pad layers in addition to the first and second electrode pad layers 11A and 11B. The first electrode pad layer 11A may be grounded or not. The second electrode pad layer 11B may be provided to be connected to one of a plurality of transistors included in the first backplane 100. For example, the plurality of transistors may include, but are not limited to, a field effect transistor (FET). For example, the second electrode pad layer 11B may be connected to a driving transistor 10T included in the first backplane 110. As an example, the second electrode pad layer 11B may be connected to a drain of the driving transistor 10T provided on the first backplane 110 to drive a first LED 100A. The plurality of transistors of the first backplane 110 may include a transistor for driving the second LED 100B and a transistor for driving the third LED 100C.

The first electrode pad layer 11A and the second electrode pad layer 11B may have the same height in a vertical direction (stacking direction), and the first backplane 110 may include another electrode pad layer provided to have the same height as the first and/or second electrode pad layers 11A and 11B. A height of upper surfaces of the first and second electrode pad layers 11A and 11B may be the same as a height of an upper surface of the first backplane 110 but may also be different.

The electrode pad layer(s) provided on the first backplane 110, including the first and second electrode pad layers 11A and 11B, may be provided at an edge or along the edge of the first backplane 110, but embodiments are not limited thereto.

A first attachment layer 120 may be provided on an inner region of the first backplane 110 where the electrode pad layers are provided. The first attachment layer 120 may be expressed in various ways, such as a first adhesive layer, a first adhesive member, a first bonding layer, and a first bonding member. For example, a thickness of the first attachment layer 120 may be 0.2 μm or less or about 0.1 μm, but embodiments are not limited thereto. The first attachment layer 120 may be or include an insulating material layer. For example, a material of the first attachment layer 120 may include a polymer but embodiments are not limited thereto. For example, the first attachment layer 120 may include polyimide (PI) or benzocyclobutene (BCB) but embodiments are not limited thereto.

The first attachment layer 120 may be provided to be spaced apart from the first and second electrode pad layers 11A and 11B in the horizontal direction. The first attachment layer 120 may be provided to be spaced apart from other electrode pad layers formed on the first backplane 110.

A first reflective layer 130 may be provided on the first attachment layer 120. The first reflective layer 130 may be provided directly on an upper surface of the first attachment layer 120 and may be provided to cover the entire upper surface of the first attachment layer 120. For example, the entire upper surface of the first attachment layer 120 may be covered with the first reflective layer 130. The first reflective layer 130 may be provided only on the first attachment layer 120. The first reflective layer 130 may be arranged to be spaced apart from the first and second electrode pad layers 11A and 11B, as well as other electrode pad layer(s) provided on the first backplane 110. The first reflective layer 130 may be formed on the first attachment layer 120 to have a constant or substantially constant thickness in the vertical direction. For example, the thickness of the first reflective layer 130 may be less than or equal to 0.3 μm, but embodiments are not limited thereto. For example, the first reflective layer 130 may be a single layer, but may also have a layer structure in which a plurality of layers with different refractive indices are stacked.

A material of the first reflective layer 130 may include metal or alloy, but embodiments are not limited thereto. For example, the first reflective layer 130 may include aluminum (Al) or silver (Ag), but embodiments are not limited thereto. For example, the first reflective layer 130 may include an alloy. For example, the first reflective layer 130 may further include silicon oxide (e.g., SiO₂) to increase adhesion to the first attachment layer 120. For example, the silicon oxide may be provided at an interface between the first reflective layer 130 and the first attachment layer 120, but embodiments are not limited thereto. These materials and material characteristics of the first reflective layer 130 may be equally applied to other reflective layers described below.

The first LED 100A is provided on the first reflective layer 130.

The first LED 100A may include a first compound semiconductor layer 140, a first active layer 142, and a second compound semiconductor layer 144, which are sequentially stacked. The first active layer 142 may be a first light-generating layer or a first light-emitting layer. A first electrode layer 146 is provided on the second compound semiconductor layer 144. The first electrode layer 146 may be a transparent material layer. The first LED 100A may also include the first electrode layer 146.

The first compound semiconductor layer 140 may be provided to cover an entire upper surface of the first reflective layer 130 and may be in direct contact with the entire upper surface of the first reflective layer 130. For example, an entire lower surface of the first compound semiconductor layer 140 may be covered with the first reflective layer 130.

For example, the first compound semiconductor layer 140 may include a Group III-V or Group II-VI compound semiconductor, but embodiments are not limited thereto. As an example, the first compound semiconductor layer 140 may include a two-component, three-component, or four-component compound semiconductor, but embodiments are not limited thereto. For example, the first compound semiconductor layer 140 may include a compound semiconductor doped with an n-type conductive impurity (e.g., a Group V element) or including an n-type conductive impurity (hereinafter referred to as an n-type compound semiconductor). For example, the first compound semiconductor layer 140 may include an n-type gallium nitride (GaN) layer or indium gallium nitride (InGaN) layer, but embodiments are not limited thereto.

The first compound semiconductor layer 140 may include a first upper surface 14S1 and a second upper surface 14S2 having different heights. Accordingly, a step difference may be provided between the first and second upper surfaces 14S1 and 14S2. For example, the first and second upper surfaces 14S1 and 14S2 are spaced apart from each other in the vertical direction. The first upper surface 14S1 may be flat, and the second upper surface 14S2 may also be flat. An area (surface area) of the first upper surface 14S1 may be greater than an area (surface area) of the second upper surface 14S2. The second upper surface 14S2 may be an area where a power source and the first compound semiconductor layer 140 come into contact. For example, a portion of the second upper surface 14S2 may be connected to the power source through a conductive layer formed directly on the second upper surface 14S2. The conductive layer may be an electrode layer or a first electrode layer. As the first compound semiconductor layer 140 is an n-type compound semiconductor layer, the electrode layer formed on the second upper surface 14S2 may be an N-type electrode layer, N-electrode layer, or N-electrode.

For example, a thickness of the first compound semiconductor layer 140, for example, the thickness of the first compound semiconductor layer 140 in a vertical direction perpendicular to the upper surface of the first reflective layer 130, may be less than or equal to 0.5 μm, but may be adjusted considering the thickness of the first LED 100A or the thickness of the first active layer 142 or the second compound semiconductor layer 144. The first compound semiconductor layer 140 is spaced apart from the first and second electrode pad layers 11A and 11B provided on the first backplane 110.

The first active layer 142 is provided on the first upper surface 14S1 of the first compound semiconductor layer 140. The first active layer 142 is spaced apart from the second upper surface 14S2 of the first compound semiconductor layer 140, a first charge blocking layer (CBL) 112 is provided between a side of the first active layer 142 and the second upper surface 14S2, and sides of the first active layer 142 are covered with the first CBL 112. Accordingly, charge injection through the sides of the first active layer 142 may be prevented.

The first active layer 142 may be provided to cover the entire first upper surface 14S1 of the first compound semiconductor layer 140, may be in direct contact with the entire first upper surface 14S1, but embodiments are not limited thereto. The thickness of the first active layer 142 on the first upper surface 14S1 of the first compound semiconductor layer 140 in the vertical direction may be constant or substantially constant. The thickness of the first active layer 142 may be less than the thicknesses of the first and second compound semiconductor layers 140 and 144 in the vertical direction, but embodiments are not limited thereto. For example, the first active layer 142 may include a material having a multi-quantum well (MQW) structure. The wavelength of light generated from the first active layer 142 may vary depending on the material of the first active layer 142. Therefore, when the first to third LEDs 100A, 100B, and 100C are configured to emit different wavelengths, the materials or configuration of the materials of the active layers included in the first to third LEDs 100A, 100B, and 100C may be selected to emit light of different wavelengths. As an example, the first active layer 142 may include a material that emits green light (G) or may include a material configured to emit G, but embodiments are not limited thereto.

Carriers (e.g., holes, electrons) supplied from the first and second compound semiconductor layers 140 and 144 may be recombined in the first active layer 142, and as a result, light may be generated in the first active layer 142. Light generated in the first active layer 142 may pass through the first and second compound semiconductor layers 140 and 144 to be emitted upward and downward in the vertical direction. Light emitted downward from the first active layer 142 may be reflected by the first reflective layer 130 to be emitted upward.

As a result, because the first reflective layer 130 is provided, the amount of light emitted in the vertical direction from the first LED 100A may be increased compared to when the first reflective layer 130 is not provided.

For example, because the first reflective layer 130 is provided, the amount of light emitted from the first LED 100A may be increased compared to the amount of light emitted from the existing micro-LED having the same size as the first LED 100A but not including the first reflected layer 130. Therefore, while making the size of the first LED 100A less than a size of related micro-LED, the amount of light emitted from the first LED 100A may be maintained equal to an amount of light emitted from the related micro-LED. Because the second and third LEDs 100B and 100C also have the same light intensity increasing characteristics as the first LED 100A, when the micro-LED pixel 100 is used, the size of the pixel may be reduced compared to related micro-LED pixels while maintaining the same or higher brightness of the pixel. For example, when the micro-LED pixel 100 is used, high resolution may be realized by increasing the micro-LED pixel density, that is, PPI, and at the same resolution, the size of a display device may be reduced less than that of a related display device that does not include the first reflected layer 130.

The second compound semiconductor layer 144 is provided on the first active layer 142. The second compound semiconductor layer 144 is provided to cover an entire upper surface of the first active layer 142 and may be in direct contact with the entire upper surface of the first active layer 142. The second compound semiconductor layer 144 may be provided only on the first active layer 142, and the thickness of the second compound semiconductor layer 144 in the vertical direction may be constant or substantially constant on the first active layer 142.

The thickness of the second compound semiconductor layer 144 may be greater than the first active layer 142 and less than the first compound semiconductor layer 140. A right-side surface of the second compound semiconductor layer 144 may form the same side surface as a right-side surface of the first active layer 142, a right-side surface of the first compound semiconductor layer 140, a right-side surface of the first reflective layer 130, and a right-side surface of the first attachment layer 120. A left-side surface of the second compound semiconductor layer 144 may form the same side as a left-side surface of the first active layer 142 and the step difference surface 140S existing in the first compound semiconductor layer 140. The step difference surface 140S exists between the first upper surface 14S1 and the second upper surface 14S2 of the first compound semiconductor layer 140.

For example, a material of the second compound semiconductor layer 144 may be the same as the material of the first compound semiconductor layer 140, excluding doping materials or included (added) materials, but embodiments are not limited thereto, and the material of the second compound semiconductor layer 144 may be different from the material of the first compound semiconductor layer 140. For example, the main components of the second compound semiconductor layer 144 may be the same as that of the first compound semiconductor layer 140, but unlike the first compound semiconductor layer 140, the second compound semiconductor layer 144 may be doped with or may include a p-type conductive impurity (e.g., Group Ill elements). For example, when the first and second compound semiconductor layers 140 and 144 are compound semiconductor layers having two-components (e.g., GaN) as the main component, the first compound semiconductor layer 140 may be an n-GaN layer and the second compound semiconductor layer 144 may be a p-GaN layer.

The first transparent electrode layer 146 exists on the second compound semiconductor layer 144. The first transparent electrode layer 146 may be provided to cover an entire upper surface of the second compound semiconductor layer 144 and may be in contact with the entire upper surface of the second compound semiconductor layer 144. The first transparent electrode layer 146 may be a P-type electrode, a P-type electrode layer, a P-side electrode, etc. in that the first transparent electrode layer 146 directly contacts the p-type second compound semiconductor layer 144. A right-side surface of the first transparent electrode layer 146 and the right-side surface of the second compound semiconductor layer 144 may be coplanar and form one flat side surface. The left-side surface of the first transparent electrode layer 146 and the left-side surface of the second compound semiconductor layer 144 may also be coplanar and form one flat side surface.

For example, the first transparent electrode layer 146 may be or include a material layer that is transparent to at least visible light. As an example, the first transparent electrode layer 146 may include indium tin oxide (ITO), but embodiments are not limited thereto.

A second attachment layer 220 may be provided on a portion of the first transparent electrode layer 146. Another portion of the first transparent electrode layer 146 is in contact with a first interconnection electrode layer 146E. The first interconnection electrode layer 146E may be a P-type first interconnection electrode layer or a first P-type interconnection electrode layer in that the first interconnection electrode layer 146E contacts the first transparent electrode layer 146. For example, a material (substance) of the first interconnection electrode layer 146E may be the same as that of the first transparent electrode layer 146. For example, among electrode materials that are transparent to at least visible light, the first interconnection electrode layer 146E may include a first transparent electrode material, and the first transparent electrode layer 146 may include a second transparent electrode material different from the first transparent electrode material. Material properties of other interconnection electrode layers described below may also be the same as those of the first interconnection electrode layer 146E, but are not limited thereto.

The second attachment layer 220 and the first interconnection electrode layer 146E are spaced apart from each other, and the first CBL 112 is provided therebetween. Accordingly, the second attachment layer 220 and the first interconnection electrode layer 146E do not contact each other. The first interconnection electrode layer 146E may be connected to the second electrode pad layer 11B of the first backplane 110. For example, the first interconnection electrode layer 146E may be a conductive layer that connects the second electrode pad layer 11B of the first backplane 110 and the first transparent electrode layer 146.

For example, the second attachment layer 220 may be a material layer provided to bond the second LED 100B, which is transferred onto the first LED 100A, with the first LED 100A. A material of the second attachment layer 220 may be the same as the material of the first attachment layer 120, but the materials may be different from each other.

A second reflective layer 230 may be provided on the second attachment layer 220. The second reflective layer 230 may be provided only on the second attachment layer 220. The second reflective layer 230 may be provided to cover an entire upper surface of the second attachment layer 220 and may be in direct contact with the entire upper surface of the second attachment layer 220. The function of the second reflective layer 230 may be the same as that of the first reflective layer 130. For example, the second reflective layer 230 may be arranged to reflect light emitted downward from a second active layer 242 of the second LED 100B upward. For example, the material and layer structure (configuration) of the second reflective layer 230 may be the same as those of the first reflective layer 130, but are not limited thereto.

A horizontal length of the second reflective layer 230 may be the same as a horizontal length of the second attachment layer 220, but the lengths may be different from each other. The horizontal lengths of the second attachment layer 220 and the second reflective layer 230 may be less than a horizontal length of the first transparent electrode layer 146.

Because the second reflective layer 230 is provided, light emitted from a corresponding portion of the first active layer 142 below the second reflective layer 230 may be difficult to be emitted. For example, light emitted from a portion of the first active layer 142 corresponding to the second reflective layer 230 may be blocked by the second reflective layer 230. In this regard, a portion of the first transparent electrode layer 146 corresponding to the second reflective layer 230 may be removed, and the first transparent electrode layer 146 may be provided only in a portion where the second reflective layer 230 is not present. For example, a region where the first transparent electrode layer 146 is removed may be filled with the second attachment layer 220. In this case, a thickness of the second attachment layer 220 below the second reflective layer 230 may be greater than the thickness of the second attachment layer 200 as illustrated in FIG. 1.

The second LED 100B may be provided on the second reflective layer 230. Therefore, as in the case of the first LED 100A provided on the first reflective layer 130, the amount of light emitted from the second LED 100B may also be increased compared to the case when the second reflective layer 230 is not provided. Therefore, the second LED 100B may also have the advantages of the first LED 100A described above.

The second LED 100B may include a third compound semiconductor layer 240, a second active layer 242, and a fourth compound semiconductor layer 244 sequentially stacked on the second reflective layer 230. The third compound semiconductor layer 240 may be physically the same as the first compound semiconductor layer 140, but the third compound semiconductor layer 240 and the first compound semiconductor layer 140 may also be physically different from each other. The third compound semiconductor layer 240 includes a first upper surface 24S1 and a second upper surface 24S2 of different heights in the vertical direction. Accordingly, a step difference may be provided between the first and second upper surfaces 24S1 and 24S2. A height of the second upper surface 24S2 may be lower than that of the first upper surface 24S1. An area of the first upper surface 24S1 may be greater than an area of the second upper surface 24S2. A thickness of the third compound semiconductor layer 240 may be substantially the same as the thickness of the first compound semiconductor layer 140 in the vertical direction, but the thicknesses may be different from each other.

The second active layer 242 may be provided on the first upper surface 24S1 of the third compound semiconductor layer 240. The second active layer 242 may be provided only on the first upper surface 24S1 or may be provided to cover the entire first upper surface 24S1. The second active layer 242 may be in direct contact with the entire first upper surface 24S1. A horizontal length of the second active layer 242 may be equal to or substantially equal to a horizontal length of the first upper surface 24S1. The function of the second active layer 242 may be the same as that of the first active layer 142, the second active layer 242 may include a material layer having a multi-quantum well (MQW) structure. For example, the material of the second active layer 242 may be different from the material of the first active layer 142. For example, when the first active layer 142 includes a material that emits light of a first wavelength, the second active layer 242 may include a material that emits light of a second wavelength different from the first wavelength. The first wavelength may be a wavelength included in a first band, and the second wavelength may be a wavelength included in a second band different from the first band. The light of the first wavelength or the light of the second wavelength may include one of red light (R), green light (G), and blue light (B).

The second active layer 242 is spaced apart from the second upper surface 24S2. Both side surfaces of the second active layer 242 are covered with the first CBL 112. Accordingly, charge injection through the side surface of the second active layer 242 may be prevented.

The fourth compound semiconductor layer 244 is provided on the second active layer 242. The fourth compound semiconductor layer 244 may be provided only on an upper surface of the second active layer 242. The fourth compound semiconductor layer 244 may be provided to cover the entire upper surface of the second active layer 242 and may be in direct contact with the corresponding entire upper surface of the second active layer 242. A horizontal length of the fourth compound semiconductor layer 244 may be the same or substantially the same as the horizontal length of the second active layer 242. A thickness of the fourth compound semiconductor layer 244 may be greater than a thickness of the second active layer 242 and less than a thickness of the third compound semiconductor layer 240 in the vertical direction. For example, a material of the fourth compound semiconductor layer 244 may be the same as the material of the second compound semiconductor layer 144, but among the p-type compound semiconductor materials, the fourth compound semiconductor layer 244 and the second compound semiconductor layer 144 may include p-type compound semiconductor materials different from each other.

A second transparent electrode layer 246 may be provided on the fourth compound semiconductor layer 244. The second transparent electrode layer 246 may be provided to cover an entire upper surface of the fourth compound semiconductor layer 244 and may be in direct contact with the entire upper surface of the fourth compound semiconductor layer 244. A material of the second transparent electrode layer 246 may be the same as that of the first transparent electrode layer 146, but the materials may be different from each other.

Because the second transparent electrode layer 246 is an electrode that directly contacts the p-type fourth compound semiconductor layer 244, the second transparent electrode layer 246 may be a P-type electrode or a P-type electrode layer. A horizontal length of the second transparent electrode layer 246 may be the same or substantially the same as the horizontal length of the fourth compound semiconductor layer 244.

The second LED 100B may also include the second reflective layer 230 and/or the second transparent electrode layer 246.

A third attachment layer 320 may be provided on a first region of the second transparent electrode layer 246. The first region may be a first region of an upper surface of the second transparent electrode layer 246. A second interconnection electrode layer 246E is in contact with a second region of the second transparent electrode layer 246. The second region may be a second region of the upper surface of the second transparent electrode layer 246. The first region may be different from the second region. The first region of the second transparent electrode layer 246 may be wider than the second region of the second transparent electrode layer 246.

The second interconnection electrode layer 246E is spaced apart from the third attachment layer 320. The first CBL 112 is provided between the second interconnection electrode layer 246E and the third attachment layer 320. Accordingly, the second interconnection electrode layer 246E and the third attachment layer 320 do not contact each other.

The third attachment layer 320 may be provided to cover the entire first region of an upper surface of the second transparent electrode layer 246 and may be in direct contact with the entire first region of the second transparent electrode layer 246. A material of the third attachment layer 320 may be the same as a material of the first attachment layer 120, but the materials may be different from each other.

A third reflective layer 330 may be provided on the third attachment layer 320. The third reflective layer 330 may be provided only on an upper surface of the third attachment layer 320. The third reflective layer 330 may be provided to cover the entire upper surface of the third attachment layer 320 and may be in direct contact with the entire upper surface of the third attachment layer 320. A horizontal length of the third reflective layer 330 may be the same or substantially the same as a horizontal length of the third attachment layer 320. The third reflective layer 330 is provided to reflect light upward emitted downward from a third active layer 342 of the third LED 100C, and the function of the third reflective layer 330 may be equivalent to that of the first reflective layer 130 or the second reflective layer 230. Because the third reflective layer 330 is provided, an amount of light emitted from the third LED 100C in a direction perpendicular to an upper surface of the third active layer 342 (vertically upward) may be increased when the third reflective layer 330 is not provided. Therefore, the advantages described above of the first LED 100A may be equally applied to the third LED 100C.

For example, as the third reflective layer 330 is provided above the second active layer 242, for the same reason as the reason a portion of the first transparent electrode layer 146 is removed, a portion of the second transparent electrode layer 246 corresponding to the third reflective layer 330 may be removed. For example, the portion where the second transparent electrode layer 246 is removed may be filled with the third attachment layer 320. In this case, a thickness of the third attachment layer 320 may be greater than the thickness of the third attachment layer 320 as illustrated in FIG. 1.

For example, a material and layer structure (configuration) of the third reflective layer 330 may be the same as that of the first reflective layer 130, but the materials may be different from each other. Both side surfaces of the third reflective layer 330 are covered with the first CBL 112.

For example, the second reflective layer 230 and/or the third reflective layer 330 may be omitted.

The third LED 100C may be provided on the third reflective layer 330. The third LED 100C may include a fifth compound semiconductor layer 340, the third active layer 342, and a sixth compound semiconductor layer 344 sequentially stacked on an upper surface of the third reflective layer 330.

A material of the fifth compound semiconductor layer 340 may be the same as the material of the first compound semiconductor layer 140, but among n-type compound semiconductor materials, the material of the fifth compound semiconductor layer 340 and the material of the first compound semiconductor layer 140 may be different from each other. The fifth compound semiconductor layer 340 may be provided only on the upper surface of the third reflective layer 330. For example, the fifth compound semiconductor layer 340 may be provided to cover the entire upper surface of the third reflective layer 330 and may be provided to contact the entire upper surface of the third reflective layer 330. For example, an entire lower surface of the fifth compound semiconductor layer 340 may be covered with the third reflective layer 330. Accordingly, a horizontal length of the fifth compound semiconductor layer 340 may be the same or substantially the same as the horizontal length of the third reflective layer 330.

The fifth compound semiconductor layer 340 may include a first upper surface 34S1 and a second upper surface 34S2 having different heights from each other in the vertical direction. The height of the second upper surface 34S2 may be lower than the height of the first upper surface 34S1. Accordingly, a step difference may be provided between the first and second upper surfaces 34S1 and 34S2. A region of the first upper surface 34S1 may be greater than a region of the second upper surface 34S2. Both side surfaces of the fifth compound semiconductor layer 340 may be covered with the first CBL 112.

The third active layer 342 may be provided on the first upper surface 34S1 of the fifth compound semiconductor layer 340. The third active layer 342 may be provided only on the first upper surface 34S1. The third active layer 342 may be provided to cover the entire first upper surface 34S1 and may be in direct contact with the entire first upper surface 34S1. The horizontal length (or horizontal width) of the third active layer 342 may be equal to a horizontal length of the first upper surface 34S1. The function of the third active layer 342 may be the same as the function of the first active layer 142 in that the third active layer 342 emits light. The third active layer 342 may include a material layer having an MQW structure. A material (or form of material) of the third active layer 342 may be different from the material (or form of material) of the first active layer 142 that includes a material that emits light of a first wavelength or a material (or form of material) of the second active layer 242 that includes a material that emits light of a second wavelength. For example, the third active layer 342 may include a material layer that emits light of a third wavelength, or a material layer configured to emit light of the third wavelength. The third wavelength may be different from the first and second wavelengths. For example, the third wavelength may be a wavelength included in a third band. For example, the third wavelength of light may include one of R, G, and B.

Both side surfaces of the third active layer 342 are covered with the first CBL 112. Accordingly, charge injection through the side surfaces of the third active layer 342 may be prevented.

The sixth compound semiconductor layer 344 may be provided on an upper surface of the third active layer 342. The sixth compound semiconductor layer 344 may be provided only on the upper surface of the third active layer 342. The sixth compound semiconductor layer 344 may be provided to cover the entire upper surface of the third active layer 342 and may be in direct contact with the entire upper surface of the third active layer 342. A horizontal length (horizontal width) of the sixth compound semiconductor layer 344 may be the same or substantially the same as the horizontal length of the third active layer 342. A thickness of the sixth compound semiconductor layer 344 may be greater than a thickness of the third active layer 342 and less than a thickness of the fifth compound semiconductor layer 340 in the vertical direction. Both side surfaces of the sixth compound semiconductor layer 344 are covered with the first CBL 112.

A material of the sixth compound semiconductor layer 344 may be the same as the material of the second compound semiconductor layer 144, but among the p-type compound semiconductor materials, the material of the sixth compound semiconductor layer 344 and the material of the second compound semiconductor layer 144 may be different from each other.

A third transparent electrode layer 346 may be provided on the sixth compound semiconductor layer 344. The third transparent electrode layer 346 may be provided only on an upper surface of the sixth compound semiconductor layer 344. The third transparent electrode layer 346 may be provided to cover the entire upper surface of the sixth compound semiconductor layer 344 and may be in contact with the corresponding entire upper surface of the sixth compound semiconductor layer 344. A horizontal length of the third transparent electrode layer 346 may be the same or substantially the same as the horizontal length of the sixth compound semiconductor layer 344. A material of the third transparent electrode layer 346 may be the same as the material of the first transparent electrode layer 146, but among materials that are transparent to at least visible light, the material of the third transparent electrode layer 346 and the material of the first transparent electrode layer 146 may be different from each other.

The third LED 100C may also include the third reflective layer 330 and/or the third transparent electrode layer 346.

The first CBL 112 may be provided on the third transparent electrode layer 346. The first CBL 112 may include an eighth through hole 12h8 through which a portion of the third transparent electrode layer 346 is exposed. An entire upper surface of the third transparent electrode layer 346 around and adjacent to the eighth through hole 12h8 may be covered with the first CBL 112 and may be in direct contact with the first CBL 112. The first CBL 112 may include a material layer that is transparent to at least visible light and has etch resistance. For example, the first CBL 112 may include a material layer having a high etch selectivity. Therefore, the first CBL 112 may be used as an etch mask when etching some material layers.

The first CBL 112 may extend downward along both side surfaces of the third transparent electrode layer 346 and onto the upper surface of the first backplane 110. The first CBL 112 may be provided to cover the both side surfaces of the first to third transparent electrode layers 146, 246, and 346, the both side surfaces of the first to third reflective layers 130, 230, and 330, and the both side surfaces of the third LED 100C while extending downward. In addition, the first CBL 112 may be provided to cover the upper surface of the first backplane 110 around and adjacent to the first LED 100A, the second upper surface 14S2 of the first compound semiconductor layer 140, and the second upper surface 24S2 of the second compound semiconductor layer 240, and the second upper surface 34S2 of the third compound semiconductor layer 340.

The first CBL 112 may include a first through hole 12h1 through which the first electrode pad layer 11A is exposed and a second through hole 12h2 through which the second electrode pad layer 11B is exposed on the upper surface of the first backplane 110. The upper surface of the first backplane 110 between the first and second through holes 12h1 and 12h2 and the first attachment layer 120 is covered with the first CBL 112.

The first CBL 112 may include a third through hole 12h3 through which a portion of the second upper surface 14S2 is exposed on the second upper surface 14S2 of the first compound semiconductor layer 140, and a fifth through hole 12h5 through which a portion of the second upper surface 24S2 is exposed on the second upper surface 24S2 of the second compound semiconductor layer 240. Additionally, the first CBL 112 may include a seventh through hole 12h7 through which a portion of the second upper surface 34S2 is exposed on the second upper surface 34S2 of the second compound semiconductor layer 340. The first CBL 112 may be formed to cover a portion of the first transparent electrode layer 146 and include a fourth through hole 12h4 through which a portion of the first transparent electrode layer 146 is exposed. The first CBL 112 may be formed to cover a portion of the second transparent electrode layer 246 and include a sixth through hole 12h6 through which a portion of the second transparent electrode layer 246 is exposed.

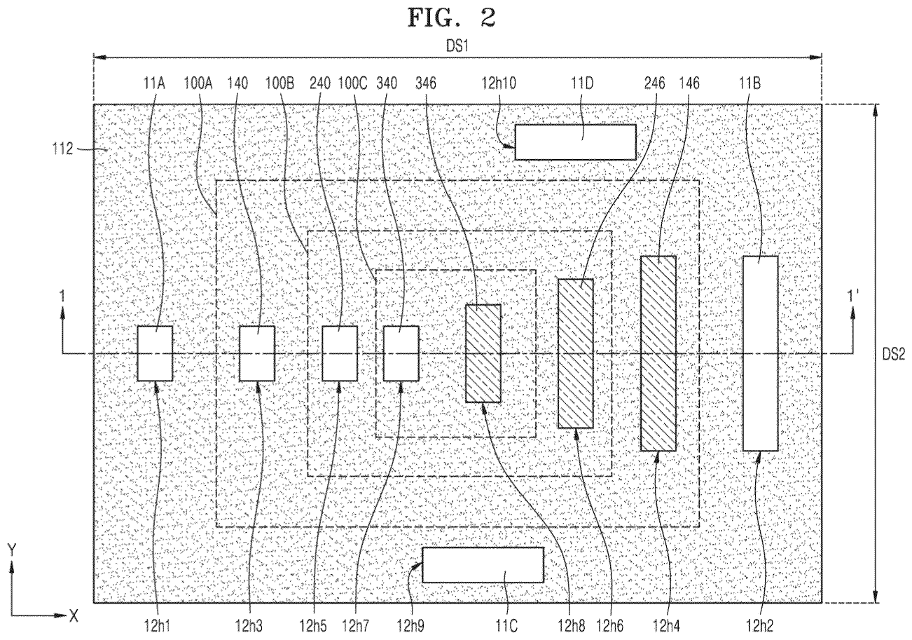

As seen in the plan view of FIG. 2, the first CBL 112 may include, in addition to the first and second through holes 12h1 and 12h2, a ninth through hole 12h9 through which a third electrode pad layer 11C is exposed and a tenth through hole 12h10 through which a fourth electrode pad layer 11D is exposed on the first backplane 110. The first CBL 112 may be provided to cover the entire surface adjacent to and surrounding the first to tenth through holes 12h1 to 12h10 and may be in contact with the entire corresponding surface. As a result, the first CBL 112 may be provided between the through holes 12h1 to 12h10, and a region between the through holes 12h1 to 12h10 is covered with the first CBL 112.

The first interconnection electrode layer 146E, the second interconnection electrode layer 246E, the third interconnection electrode layer 346E, and the fourth interconnection electrode layer 40E may be provided on the first CBL 112. The first to fourth interconnection electrode layers 146E, 246E, 346E, and 40E may be transparent. The first to fourth interconnection electrode layers 146E, 246E, 346E, and 40E may include a material layer that is transparent to at least visible light. For example, the transparent material layer may include an indium tin oxide (ITO) layer. The first interconnection electrode layer 146E may be provided on the first CBL 112 between the second and fourth through holes 12h2 and 12h4, and provided to fill the second and fourth through holes 12h2 and 12h4. Accordingly, the entire second electrode pad layer 11B exposed through the second through hole 12h2 may be covered with the first interconnection electrode layer 146E and may be in direct contact with the first interconnection electrode layer 146E. Additionally, the entire portion of the first transparent electrode layer 146 exposed through the fourth through hole 12h4 may be covered with the first interconnection electrode layer 146E and may be in direct contact with the first interconnection electrode layer 146E. Accordingly, the first transparent electrode layer 146 and the second electrode pad layer 11B of the first backplane 110 may be connected to each other by the first interconnection electrode layer 146E. The first transparent electrode layer 146 is in direct contact with the second compound semiconductor layer 144, which is a P-type compound semiconductor layer of the first LED 100A. Accordingly, the P-type electrode layer of the first LED 100A may be connected to the second electrode pad layer 11B of the first backplane 110 through the first interconnection electrode layer 146E, and may be connected to a driving transistor connected to the second electrode pad layer 11B. As a result, a driving voltage may be supplied to the second compound semiconductor layer 144 of the first LED 100A through the first interconnection electrode layer 146E.

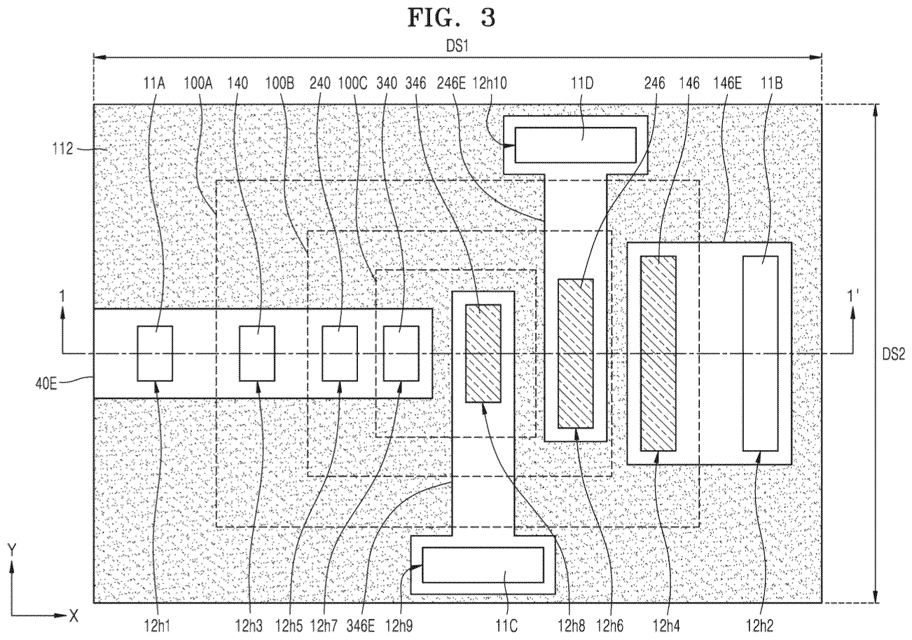

The second interconnection electrode layer 246E may be provided on the first CBL 112 around and adjacent to the sixth through hole 12h6 and may fill the sixth through hole 12h6. The second interconnection electrode layer 246E covers the second transparent electrode layer 246 exposed through the sixth through hole 12h6 and may be in direct contact with the entire exposed portion of the second transparent electrode layer 246. As seen in the plan view of FIG. 3, the second interconnection electrode layer 246E may extend to the tenth through hole 12h10 and may be provided to cover the fourth electrode pad layer 11D of the first backplane 110 exposed through the tenth through hole 12h10. The second interconnection electrode layer 246E may completely fill the tenth through hole 12h10 and may be in direct contact with the entire fourth electrode pad layer 11D exposed through the tenth through hole 12h10. Accordingly, the second transparent electrode layer 246 and the fourth electrode pad layer 11D may be connected to each other by the second interconnection electrode layer 246E. The second transparent electrode layer 246 is a P-type electrode layer of the second LED 100B, and the fourth electrode pad layer 11D is connected to a transistor for driving the LED, and thus, the P-type compound semiconductor layer (fourth compound semiconductor layer) 244 of the second LED 100B may be connected to the driving transistor of the first backplane 110 through the second interconnection electrode layer 246E.

The third interconnection electrode layer 346E may be provided on the first CBL 112 around and adjacent to the eighth through hole 12h8 and may be provided to completely fill the eighth through hole 12h8. Accordingly, the third transparent electrode layer 346 exposed through the eighth through hole 12h8 may be in direct contact with the third interconnection electrode layer 346E.

As seen in the plan view of FIG. 3, the third interconnection electrode layer 346E may be provided to extend to the third electrode pad layer 11C of the first backplane 110 and to cover the entire third electrode pad layer 11C. The third interconnection electrode layer 346E may be provided to fill the ninth through hole 12h9 through which the third electrode pad layer 11C is exposed. The third interconnection electrode layer 346E may completely fill the ninth through hole 12h9. Accordingly, the entire third electrode pad layer 11C exposed through the ninth through hole 12h9 may be in direct contact with the third interconnection electrode layer 346E.

The third electrode pad layer 11C may be provided to be connected to a driving transistor to drive the third LED 100C. Also, because the third transparent electrode layer 346 corresponds to the P-type electrode layer of the third LED 100C, as a result, the P-type compound semiconductor layer 344 of the third LED 100C may be connected to the driving transistor of the first backplane 110 through the third interconnection electrode layer 346E.

As seen in the top view of FIGS. 2 and 3, the fourth interconnection electrode layer 40E may be a conductive layer that connects the N-type compound semiconductor layers 140, 240, and 340 of the first to third LEDs 100A to 100C to the first electrode pad layer 11A of the backplane 110 to each other. Accordingly, the fourth interconnection electrode layer 40E may be expressed as a common electrode layer or an N-type common electrode layer.

The fourth interconnection electrode layer 40E may be provided on the first CBL 112 around and adjacent to the first, third, fifth, and seventh through holes 12h1, 12h3, 12h5, and 12h7, and may extend from the first through hole 12h1 to the seventh through hole 12h7 through the third through hole 12h3 and the fifth through hole 12h5. The fourth interconnection electrode layer 40E may be provided to fill the first, third, fifth, and seventh through holes 12h1, 12h3, 12h5, and 12h7. Accordingly, the fourth interconnection electrode layer 40E may be in contact with the first electrode pad layer 11A exposed through the first through hole 12h1, may be in contact with the second upper surface 14S2 of the first compound semiconductor layer 140 exposed through the third through hole 12h3, may be in contact with the second upper surface 24S2 of the third compound semiconductor layer 240 exposed through the fifth through hole 12h5, and may be in contact with the second upper surface 34S2 of the fifth compound semiconductor layer 340 exposed through the seventh through hole 12h7.

In the first micro-LED pixel 100, the N-type compound semiconductor layers 140, 240, and 340 of the first to third LEDs 100A, 100B, and 100C are connected to the first backplane 110 with one transparent common electrode layer (the fourth interconnection electrode layer) 40E, and the P-type compound semiconductor layers 144, 244, and 344 are connected to a driving transistor of the backplane 110 with a transparent conductive layer.

In this way, because each of the first to third LEDs 100A, 100B, and 100C of the first micro-LED pixel 100 is connected to the first backplane 110 through a transparent conductive layer (e.g., ITO layer), compared to existing hybrid bonding of LED to a backplane using copper, damage to a substrate may be reduced and productivity may be increased.

In addition, each of the first to third LEDs 100A, 100B, and 100C of the first micro-LED pixel 100, as will be described later, may be stacked on the first backplane 110 using a transfer method and bonding using an attachment layer after separately forming each of the first to third LEDs 100A, 100B, and 100C including a P-type electrode layer. Therefore, the process may be more simplified and free from damage caused by etching of the existing p-GaN layer. In addition, because each of the reflective layers 130, 230, and 330 is provided below each of the active layers 142, 242, and 342 of each of the first to third LEDs 100A, 100B, and 100C, light emitted downward from the active layers 142, 242, and 342 may be reflected upward. Accordingly, the amount of light emitted from each of the first to third LEDs 100A, 100B, and 100C may be increased, and as a result, the light efficiency or light emission efficiency of the first micro-LED pixel 100 may be increased.

FIGS. 2 and 3 are plan views of the first micro-LED pixel 100 of FIG. 1. FIG. 2 is a plan view omitting the first to fourth interconnection electrode layers 146E, 246E, 346E, and 40E in FIG. 1. FIG. 1 is a cross-sectional view taken along line 1-1′ of FIG. 3.

Referring to FIGS. 1 to 3 together, a planar shape of the first micro-LED pixel 100 and a planar shape of the first to third LEDs 100A, 100B, and 100C may be square, but are not limited thereto.

The first micro-LED pixel 100 may have a first length DS1 in a horizontal direction (e.g., X-axis direction) and a second length DS2 in a vertical direction perpendicular to the horizontal direction (e.g., Y-axis direction). One of the horizontal direction and the vertical direction may be expressed as a first direction, and the other may be expressed as a second direction.

For example, the first length DS1 may be less than or equal to 10 μm, less than or equal to 8 μm, less than or equal to 5 μm, or less than or equal to 4 μm, but embodiments are not limited thereto. For example, the second length DS2 may be less than or equal to 10 μm, less than or equal to 8 μm, less than or equal to 5 μm, or less than or equal to 4 μm, but embodiments are not limited thereto. For example, the first and second lengths DS1 and DS2 may be the same or different from each other within the above numerical range, but are not limited thereto. In the first micro-LED pixel 100, horizontal and vertical lengths of the first LED 100A may be less than the horizontal and vertical lengths DS1 and DS2 of the first micro-LED pixel 100.

Four electrode pad layers 11A to 11D are provided on the first backplane 110. One of each of the four electrode pad layers 11A to 11D are provided on each side of the first LED 100A, but embodiments are not limited thereto. The first electrode pad layer 11A may be provided adjacent to the third through hole 12h3 where the N-type compound semiconductor layer (first compound semiconductor layer) 140 of the first LED 100A is exposed. The second electrode pad layer 11B may be provided adjacent to the fourth through hole 12h4 where the P-type electrode layer (first transparent electrode layer) 146 of the first LED 100A is exposed. Because the third electrode pad layer 11C is connected to the P-type electrode layer (third transparent electrode layer) 346 of the third LED 100C, the third electrode pad layer 11C may be arranged taking this connection into consideration. Because the fourth electrode pad layer 11D is connected to the P-type electrode layer (second transparent electrode layer) 246 of the second LED 100B, the fourth electrode pad layer 11D may be arranged taking this into consideration.

For example, in each of the first to third LEDs 100A, 100B, and 100C, sizes of the third, fifth and seventh through holes 12h3, 12h5, and 12h7 through which the N-type compound semiconductor layers 140, 240, and 340 are exposed may be less than sizes of the fourth, sixth and eighth through holes 12h4, 12h6, and 12h8 through which the P-type electrode layers 146, 246, and 346 are exposed, but embodiments are not limited thereto. For example, sizes of the first to fourth through holes 12h1 to 12h4 through which the first to fourth electrode pad layers 11A to 11D are exposed may also be different, but are not limited thereto.

Referring to FIG. 3, the first to fourth interconnection electrode layers 146E, 246E, 346E, and 40E are spaced apart from each other.

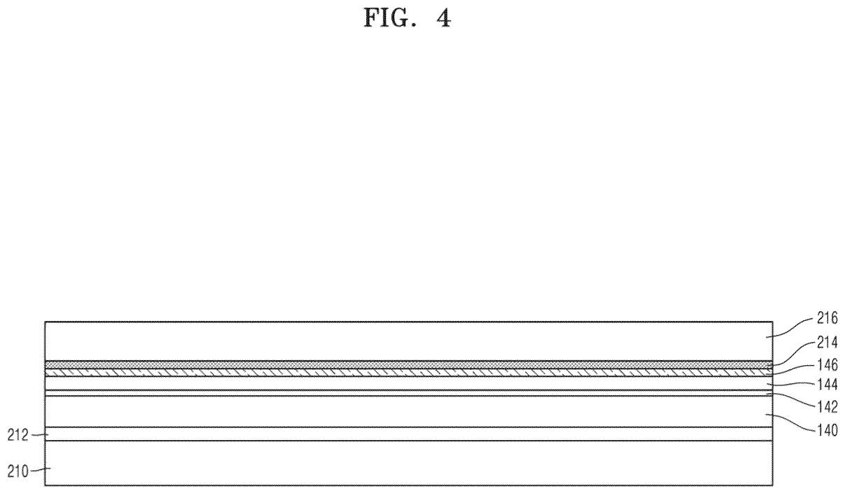

Next, a first method of manufacturing the first micro-LED pixel 100 of FIG. 1 will be described with reference to FIGS. 4 to 22. Reference numbers that are the same as those mentioned in the description of FIG. 1 indicate the same members, and description thereof will be omitted.

First, as shown in FIG. 4, a buffer layer 212 is formed on a growth base substrate 210. The buffer layer 212 may be formed by using an epitaxy method, but is not limited to this method. For example, the buffer layer 212 may include the same compound semiconductor layer as the first compound semiconductor layer 140 to be formed thereon. However, the buffer layer 212 may include an intrinsic compound semiconductor layer that does not include a dopant, but embodiments are not limited thereto. A first compound semiconductor layer 140, which is an n-type, may be formed on the buffer layer 212. The first compound semiconductor layer 140 may be formed by using a growth method, and an n-type dopant may be supplied during the formation. The first compound semiconductor layer 140 may be formed by using a method other than a growth method (e.g., chemical vapor deposition (CVD) method). A first active layer 142 may be formed on the first compound semiconductor layer 140. A second compound semiconductor layer 144, which is a p-type, may be formed on the first active layer 142. The first active layer 142 and the second compound semiconductor layer 144 may be formed by using a growth method, but are not limited to this method. A p-type dopant may be supplied during the formation of the second compound semiconductor layer 144, and the second compound semiconductor layer 144 and the active layer 142 may be formed by other methods other than the growth method.

A first transparent electrode layer 146 may be formed on the second compound semiconductor layer 144, and an attachment layer 214 for separation may be formed on the first transparent electrode layer 146. A temporary substrate 216 may be attached to the attachment layer 214. Afterwards, the growth base substrate 210 and the buffer layer 212 are removed.

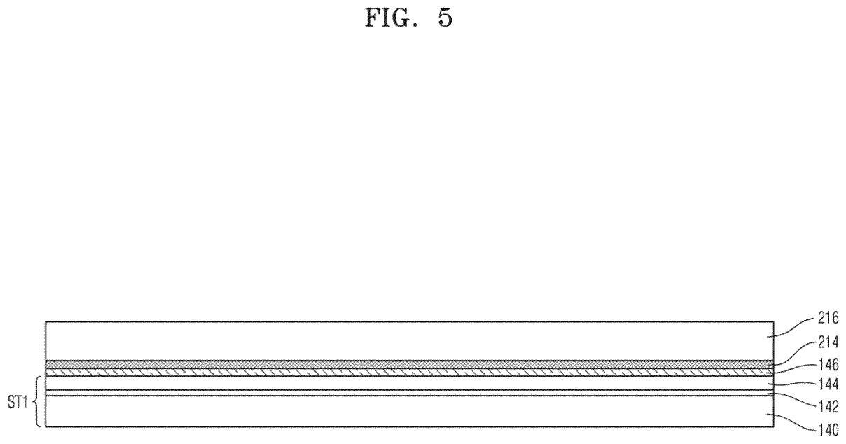

FIG. 5 shows a resultant product from which the growth base substrate 210 and the buffer layer 212 are removed.

In FIG. 5, a first stack ST1 may be a stack having a layer structure in which the first compound semiconductor layer 140, the first active layer 142, and the second compound semiconductor layer 144 are sequentially stacked. The first stack ST1 may be processed into the first LED 100A of FIG. 1 in a subsequent process. Accordingly, the first stack ST1 may be a first LED stack or a first light-emitting stack. For example, the first stack ST1 may include up to the first transparent electrode layer 146.

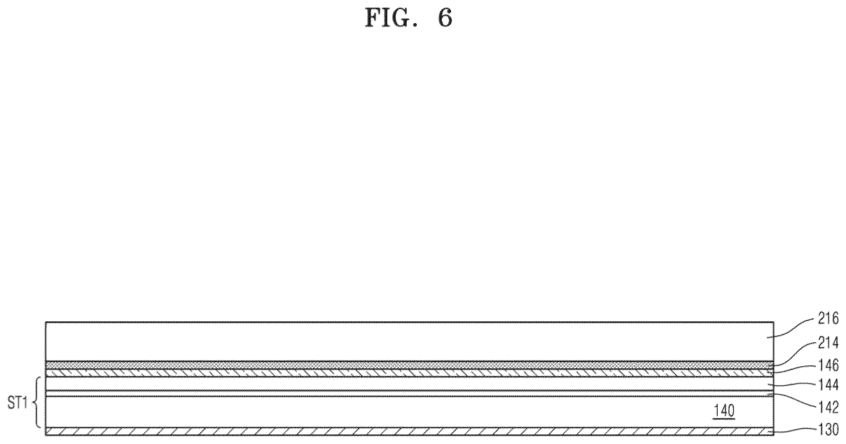

Next, as shown in FIG. 6, a first reflective layer 130 may be formed on the lower surface of the first compound semiconductor layer 140 from which the buffer layer 212 is removed. The first reflective layer 130 may be formed to cover the entire lower surface of the first compound semiconductor layer 140. A thickness of the first compound semiconductor layer 140 may be uniform in the vertical direction, and the lower surface thereof may be entirely flat.

In FIG. 6, the first stack ST1 may include the first transparent electrode layer 146 and/or the first reflective layer 130.

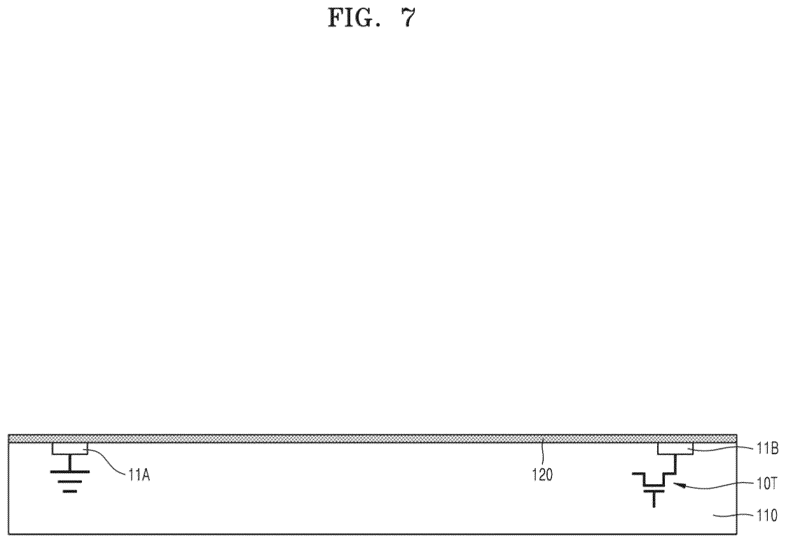

Next, as shown in FIG. 7, a first attachment layer 120 may be formed on the first backplane 110 including a driving transistor 10T and a plurality of electrode pad layers 11A and 11B. The first attachment layer 120 may be formed to cover an entire upper surface of the first backplane 110 and the entire electrode pad layers 11A and 11B.

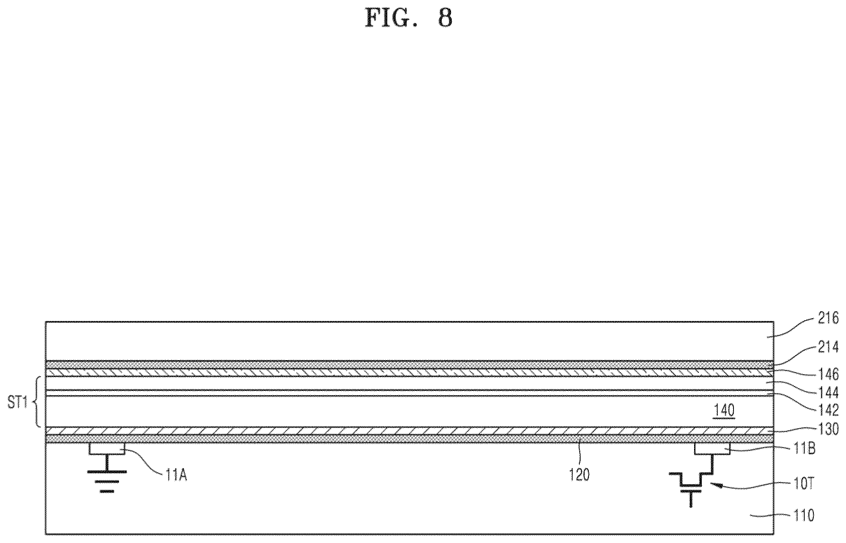

Next, as shown in FIG. 8, the resultant product shown in FIG. 6 is transferred onto the first reflective layer 130. In the transfer, a lower surface of the first reflective layer 130 may correspond to the upper surface of the first attachment layer 120. The transfer may be performed so that the entire lower surface of the first reflective layer 130 is attached to the entire upper surface of the first attachment layer 120.

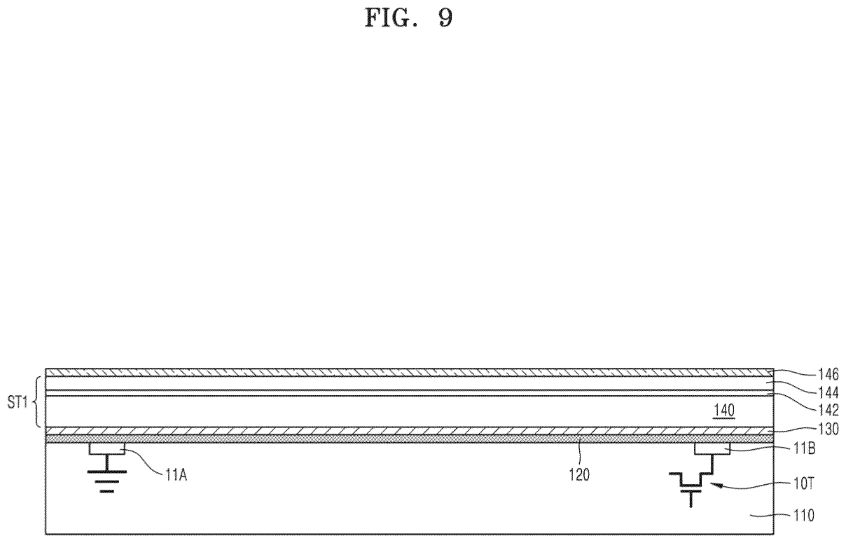

After the transfer is performed, the attachment layer 214 and the temporary substrate 216 are removed from the resultant product of FIG. 8. In this way, the first stack ST1 may be transferred onto the first backplane 110. The first stack ST1 may be processed into the first LED 100A illustrated in FIGS. 1 to 3 in a subsequent process. FIG. 9 shows a resultant product from which the attachment layer 214 and temporary substrate 216 in FIG. 8 are removed.

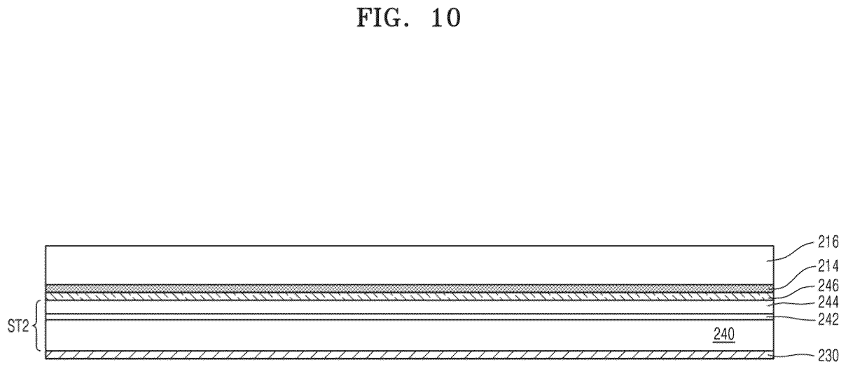

Next, as shown in FIG. 10, a second stack ST2 may be formed on a second reflective layer 230, a second transparent electrode layer 246 may be formed on the fourth compound semiconductor layer 244 of the second stack ST2, and the attachment layer 214 and the temporary substrate 216 are sequentially formed on the second transparent electrode layer 246.

A resultant product shown in FIG. 10 may be obtained by proceeding in the same manner as the manufacturing process described with reference to FIGS. 4 to 6.

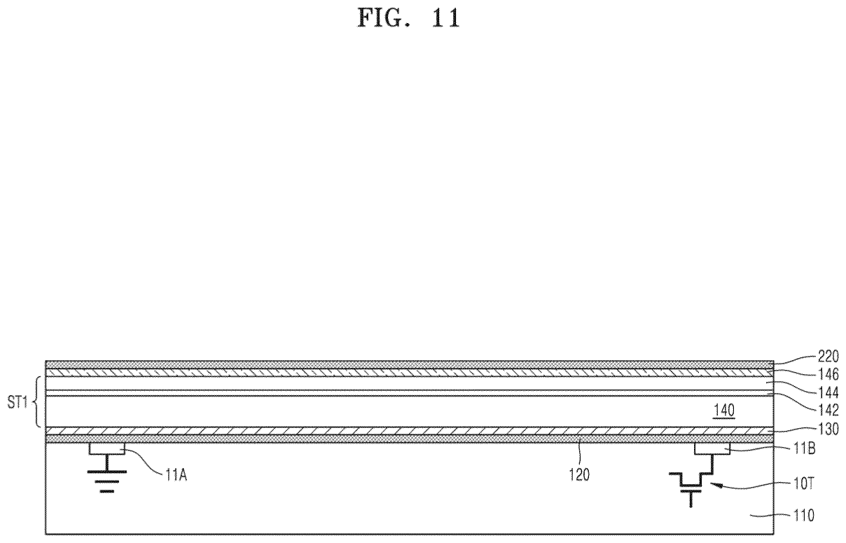

Next, as shown in FIG. 11, a second attachment layer 220 may be formed on the first transparent electrode layer 146. The second attachment layer 220 may be formed to cover an entire upper surface of the first transparent electrode layer 146.

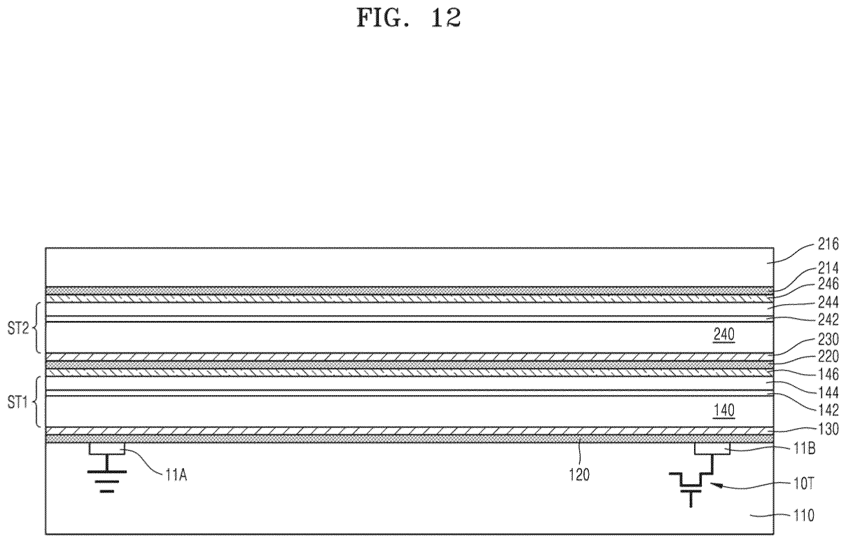

Next, as shown in FIG. 12, the resultant product of FIG. 10 is transferred onto the second attachment layer 220. This transfer may be performed so that a lower surface of the second reflective layer 230 faces the upper surface of the second attachment layer 220, and the entire lower surface of the second reflective layer 230 is in contact with the entire upper surface of the second attachment layer 220. Through this transfer, the second stack ST2 may be stacked on the first stack ST1. The layer structure (layer configuration) of the second stack ST2 may correspond to the second LED 100B of FIG. 1. The second stack ST2 may be processed into the second LED 100B in a subsequent process. Accordingly, the second stack ST2 may be expressed as a second LED stack or a second light-emitting stack. The second stack ST2 may also include the second reflective layer 230 and/or the second transparent electrode layer 246.

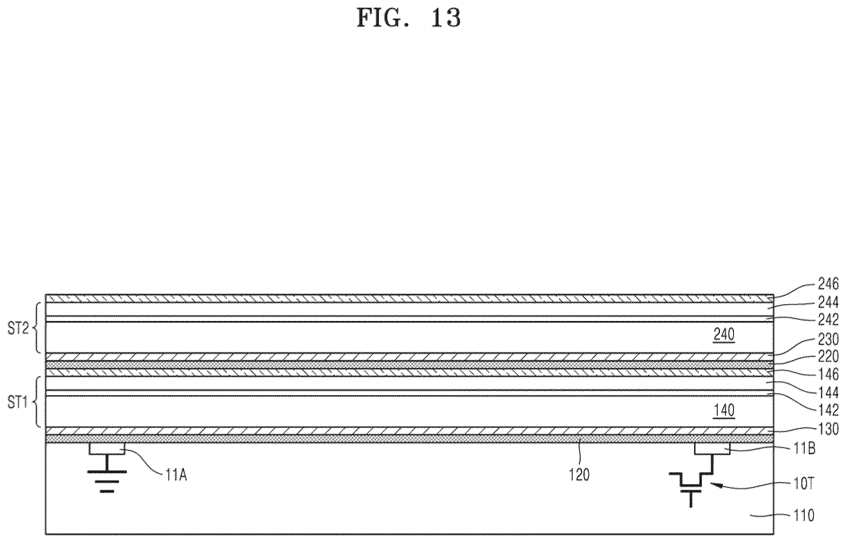

As shown in FIG. 13, after the transfer of the second stack ST2 is completed, the attachment layer 214 and the temporary substrate 216 are removed.

FIG. 13 shows a resultant product from which the attachment layer 214 and the temporary substrate 216 are removed from FIG. 12.

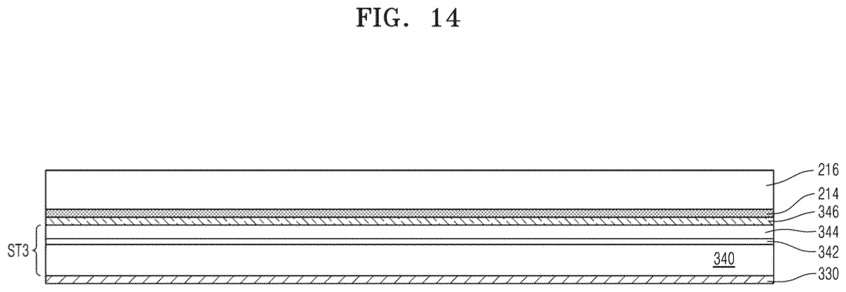

Next, as shown in FIG. 14, a third reflective layer 330, a third stack ST3, a third transparent electrode layer 346, the attachment layer 214, and the temporary substrate 216 are sequentially formed. The layer structure (layer configuration) of the third stack ST3 may correspond to the third LED 100C of FIG. 1. The third stack ST3 may be processed into the third LED 100C in a subsequent process. Accordingly, the third stack ST3 may be expressed as a third LED stack or a third light-emitting stack. For example, the third stack ST3 may also include the third reflective layer 330 and/or the third transparent electrode layer 346.

The resultant product of FIG. 14 may be obtained through the same manufacturing process as described with reference to FIGS. 4 to 6.

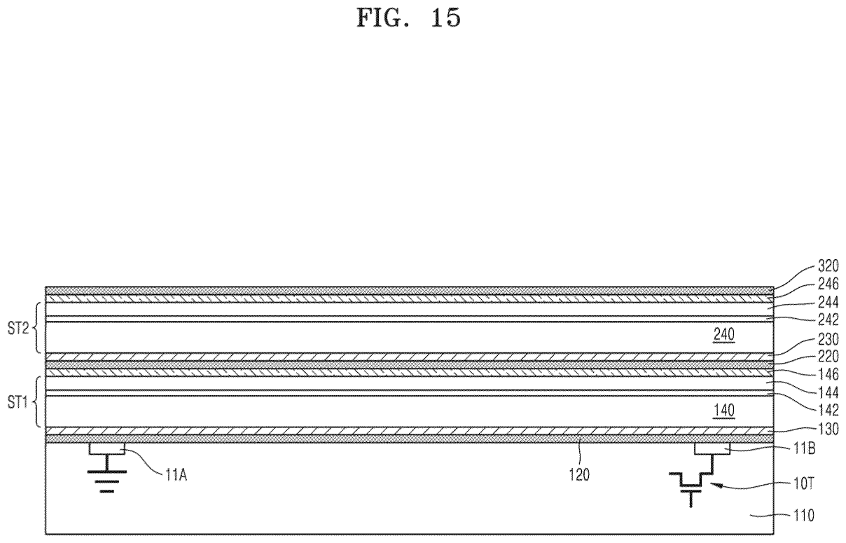

Next, as shown in FIG. 15, a third attachment layer 320 is formed on the second transparent electrode layer 246. The third attachment layer 320 may be formed to cover the entire upper surface of the second transparent electrode layer 246.

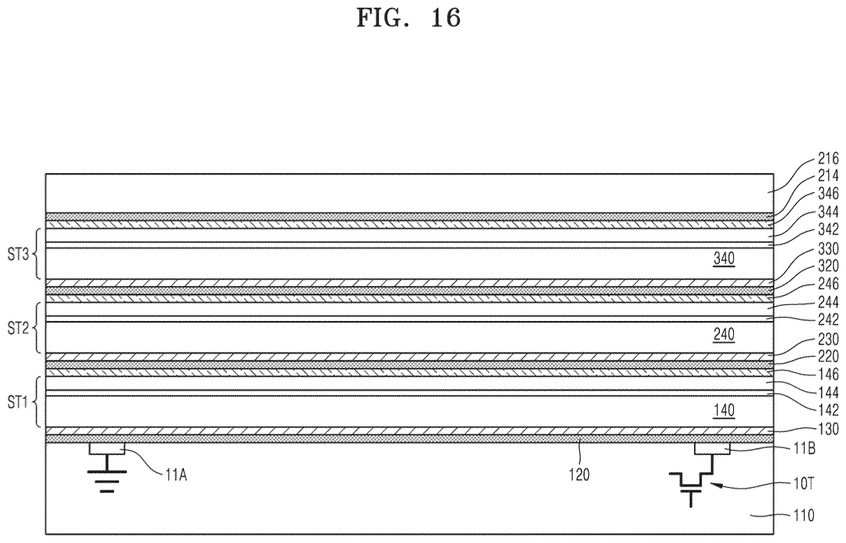

Next, as shown in FIG. 16, the resultant product of FIG. 14 is transferred onto the third attachment layer 320. The transfer may be performed, after moving the resultant product of FIG. 14 onto the third attachment layer 320 so that a lower surface of the third reflective layer 330 faces the upper surface of the third attachment layer 320, and then, in a method of contacting the entire lower surface of the third reflective layer 330 with the entire upper surface of the third attachment layer 320.

After the transfer of the resultant product shown in FIG. 14 is completed, the attachment layer 214 and the temporary substrate 216 in FIG. 16 are removed.

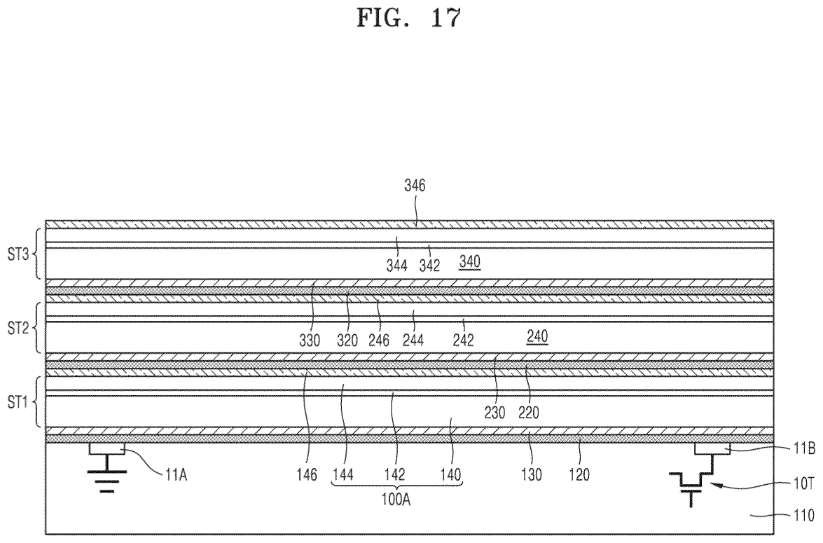

FIG. 17 shows a resultant product in which the attachment layer 214 and the temporary substrate 216 in FIG. 16 are removed.

Next, the resultant product of FIG. 17 is patterned to become a pattern corresponding to the first to third LEDs 100A, 100B, and 100C of FIG. 1 by applying a photo-etching process to the first to third stacks ST1, ST2, and ST3, the first to third attachment layers 120, 220, and 320, the first to third reflective layers 130, 230, and 330, and the first to third transparent electrode layers 146, 246, and 346 in the resultant product of FIG. 17.

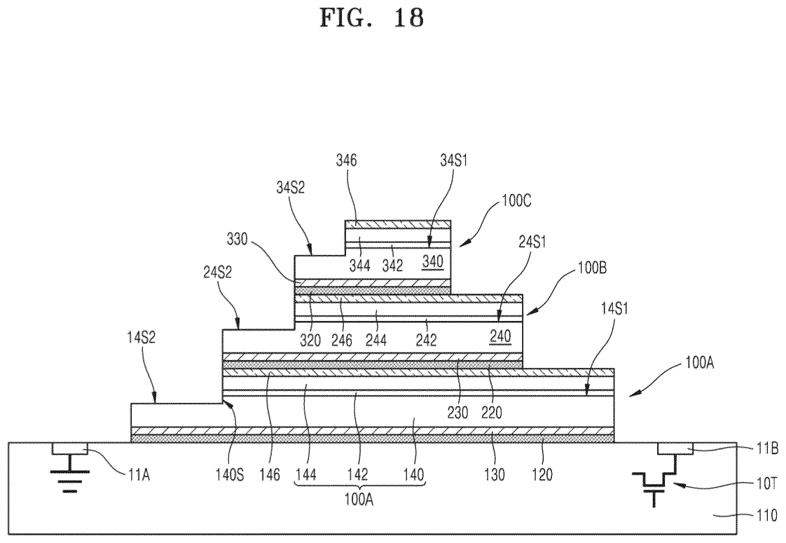

As shown in FIG. 18, through the patterning process, first to third LEDs 100A, 100B, and 100C may be formed sequentially stacked in the vertical direction on the first backplane 110.

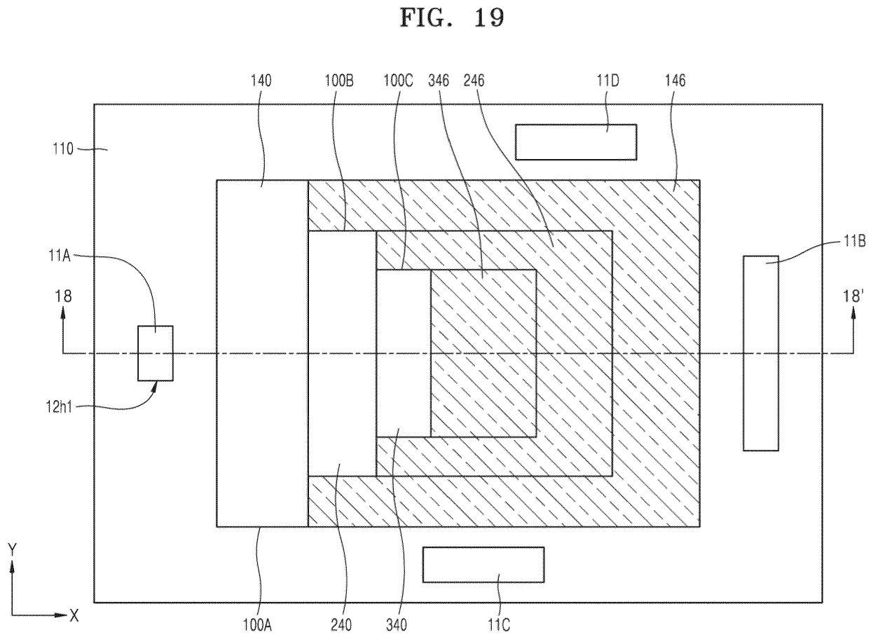

FIG. 19 is a plan view of a resultant product of FIG. 18. FIG. 18 may be a cross-sectional view taken along line 18-18′ of FIG. 19.

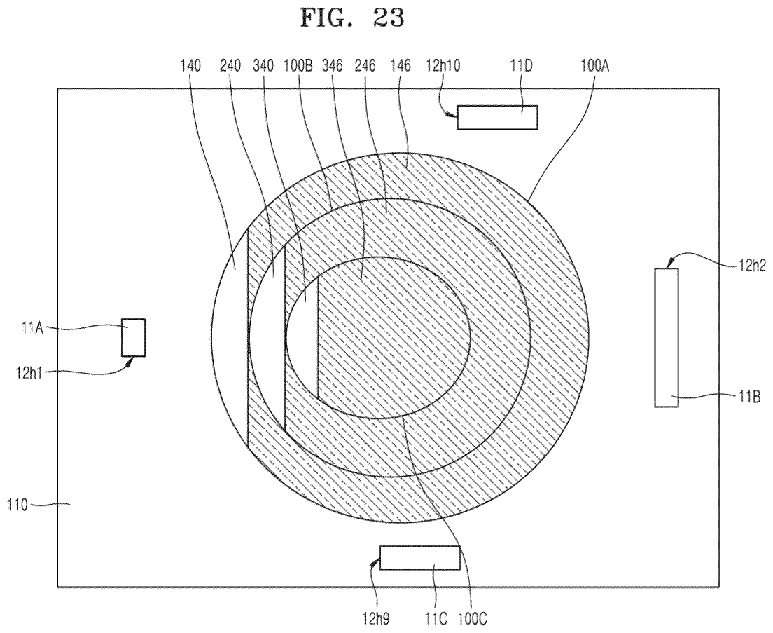

Referring to FIGS. 18 and 19, among the first to third LEDs 100A, 100B, and 100C, an area of the first LED 100A is the greatest, and the area becomes smaller as it moves toward the third LED 100C. A planar shape of the first to third LEDs 100A, 100B, and 100C may be square, but may also have other shapes. For example, as illustrated in FIG. 23, the planar shape of each of the first to third LEDs 100A, 100B, and 100C may be circular.

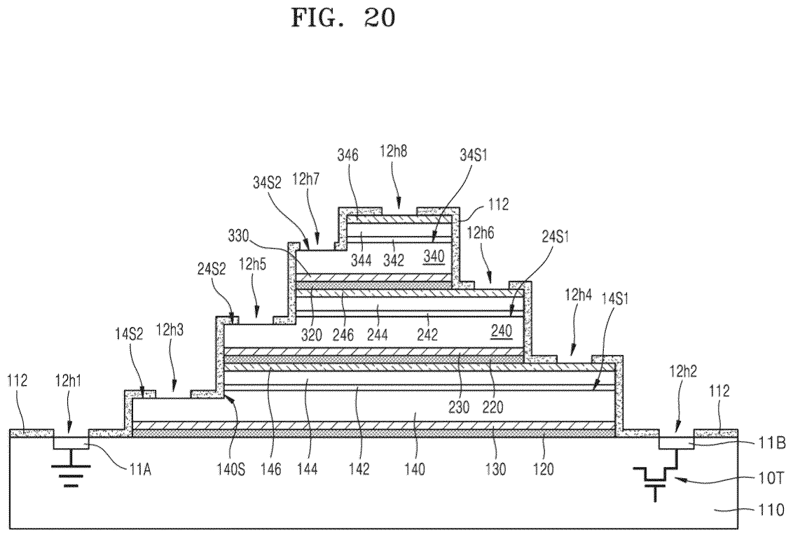

Next, as shown in FIG. 20, a first CBL 112 covering the first to third LEDs 100A, 100B, and 100C may be formed on the first backplane 110, and first to tenth through holes 12h1 to 12h10 described with reference to FIGS. 1 and 2 are formed in the first CBL 112.

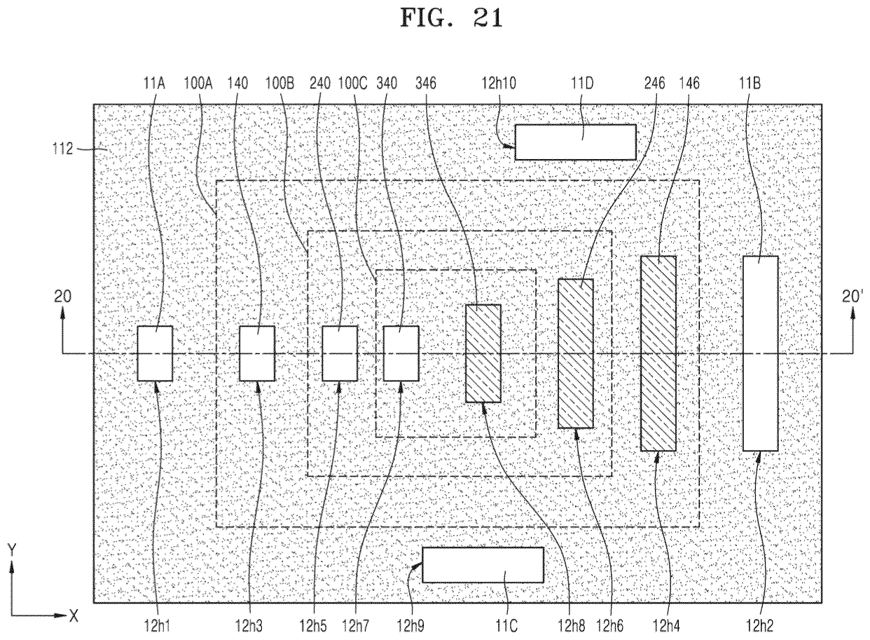

FIG. 21 is a plan view of a resultant product of FIG. 20. FIG. 20 may be a cross-sectional view taken along line 20-20′ of FIG. 21.

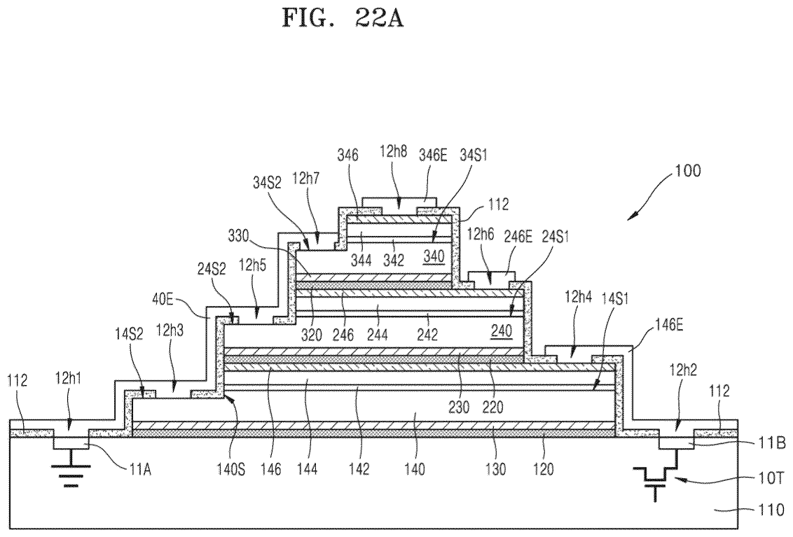

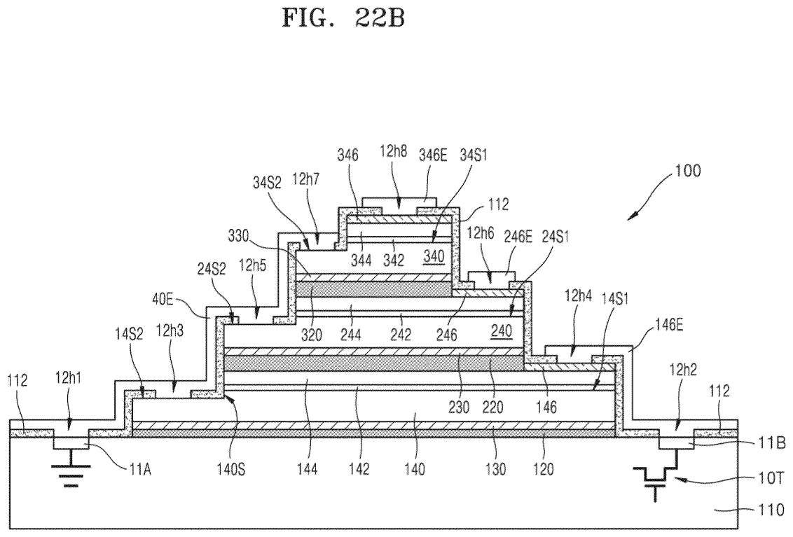

Next, as shown in FIG. 22A, the first to fourth interconnection electrode layers 146E, 246E, 346E, and 40E described with reference to FIG. 1 are formed on the first CBL 112. For example, regions where the first to fourth interconnection electrode layers 146E, 246E, 346E, and 40E will be formed may be defined (formed) by a mask, and the first to fourth interconnection electrode layers 146E, 246E, 346E, and 40E may be formed in the regions defined (formed) by the mask using a given deposition method, such as an atomic layer deposition (ALD) method. After the first to fourth interconnection electrode layers 146E, 246E, 346E, and 40E are formed, the mask may be removed. For example, the first to fourth interconnection electrode layers 146E, 246E, 346E, and 40E may be transparent electrode layers and may include ITO as a transparent electrode material but are not limited thereto.

In this way, the first micro-LED pixel 100 illustrated in FIG. 1 may be formed.

As also described with reference to FIG. 1, a portion of the first transparent electrode layer 146 corresponding to the second reflective layer 230 may be removed, and a region from which the portion of the first transparent electrode layer 146 is removed may be filled with the second attachment layer 220 as illustrated in FIG. 22B. A portion of the second transparent electrode layer 246 corresponding to the third reflective layer 330 may also be removed, and a region from which the portion of the second transparent electrode layer 246 is removed may be filled with the third attachment layer 320 as illustrated in FIG. 22B.

The planar shape of the first to third LEDs 100A, 100B, and 100C may be a square shape as shown in FIG. 19, but embodiments are not limited thereto, and for example, the shape may also be circular as shown in FIG. 23.

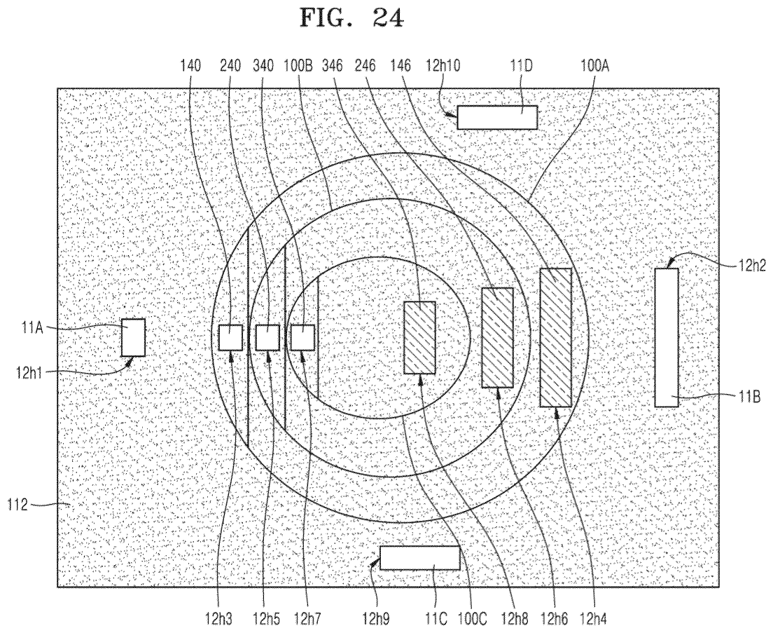

FIG. 24 is a diagram showing a result in which the first CBL 112 is formed on the first backplane 110 and the first to tenth through holes 12h1 to 12h10 are formed in the first CBL 112 in FIG. 23.

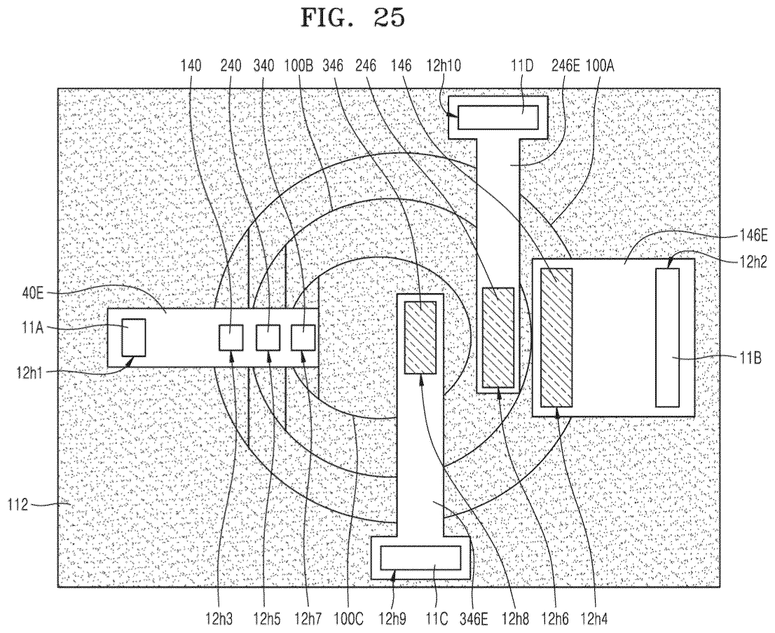

FIG. 25 shows a result in which the first to fourth interconnection electrode layers 146E, 246E, 346E, and 40E are formed in FIG. 24 in which the first to tenth through holes 12h1 to 12h10 are formed.

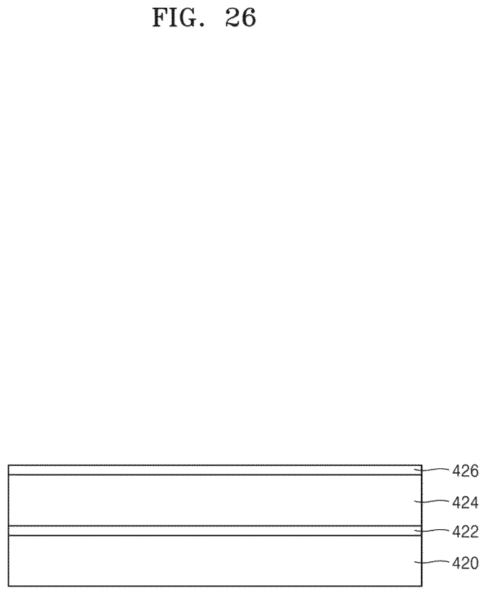

Next, a second method of manufacturing the first micro-LED pixel 100 of FIG. 1 will be described with reference to FIGS. 26 to 31. Reference numbers that are the same as those mentioned in the description of FIG. 1 indicate the same members, and description thereof will be omitted.

First, as shown in FIG. 26, a two-dimensional (2D) material layer 422 may be formed on a parent substrate 420. For example, the parent substrate 420 may include a material layer suitable for 2D material growth, and parent substrates of different materials may be used depending on the 2D material. For example, when the 2D material is graphene, a gallium arsenide (GaAs) substrate may be used as the parent substrate 420. For example, when h-BN is grown as a 2D material, a sapphire substrate may be used as the parent substrate 420.

A first LED stack 424 may be formed on the 2D material layer 422. For example, the first LED stack 424 may include a layer structure in which an n-type compound semiconductor layer, a first active layer, and a p-type compound semiconductor layer are sequentially stacked. The first active layer may correspond to the first active layer 142 of the first LED 100A of FIG. 1. For example, the first LED stack 424 may correspond to the first stack ST1 of the first manufacturing method described above.

A fourth transparent electrode layer 426 may be formed on the first LED stack 424. The fourth transparent electrode layer 426 may correspond to the first transparent electrode layer 146 formed on the first LED 100A of FIG. 1. After forming the fourth transparent electrode layer 426, the first LED stack 424 and the fourth transparent electrode layer 426 are separated from the 2D material layer 422.

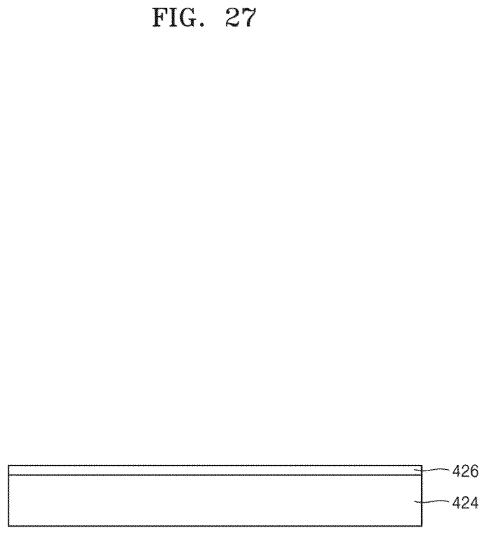

FIG. 27 shows the separated first LED stack 424 and the fourth transparent electrode layer 426.

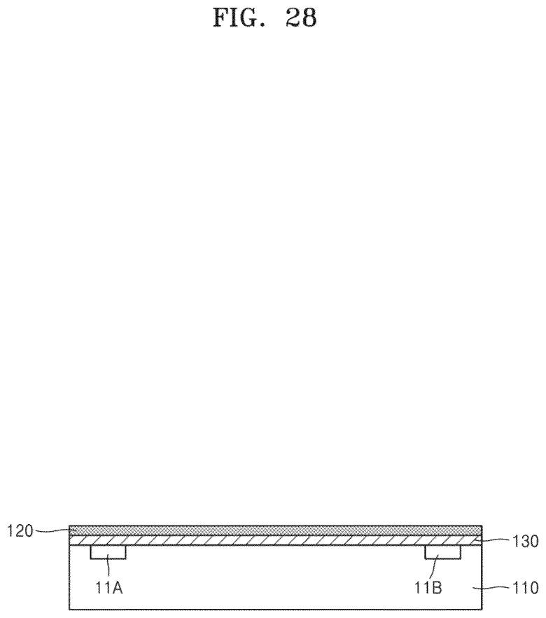

Next, as shown in FIG. 28, a first reflective layer 130 and a first attachment layer 120 are sequentially formed on the first backplane 110.

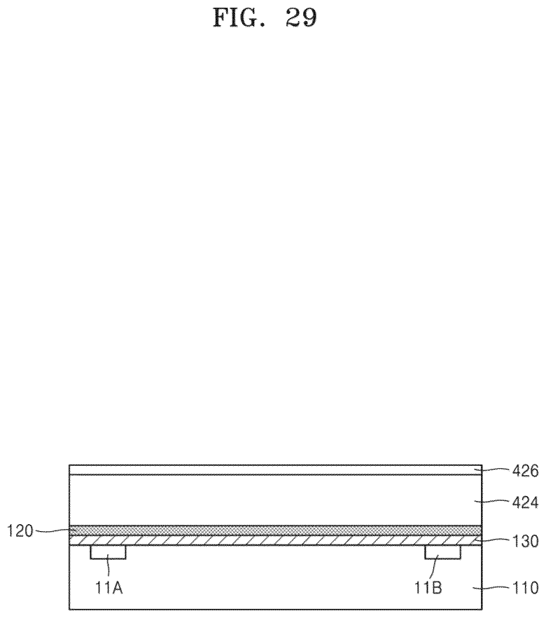

Next, as shown in FIG. 29, the first LED stack 424 of FIG. 27 is transferred onto the first attachment layer 120.

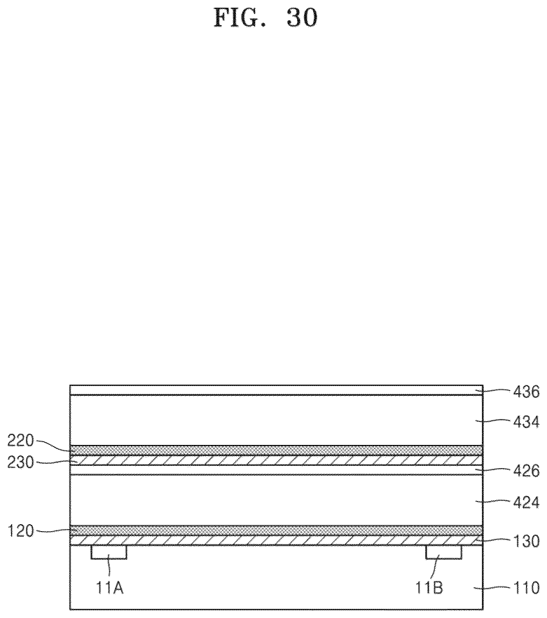

Next, as shown in FIG. 30, a second reflective layer 230 and a second attachment layer 220 are sequentially formed on the fourth transparent electrode layer 426. Next, a second LED stack 434 and a fifth transparent electrode layer 436, which are sequentially stacked, are transferred on the second attachment layer 220. The second LED stack 434 and the fifth transparent electrode layer 436 may be formed in the same manner as the method of forming the first LED stack 424 and the fourth transparent electrode layer 426 described with reference to FIGS. 26 and 27. As an example, the second LED stack 434 may include a layer structure in which an n-type compound semiconductor layer, a second active layer, and a p-type compound semiconductor layer are sequentially stacked. For example, the second LED stack 434 may correspond to the second stack ST2 of the first manufacturing method described above. The second active layer may correspond to the second active layer 242 of the second LED 100B of FIG. 1. A material of the fifth transparent electrode layer 436 may be the same as that of the fourth transparent electrode layer 426, but the materials may be different from each other.

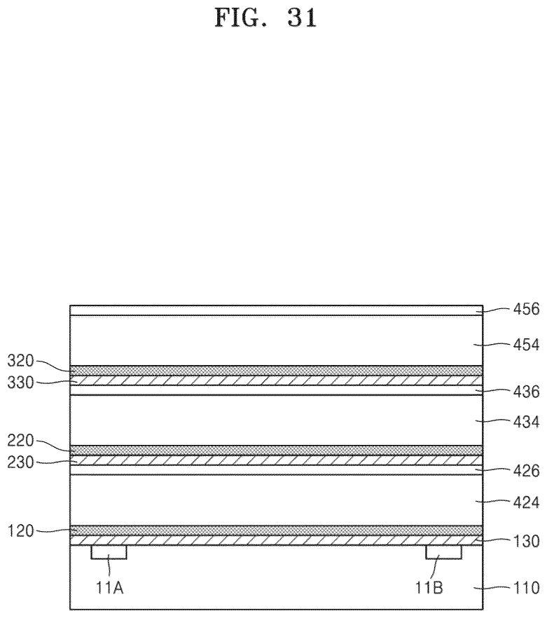

Next, as shown in FIG. 31, a third reflective layer 330 and a third attachment layer 320 are sequentially formed on the fifth transparent electrode layer 436. Next, a third LED stack 454 and a sixth transparent electrode layer 456, which are sequentially stacked, are transferred on the third attachment layer 320. The third LED stack 454 and the sixth transparent electrode layer 456 may be formed in the same manner as the method of forming the first LED stack 424 and the fourth transparent electrode layer 426 described with reference to FIGS. 26 and 27. The third LED stack 454 may include a layer structure in which an n-type compound semiconductor layer, a third active layer, and a p-type compound semiconductor layer are sequentially stacked. For example, the third LED stack 454 may correspond to the third stack ST3 of the first manufacturing method described above. The third active layer may correspond to the third active layer 342 of the third LED 100C of FIG. 1. A material of the sixth transparent electrode layer 456 may be the same as that of the fourth transparent electrode layer 426, but the materials may be different from each other.

After forming a resultant product shown in FIG. 31, a process for obtaining the resultant product shown in FIG. 18 (first to third LED formation processes), a process for obtaining the resultant product shown in FIG. 20 (CBL formation and through-hole formation process), and a process for obtaining the resultant product of FIG. 22A (interconnection electrode layer formation process) may be performed. During these processes, a process for obtaining the resultant product of FIG. 22B instead of the resultant product of FIG. 22A may be performed.

The resultant product of this process may be the same case as when the stacking order of the attachment layers 120, 220, and 320 and the reflective layers 130, 230, and 330 under each LED is reversed in FIGS. 22A and 22B.

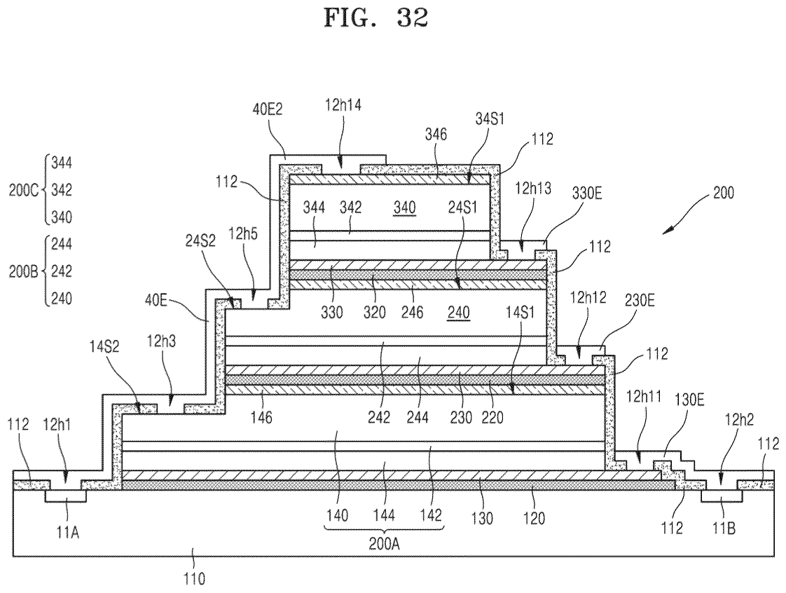

FIG. 32 shows a second type of vertically stacked micro-LED pixel 200 (hereinafter referred to as a second micro-LED pixel 200) according to one or more embodiments. The first micro-LED pixel 100 of FIG. 1 has a non-flip structure, and all of the p-type electrode layers or p-type compound semiconductor layers face upward in the vertically stacked first to third micro-LEDs 100A, 100B, and 100C. For example, the p-type compound semiconductor layer is provided on the active layer.

The second micro-LED pixel 200 has a flip structure, and all p-type compound semiconductor layers face downward. For example, a p-type compound semiconductor layer is provided below an active layer.

Referring to FIG. 32, an overall layer structure or layer configuration of the second micro-LED pixel 200 may be similar to that of the first micro-LED pixel 100. However, in each of LEDs 200A, 200B, and 200C of the second micro-LED pixel 200, p-type compound layers 144, 244, and 344, active layers 142, 242, and 342, and n-type compound semiconductor layers 140, 240, and 340 are sequentially stacked on reflective layers 130, 230, and 330. For example, in each of the LEDs 200A, 200B, and 200C, the p-type compound semiconductor layers 144, 244, and 344 are formed directly on the reflective layers 130, 230, and 330. Also, each of the transparent electrode layers 146, 246, and 346 is formed directly on each of the first upper surfaces 14S1, 24S1, and 34S1 of the n-type compound semiconductor layers 140, 240, and 340, respectively. The transparent electrode layers 146, 246, and 346 may be spaced apart from the p-type compound semiconductor layers 144, 244, and 344. In each of the LEDs 200A, 200B, and 200C, both side surfaces of the p-type compound semiconductor layers 144, 244, and 344 are covered with the first CBL 112.

A horizontal length of each of reflective layers 130, 230, and 330 under each of the LEDs 200A, 200B, and 200C is greater than a horizontal length of the p-type compound semiconductor layers 144, 244, and 344, and includes a portion extending beyond the horizontal length of the p-type compound semiconductor layers 144, 244, and 344. A horizontally extended portion of each of the reflective layers 130, 230, and 330 may be exposed through eleventh to thirteenth through holes 12h11, 12h12, and 12h13 of the first CBL 112. The extended portion of the first reflective layer 130 exposed through the eleventh through hole 12h11 is in contact with a fifth interconnection electrode layer 130E. The fifth interconnection electrode layer 130E is provided to connect the second electrode pad layer 11B of the first backplane 110 and the first reflective layer 130. A voltage applied to the first LED 200A through a driving transistor connected to the second electrode pad layer 11B may be applied to the p-type compound semiconductor layer 144 through the fifth interconnection electrode layer 130E and the first reflective layer 130. As a result, the first reflective layer 130 may function as a p-type electrode layer.

In this way, because the first reflective layer 130 not only reflects light but also functions as an electrode layer, the first reflective layer 130 may be expressed as a first reflective electrode or a first reflective electrode layer.

An extended portion of the second reflective layer 230 exposed through the twelfth through hole 12h12 is in contact with the sixth interconnection electrode layer 230E. The sixth interconnection electrode layer 230E is connected to a driving transistor provided in the first backplane 110 to drive the second LED 200B. A voltage supplied from a driving transistor provided to drive the second LED 200B of the first backplane 110 may be applied to the p-type compound semiconductor layer 244 through the sixth interconnection electrode layer 230E and the second reflective layer 230. Like the first reflective layer 130, the second reflective layer 230 may also function as a p-type electrode layer. Accordingly, the second reflective layer 230 may be expressed as a second reflective electrode or a second reflective electrode layer.

An extended portion of the third reflective layer 330 exposed through the thirteenth through hole 12h13 is in contact with the seventh interconnection electrode layer 330E. The seventh interconnection electrode layer 330E may be connected to a driving transistor provided in the first backplane 110 to drive the third LED 200C. A voltage supplied from a driving transistor of the first backplane 110 may be applied to the p-type compound semiconductor layer 344 of the third LED 200C through the seventh interconnection electrode layer 330E and the third reflective layer 330. Accordingly, the third reflective layer 330 may be expressed as a third reflective electrode or a third reflective electrode layer.

The first CBL 112 may include a fourteenth through hole 12h14 exposing a portion of the third transparent electrode layer 346 covering the upper surface 34S1 of the n-type compound semiconductor layer 340 on the third LED 200C. The fourteenth through hole 12h14 may be filled with the eighth interconnection electrode layer 40E2. Accordingly, an entire exposed portion of the third transparent electrode layer 346 exposed through the fourteenth through hole 12h14 may be in direct contact with the eighth interconnection electrode layer 40E2.

The eighth interconnection electrode layer 40E2 may be a common electrode layer like the fourth interconnection electrode layer 40E and may extend from the first through hole 12h1 exposing the first electrode pad layer 11A to the fourteenth through hole 12h14 through the third through hole 12h3 exposing the second upper surface 14S2 of the n-type compound semiconductor layer 140 of the first LED 200A and the fifth through hole 12h5 exposing the second upper surface 24S2 of the n-type compound semiconductor layer 240 of the second LED 200B. The eighth interconnection electrode layer 40E2 may fill the first through hole 12h1, the third through hole 12h3, the fifth through hole 12h5, and the fourteenth through hole 12h14, and may be in contact with the first electrode pad layer 11A, the second upper surface 14S2 of the n-type compound semiconductor layer 140 of the first LED 200A, the second upper surface 24S2 of the n-type compound semiconductor layer 140 of the second LED 200B, and the third transparent electrode layer 346.

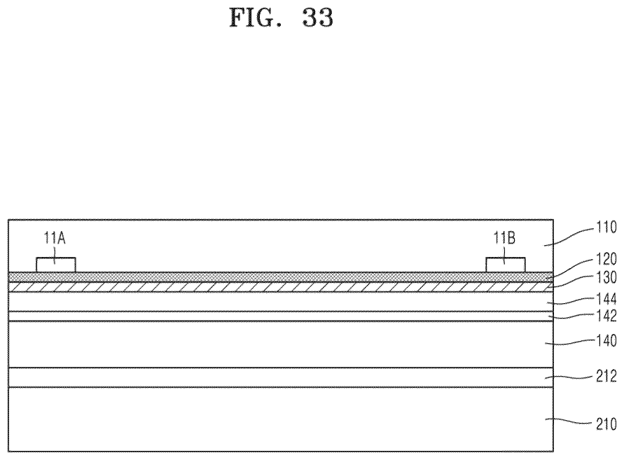

Next, a manufacturing method of the second micro-LED pixel 200 of FIG. 32 will be described with reference to FIGS. 33 to 47.

First, as shown in FIG. 33, the buffer layer 212, the n-type first compound semiconductor layer 140, the first active layer 142, and the p-type second compound semiconductor layer 144 are formed on the base substrate 210. For example, each of the layers 212, 140, 142, and 144 may be formed by using an epitaxy method, but the method embodiments are not limited thereto. After sequentially forming the first reflective layer 130 and the first attachment layer 120 on the second compound semiconductor layer 144, the first backplane 110 is formed on the first attachment layer 120. For example, the first backplane 110 may be transferred onto the first attachment layer 120 to be attached to the first attachment layer 120. For example, after forming the first attachment layer 120 on the first backplane 110, the first backplane 110 on which the first attachment 120 is formed may be transferred onto the first reflective layer 130. For example, the parent substrate 420 having the 2D layer 422 described with reference to FIG. 26 may be used as the base substrate 210.

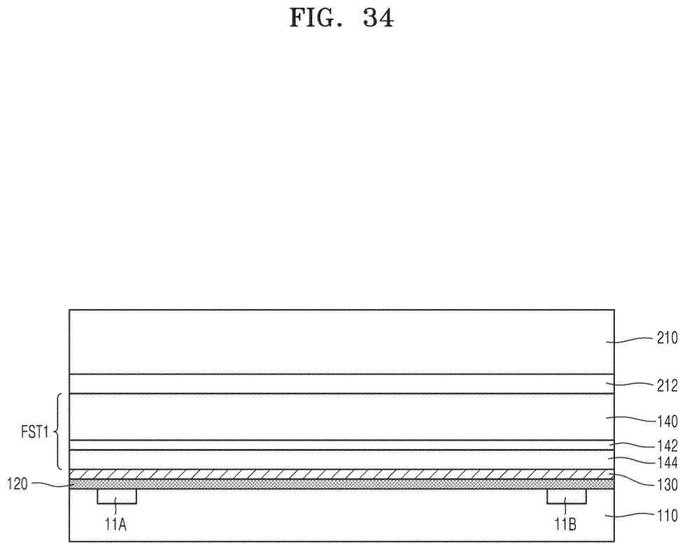

Next, a resultant product of FIG. 33 is flipped so that the first backplane 110 is located below and the base substrate 210 is located above, as shown in FIG. 34. Because the resultant product of FIG. 33 is reversed, the second compound semiconductor layer 144, which is a p-type compound semiconductor layer, may be located below the first active layer 142, and the first compound semiconductor layer 140, which is an n-type compound semiconductor layer, may be located below the first active layer. 142. For example, as the resultant product of FIG. 33 is reversed, the p-type compound semiconductor layer 144 may be located between the first active layer 142 and the first backplane 110.

The buffer layer 212 and the base substrate 210 are removed from a resultant product of FIG. 34.

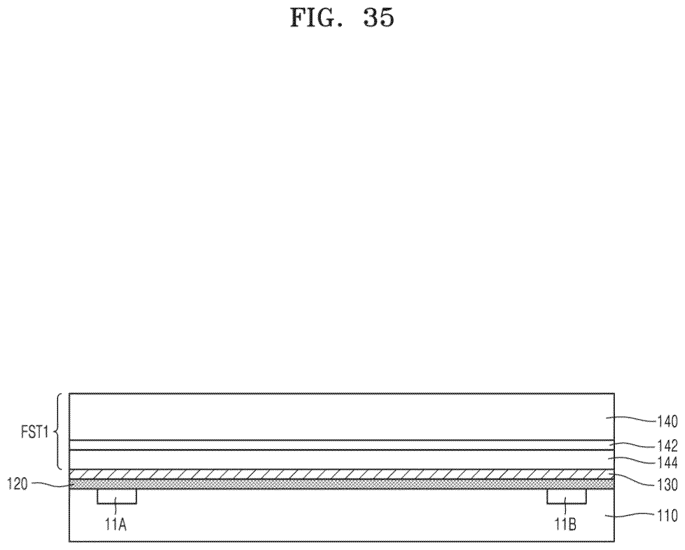

FIG. 35 shows a result of removing the buffer layer 212 and the base substrate 210 from FIG. 34.

In FIG. 35, a layer structure including the second compound semiconductor layer 144, the first active layer 142, and the first compound semiconductor layer 140 sequentially formed on the first reflective layer 130 may be expressed as a flip-type first stack FST1. For example, the flip-type first stack FST1 may also include the first reflective layer 130.

The layer structure or layer configuration of the flip-type first stack FST1 may correspond to the first LED 200A of FIG. 32. The flip-type first stack FST1 may be processed into the first LED 200A of FIG. 32 in a subsequent processing process. Accordingly, the flip-type first stack FST1 may be a flip-type first light-emitting stack or a flip-type first LED stack.

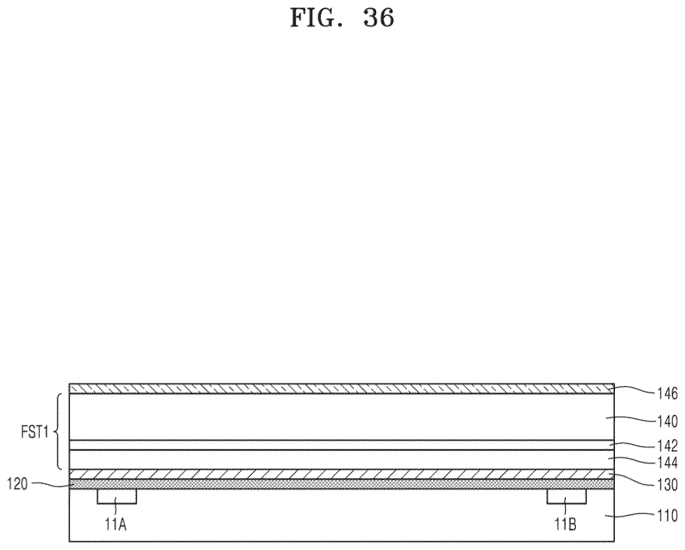

Next, as shown in FIG. 36, a first transparent electrode layer 146 may be formed on the first compound semiconductor layer 140. The first transparent electrode layer 146 may be formed to cover an entire upper surface of the first compound semiconductor layer 140 and may be in contact with the corresponding entire upper surface of the first compound semiconductor layer 140.

In FIG. 36, the flip-type first stack FST1 may also include the first transparent electrode layer 146 and/or the first reflective layer 130.

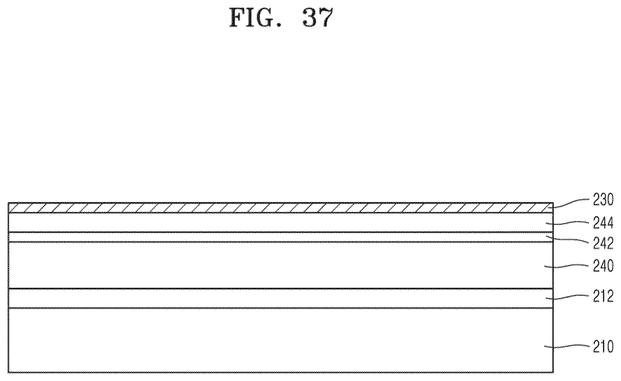

Next, as shown in FIG. 37, after preparing a separate base substrate 210, the buffer layer 212, the n-type third compound semiconductor layer 240, the second active layer 242, and the p-type fourth compound semiconductor layer 244 are sequentially formed on the separate base substrate 210. Next, the second reflective layer 230 may be formed on the fourth compound semiconductor layer 244.

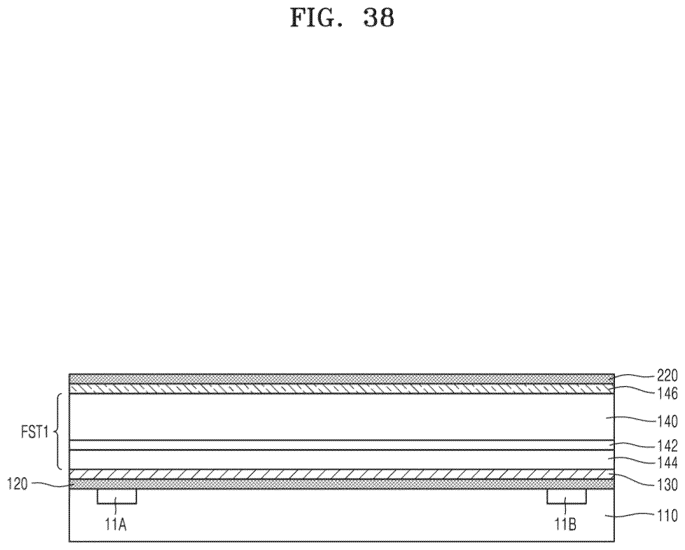

Next, as shown in FIG. 38, the second attachment layer 220 may be formed on the first transparent electrode layer 146.

Next, the resultant product of FIG. 37 is flipped and transferred onto a resultant product of FIG. 38 so that the second reflective layer 230 is transferred onto the resultant product of FIG. 38, that is, onto the second attachment layer 220. The transfer process may include a process for contacting the entire upper surface of the second reflective layer 230 with the entire upper surface of the second attachment layer 220 after turning over the resultant product of FIG. 37 and moving the resultant product of FIG. 37 onto the second attachment layer 220 in FIG. 38.

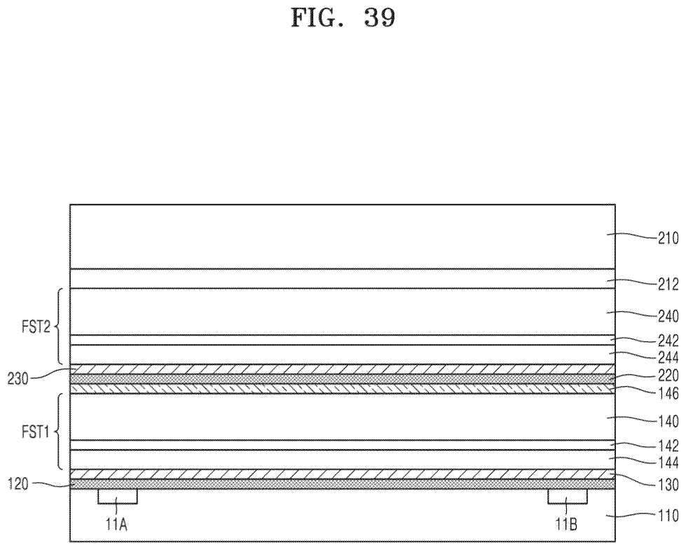

FIG. 39 is a diagram showing the completion of transfer.

In FIG. 39, a layer structure including the fourth compound semiconductor layer 244, the second active layer 242, and the third compound semiconductor layer 240 sequentially formed on the second reflective layer 230 may be expressed as a flip-type second stack FST2. The layer configuration of the flip-type second stack FST2 may correspond to the flip-type second LED 200B of FIG. 32. For example, the flip-type second stack FST2 may also include a second reflective layer 230. The flip-type second stack FST2 may be processed into the second LED 200B in a subsequent process. Accordingly, the flip-type second stack FST2 may be a flip-type second light-emitting stack.

In FIG. 39, the base substrate 210 and the buffer layer 212 may be removed.

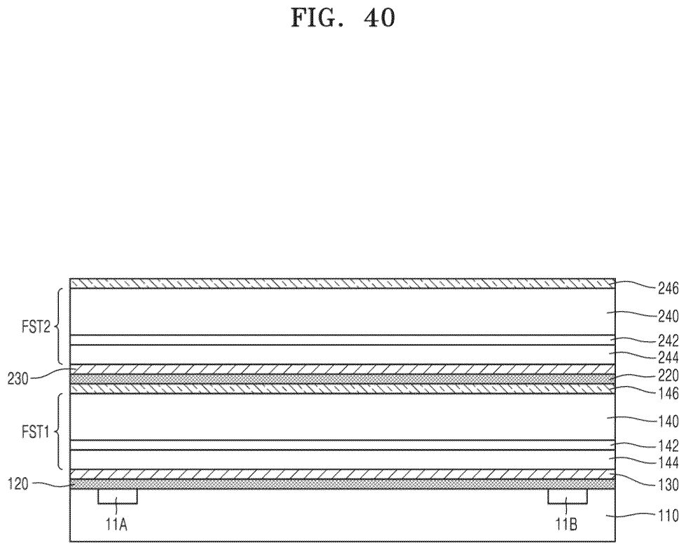

Next, as shown in FIG. 40, after removing the base substrate 210 and the buffer layer 212, the second transparent electrode layer 246 may be formed on an upper surface of the n-type third compound semiconductor layer 240.

For example, the flip-type second stack FST2 of FIG. 40 may also include the second reflective layer 230 and/or the second transparent electrode layer 246.

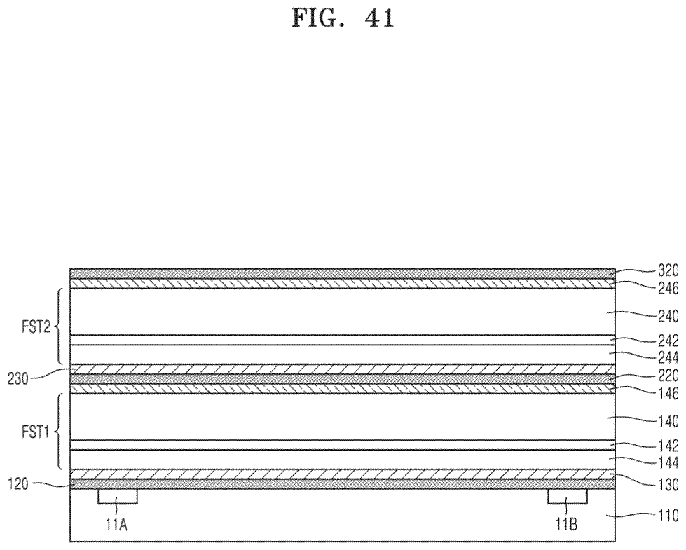

Next, as shown in FIG. 41, the third attachment layer 320 may be formed on the second transparent electrode layer 246. The third attachment layer 320 may be formed to cover the entire upper surface of the second transparent electrode layer 246 and may be in contact with the entire upper surface of the second transparent electrode layer 246.

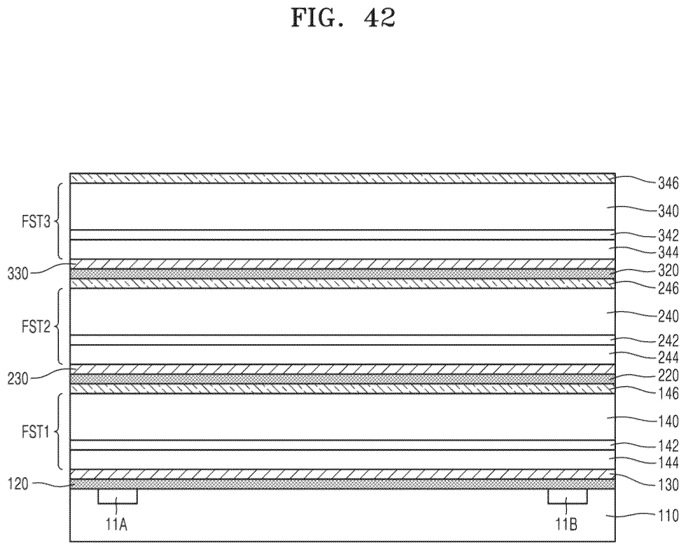

Next, as shown in FIG. 42, the third reflective layer 330, the p-type sixth compound semiconductor layer 344, the third active layer 342, and the n-type fifth compound semiconductor layer 340 may be sequentially formed on the third attachment layer 320. The third transparent electrode layer 346 may be formed on the fifth compound semiconductor layer 340. The sequentially formed third reflective layer 330, the sixth compound semiconductor layer 344, the third active layer 342, the fifth compound semiconductor layer 340, and the third transparent electrode layer 346 may be formed according to the formation and transfer processes illustrated in FIGS. 37 to 40

The sequentially formed stack of the sixth compound semiconductor layer 344, the third active layer 342, and the fifth compound semiconductor layer 340 may be expressed as a flip-type third stack FST3. The layer configuration of the flip-type third stack FST3 may correspond to the flip-type third LED 200C of FIG. 32. The flip-type third stack FST3 may be processed into the third LED 200C in a subsequent process. Accordingly, the flip-type third stack FST3 may be expressed as a flip-type third light-emitting stack or a flip-type third light-emitting structure.

For example, the third stack FST3 of FIG. 42 may also include the third reflective layer 330 and/or the third transparent electrode layer 346.

Next, the flip-type first to third stacks FST1, FST2, and FST3, the first to third attachment layers 120, 220, and 320, the first to third reflective layers 130, 230, and 330, and the first to third transparent electrode layers 146, 246, and 346 of FIG. 42 may be patterned using a photoetching process so that the resultant product of FIG. 42 is processed into the same form as the flip-type first to third LEDs 200A, 200B, and 200C shown in FIG. 32.

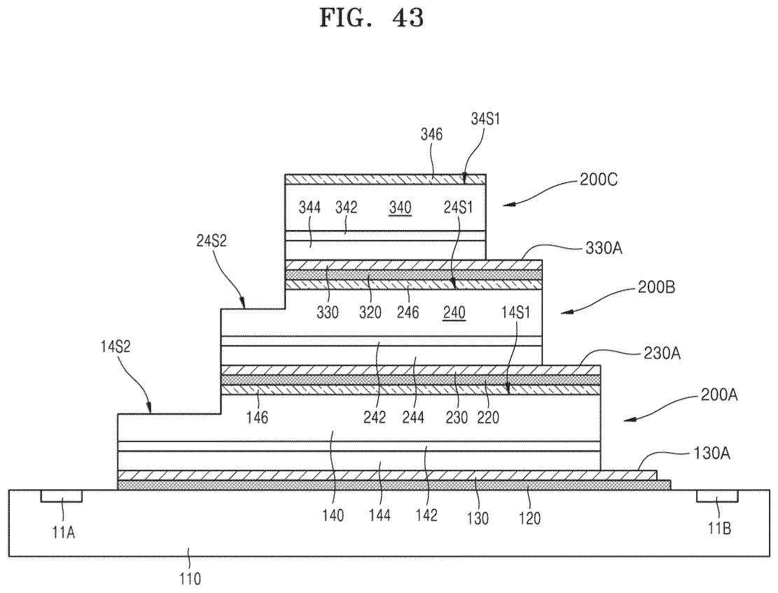

As a result of the patterning, as shown in FIG. 43, the flip-type first to third LEDs 200A, 200B, and 200C vertically sequentially stacked on the first backplane 110 between the first and second electrode pad layers 11A and 11B are formed. In the process of forming the first to third LEDs 200A, 200B, and 200C, a portion of the upper surface of each of the reflective layers 130, 230, and 330 provided below each of the LEDs 200A, 200B, and 200C may be exposed. The exposed portions 130A, 230A, and 330A of each of the reflective layers 130, 230, and 330 may be extended portions of the reflective layers 130, 230, and 330 and may contact the interconnection electrode layers 130E, 230E, and 330E.

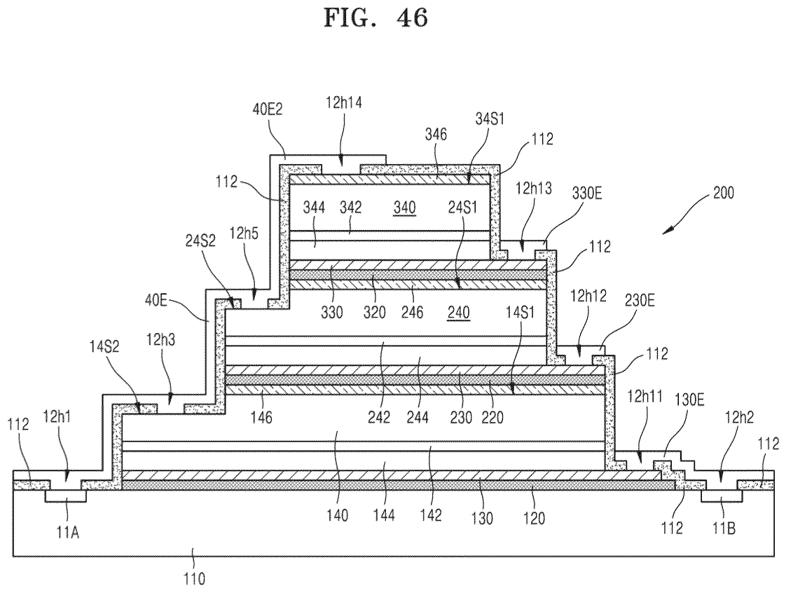

For example, each of the LEDs 200A, 200B, and 200C may also include the corresponding reflective layers 130, 230, and 330, and, as shown in FIG. 46, may also include a first CBL 112 and the corresponding interconnection electrode layers 130E, 230E, 330E, and 40E2.

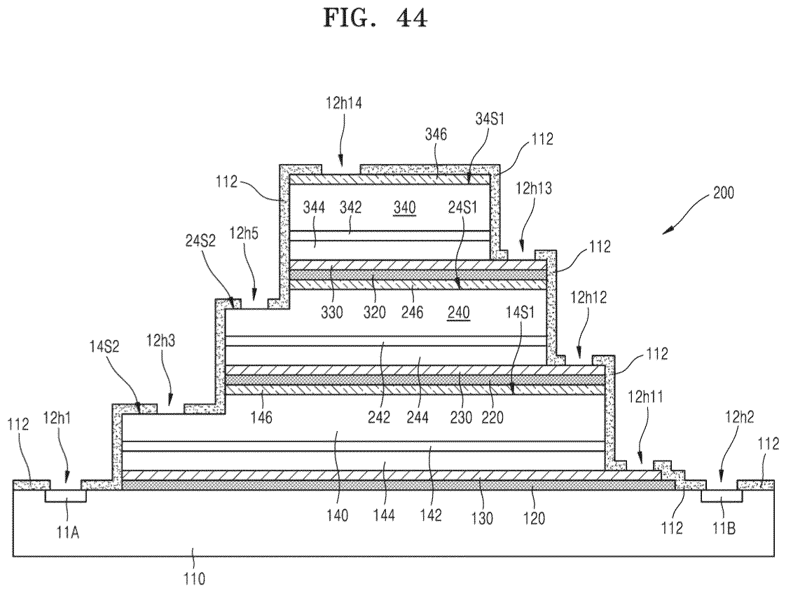

As shown in FIG. 43, after forming the first to third LEDs 200A, 200B, and 200C, as shown in FIG. 44, the first CBL 112 covering the first to third LEDs 200A, 200B, and 200C may be formed on the first backplane 110, and first, second, third, fifth, eleventh, twelfth, thirteenth and fourteenth through holes 12h1 to 12h3, 12h5, and 12h11 to 12h14 may be formed in the first CBL 112.

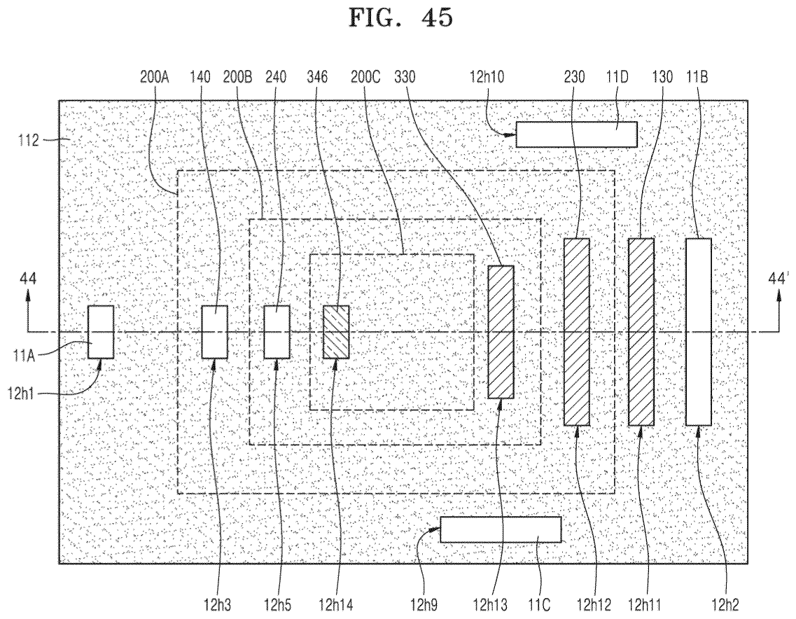

FIG. 45 is a plan view of FIG. 44. FIG. 44 may be a cross-sectional view taken along line 44-44′ of FIG. 45.

Referring to FIG. 45, a planar shape of the first to third LEDs 200A, 200B, and 200C may be square, but embodiments are not limited thereto. For example, the planar shape of the first to third LEDs 200A, 200B, and 200C may be a circular shape, similar to the planar shape of the non-flip first to third LEDs 100A, 100B, and 100C illustrated in FIG. 24.

In FIG. 45, sizes of the first, third, fifth, and fourteenth through-holes 12h1, 12h3, 12h5, and 12h14 may be relatively smaller than the sizes of the second, eleventh, twelfth, and thirteenth through holes 12h2, and 12h11-12h13.

After forming the first CBL 112 and the through holes 12h1-12h3, 12h5, and 12h11-12h14, as shown in FIG. 46, interconnection electrode layers 130E, 230E, 330E, and 40E2 that fill the through holes 12h1-12h3, 12h5, and 12h11-12h14 may be formed on the first CBL 112. The interconnection electrode layers 130E, 230E, 330E, and 40E2 may be in contact with surfaces exposed through the corresponding through holes 12h1-12h3, 12h5, and 12h11-12h14, respectively. The interconnection electrode layers 130E, 230E, 330E, and 40E2 may include a transparent conductive material layer (e.g., ITO) and may be formed by using an ALD method but are not limited thereto.

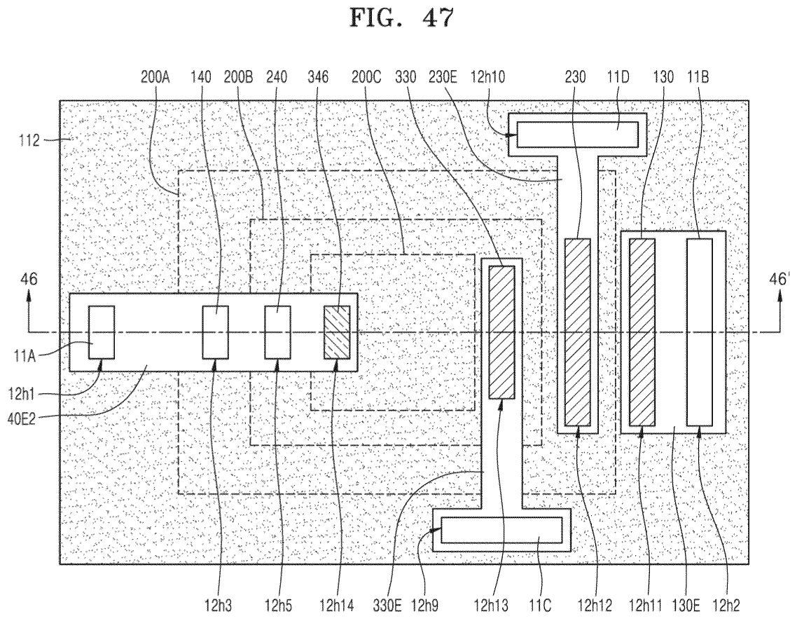

FIG. 47 is a plan view of FIG. 46. FIG. 46 may be a cross-sectional view taken along line 46-46′ of FIG. 47.

Referring to FIGS. 46 and 47 together, the fifth interconnection electrode layer 130E may be formed to connect the second electrode pad layer 11B of the first backplane 110 and the first reflective layer 130. The sixth interconnection electrode layer 230E may be formed to connect the fourth electrode pad layer 11D of the first backplane 110 and the second reflective layer 230. The seventh interconnection electrode layer 330E may be formed to connect the third electrode pad layer 11C of the first backplane 110 and the third reflective layer 330. The eighth interconnection electrode layer 40E2 may be formed to connect the n-type compound semiconductor layer 140 of the first LED 200A, the n-type compound semiconductor layer 240 of the second LED 200B, and the third transparent electrode layer 346 to the first electrode pad layer 11A of the backplane 110.

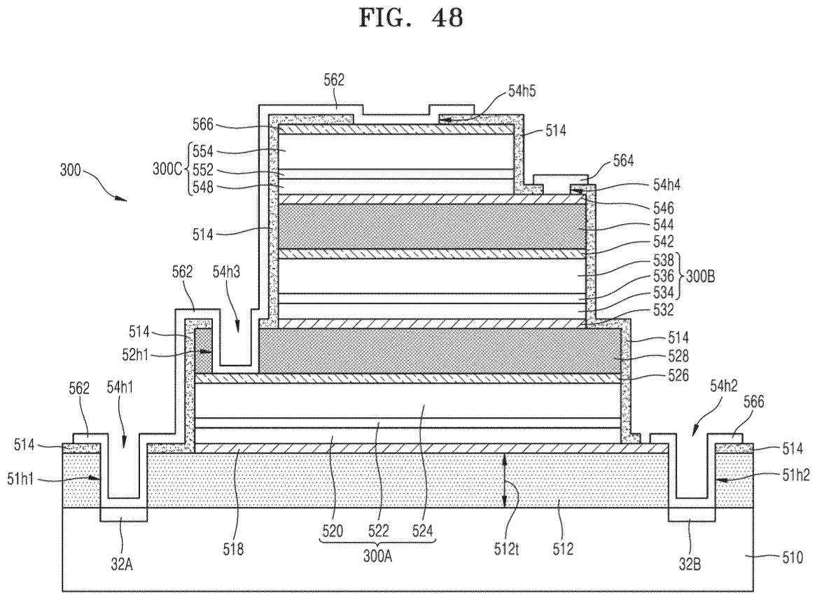

FIG. 48 shows a third type of vertically stacked micro-LED pixel 300 (hereinafter referred to as a third micro-LED pixel) according to one or more embodiments. The third micro-LED pixel 300 may be a first type Pentile micro-LED pixel.

Referring to FIG. 48, the third micro-LED pixel 300 is provided with a first attachment layer 512 on a second backplane 510. On the first attachment layer 512, first to third LEDs 300A, 300B, and 300C are sequentially stacked in a direction perpendicular to an upper surface of the first attachment layer 512.

The second backplane 510 may include elements for driving the first to third LEDs 300A, 300B, and 300C. For example, the second backplane 510 may include a first driving transistor for driving the first LED 300A, a second driving transistor for driving the second LED 300B, and a third driving transistor for driving the third LED 300C and may also include a control unit or a control circuit for controlling the operation of the first to third LEDs 300A, 300B, and 300C. The second backplane 510 may include a plurality of contact pads or electrode pads as contact regions for connecting the driving transistors and the first to third LEDs 300A, 300B, and 300C.

First and second electrode pad layers 32A and 32B provided to be spaced apart from each other on the second backplane 510 shown in FIG. 48 may be portions of the plurality of electrode pads. The first and second electrode pad layers 32A and 32B may be provided so that upper surfaces thereof are exposed. A height of the upper surfaces of the first and second electrode pad layers 32A and 32B may be the same as a height of an upper surface of the second backplane 510 in the vertical direction, but the heights may not be the same.

The first attachment layer 512 may include a first through hole 51h1 and a second through hole 51h2. The first electrode pad layer 32A may be exposed through the first through hole 51h1, and the second electrode pad layer 32B may be exposed through the second through hole 51h2. The first and second through holes 51h1 and 51h2 may be formed around and adjacent to the first LED 300A and spaced apart from the first LED 300A. The first attachment layer 512 may further include at least one through hole in addition to the first and second through holes 51h1 and 51h2 around and adjacent to the first LED 300A.

The first attachment layer 512 has a first thickness 512t. For example, the first attachment layer 512 may have a thickness greater than thicknesses of active layers 522, 536, and 552 and p-type compound semiconductor layers 520, 534, 548 of each of the LEDs 300A, 300B, and 300C, and greater than thicknesses of n-type compound semiconductor layers 524, 538, and 554, but embodiments are not limited thereto. For example, the first thickness 512t of the first attachment layer 512 may be greater than a total thickness of a layer including the p-type compound semiconductor layer 520, 534, and 548, the active layer 522, 536, and 552, and the n-type compound semiconductor layer 524, 538, and 554 of each of the LEDs 300A, 300B, and 300C. For example, the first thickness 512t may be in a range from about 0.5 μm to about 1.0 μm, in a range from about 0.5 μm to about 0.9 μm, in a range from about 0.5 μm to about 0.8 μm, or in a range from about 0.5 μm to about 0.7 μm, but may vary depending on a material used as the first attachment layer 512 or the thickness of each of the LEDs 300A, 300B, and 300C. For example, the material of the first attachment layer 512 may be the same as the material of the first attachment layer 120 of the first micro-LED pixel 100 described above, but the materials may be different from each other.

A first reflective layer 518 may be provided on the first attachment layer 512 between the first and second through holes 51h1 and 51h2. For example, the material of the first reflective layer 518 may be the same as, but may be different from, the material of the first reflective layer 130 of the first or second micro-LED pixels 100 and 200. For example, the function of the first reflective layer 518 may be the same as a function of the first reflective layer 130 of the first or second micro-LED pixels 100 and 200, but the functions may be different from each other. For example, a thickness of the first reflective layer 518 may be in a range from about 0.1 μm to about 0.2 μm or 0.15 μm and may be greater or less than 0.1 μm or greater or less than 0.2 μm depending on a material or thickness of other adjacent layers.

The first reflective layer 518 may be provided to be spaced apart from the first through hole 51h1 and close to the second through hole 51h2. For example, one end of the first reflective layer 518 may be spaced apart from the first through hole 51h1, but the other end of the first reflective layer 518 may be provided close to or in contact with an entrance of the second through hole 51h2. A second CBL 514 may be provided between the first reflective layer 518 and the first through hole 51h1. For example, a material of the second CBL 514 may be the same as, but may be different from, the material of the first CBL 112 of the first or second micro-LED pixels 100 and 200. For example, a thickness of the second CBL 514 may be in a range from about 0.1 μm to about 0.2 μm or about 0.15 μm. The thickness of the second CBL 514 may be greater or less than 0.1 μm or greater or less than 0.2 μm depending on a layer configuration or layer structure of each of the LEDs 300A, 300B, and 300C or the material of a layer included in each of the LEDs 300A, 300B, and 300C.

The first LED 300A may be provided on the first reflective layer 518. The first LED 300A may include a p-type first compound semiconductor layer 520, a first active layer 522, and an n-type second compound semiconductor layer 524 vertically sequentially stacked on an upper surface of the first reflective layer 518. A first transparent electrode layer 526 may be provided on the second compound semiconductor layer 524. The first transparent electrode layer 526 may be provided to cover an entire upper surface of the second compound semiconductor layer 524 and may be in direct contact with the entire upper surface of the second compound semiconductor layer 524.

For example, an overall thickness of the p-type first compound semiconductor layer 520, the first active layer 522, and the n-type second compound semiconductor layer 524 may be in a range from about 0.5 μm to about 0.6 μm, but embodiments are not limited thereto, and the thickness may vary depending on the material of each layer.

A horizontal length of the first compound semiconductor layer 520 may be less than a horizontal length of the first reflective layer 518. An entire lower surface of the first compound semiconductor layer 520 may be covered with the first reflective layer 518 and may be in direct contact with the first reflective layer 518. A thickness of the first compound semiconductor layer 520 may be constant or substantially constant over the entire region. For example, a material of the first compound semiconductor layer 520 may be the same as the material of the p-type second compound semiconductor layer 144 of the first LED 200A of the second micro-LED pixel 200. For example, among p-type compound semiconductor materials, the material of the first compound semiconductor layer 520 may be different from the material of the second compound semiconductor layer 144 of the first LED 200A of the second micro-LED pixel 200.

The first active layer 522 may be provided to cover an entire upper surface of the first compound semiconductor layer 520 and may be provided to contact the entire upper surface of the first compound semiconductor layer 520. For example, a material of the first active layer 522 may be the same as the material of the first active layer 142 of the first LED 100A of the first micro-LED pixel 100, but the materials may be different from each other. For example, the first active layer 522 may include a material capable of emitting light of a first wavelength or may include a material form (e.g., particles with a given diameter) capable of emitting light of the first wavelength. The first wavelength may include a wavelength included in the green light band. For example, the first wavelength may be a wavelength of green light or may include a wavelength of green light. A horizontal length of the first active layer 522 may be the same or substantially the same as the horizontal length of the first compound semiconductor layer 520. A thickness of the first active layer 522 may be less than the thickness of the first compound semiconductor layer 520.

The second compound semiconductor layer 524 may be provided to cover an entire upper surface of the first active layer 522 and may be in direct contact with the entire upper surface of the first active layer 522. A horizontal length (horizontal width) of the second compound semiconductor layer 524 may be the same or substantially the same as the horizontal length (horizontal width) of the first active layer 522, but embodiments are not limited thereto. For example, a material of the second compound semiconductor layer 524 may be the same as the material of the n-type first compound semiconductor layer 140 of the first LED 200A of the second micro-LED pixel 200. For example, among n-type compound semiconductor materials, the material of the second compound semiconductor layer 524 may be different from the material of the first compound semiconductor layer 140 of the first LED 200A of the second micro-LED pixel 200. For example, the second compound semiconductor layer 524 may include an n-type first compound semiconductor material, but the first compound semiconductor layer 140 may include an n-type second compound semiconductor material that is different from the n-type first compound semiconductor material.

A thickness of the second compound semiconductor layer 524 may be greater than the thickness of the first active layer 522 and the thickness of the first compound semiconductor layer 520.

A first transparent electrode layer 526 may be provided on the second compound semiconductor layer 524. A material of the first transparent electrode layer 526 may be the same as or different from the material of the first transparent electrode layer 146 of the second micro LED pixel 200 of FIG. 32. As an example, the first transparent electrode layer 526 may include a first transparent electrode material (e.g., ITO), and the first transparent electrode layer 146 of the second micro-LED pixel 200 may include a second transparent electrode material different from the first transparent electrode material.

The first transparent electrode layer 526 may be provided to cover an entire surface (e.g., upper surface) of the second compound semiconductor layer 524 and may be provided to contact the surface. For example, a surface (e.g., bottom surface) of the first transparent electrode layer 526 directly facing the second compound semiconductor layer 524 may be entirely covered with the second compound semiconductor layer 524, and may contact the second compound semiconductor layer 524. Accordingly, a horizontal length, that is, a horizontal width, of the first transparent electrode layer 526 may be the same as the horizontal length of the second compound semiconductor layer 524 but embodiments are not limited thereto. An entire thickness of the first transparent electrode layer 526 may be constant or substantially constant but embodiments are not limited thereto. A thickness of the first transparent electrode layer 526 may be less than a thickness of the second compound semiconductor layer 524 or the thickness 512t of the first attachment layer 512. For example, the thickness of the first transparent electrode layer 526 may be about 0.1 μm, but may be greater or less than 0.1 μm depending on the LED manufacturing process or the material used.

For example, the first LED 300A may also include the first reflective layer 518 and/or the first transparent electrode layer 526.

A second attachment layer 528 may be provided on the first transparent electrode layer 526. The second attachment layer 528 includes a third through hole 52h1 through which a portion of the first transparent electrode layer 526 is exposed. For example, the second attachment layer 528 may include at least one third through hole 52h1 but embodiments are not limited thereto. An entire surface (e.g., upper surface) of the first transparent electrode layer 526 around and adjacent to the third through hole 52h1 may be covered with the second attachment layer 528 and may be in contact with the second attachment layer 528. For example, a horizontal width of the third through hole 52h1, that is, a width of the third through hole 52h1, may be less than half, less than one-third, or less than one quarter of the horizontal length of the second attachment layer 528 but embodiments are not limited thereto. For example, an area of the first transparent electrode layer 526 exposed through the third through hole 52h1 may be less than half of the total area of the first transparent electrode layer 526 around and adjacent to the third through hole 52h1. For example, the area of the first transparent electrode layer 526 exposed through the third through hole 52h1 may be less than or equal to 30%, less than or equal to 20%, or less than or equal to 10% of the total area, but embodiments are not limited thereto. An entire surface (e.g., lower surface) of the second attachment layer 528 facing the first transparent electrode layer 526 may be covered with the first transparent electrode layer 526 and may be provided to contact the first transparent electrode layer 526.

For example, a thickness of the second attachment layer 528 may be equal to, greater than, or less than the thickness of the second compound semiconductor layer 524. For example, the thickness of the second attachment layer 528 may be the same as or different from the thickness of the first attachment layer 512. For example, a material of second attachment layer 528 may be the same as or different from the material of first attachment layer 512. For example, the second attachment layer 528, like the first attachment layer 512, may include a material that is transparent to visible light and has electrical insulation, or may include an insulating layer that is at least transparent to visible light.

The third through hole 52h1 may be provided closer to the left end of the second attachment layer 528 than to the right end of the second attachment layer 528. A second reflective layer 532 may be provided on the second attachment layer 528 around and adjacent to the third through hole 52h1. For example, the second reflective layer 532 may be provided on the second attachment layer 528 between the right end of the second attachment layer 528 and the third through hole 51h1. The second reflective layer 532 may be provided to be spaced apart from the third through hole 52h1 and to be spaced apart from the right end of the second attachment layer 528. A horizontal length (horizontal width) of the second reflective layer 532 may be less than a length (distance) from the third through hole 52h1 to the right end of the second attachment layer 528. Accordingly, a step difference may be provided between the second reflective layer 532 and the second attachment layer 528. For example, a height of one surface (e.g., upper surface) of the second reflective layer 532 may be higher than a height of an upper surface of the second attachment layer 528 around and adjacent to the one surface of the second reflective layer 532.

A second CBL 514 may be provided between the second reflective layer 532 and the third through hole 52h1. A surface (e.g., upper surface) of the second attachment layer 528 between the second reflective layer 532 and the third through hole 52h1 may be covered with the second CBL 514 and may be in direct contact with the second CBL 514. A surface (e.g., top surface) of the second attachment layer 528 between the second reflective layer 532 and the right end of the second attachment layer 528 may be covered with the second CBL 514 and may be in contact with the second CBL 514.

For example, an entire surface (e.g., lower surface) of the second reflective layer 532 facing one surface (e.g., upper surface) of the second attachment layer 528 may be covered with the one surface of the second attachment layer 528 and may be in contact with the one surface of the second attachment layer 528. For example, an area of a surface of the second reflective layer 532 facing the surface of the second attachment layer 528 may be less than half, 40% or less, or 30% or less of total area of the one surface of the second attachment layer 528. but embodiments are not limited thereto.

For example, a thickness and/or material of the second reflective layer 532 may be the same as or different from that of the first reflective layer 518. The upper surface of the second reflective layer 532 may be flat. For example, the thickness of the second reflective layer 532 may be constant or substantially constant as a whole.

A second LED 300B may be provided on the upper surface of the second reflective layer 532.

For example, the second LED 300B may include a p-type third compound semiconductor layer 534, a second active layer 536, and an n-type fourth compound semiconductor layer 538 sequentially stacked in a direction perpendicular to the upper surface of the second reflection layer 532 but is not limited to this configuration. A thickness relationship between the third compound semiconductor layer 534, the second active layer 536, and the fourth compound semiconductor layer 538 may be the same or substantially the same as the thickness relationship between the first compound semiconductor layer 520, the first active layer 522, and the second compound semiconductor layer 524. For example, materials of the third compound semiconductor layer 534, the second active layer 536, and the fourth compound semiconductor layer 538 may be the same as or different from the materials of the first compound semiconductor layer 520, the first active layer 522, and the second compound semiconductor layer 524, respectively.

For example, the third compound semiconductor layer 534 and the first compound semiconductor layer 520 may include different compound semiconductor materials selected from among a plurality of different p-type compound semiconductor materials, but may include the same compound semiconductor material.

For example, the fourth compound semiconductor layer 538 and the second compound semiconductor layer 524 may include different compound semiconductor materials selected from among a plurality of different n-type compound semiconductor materials, but may include the same compound semiconductor material.

For example, the second active layer 536 may include a material that emits light of a second wavelength, for example, a material configured to emit light of a wavelength that does not belong to the green light band. For example, light of the second wavelength emitted from the second active layer 536 may be red light (R) or blue light (B).

The third compound semiconductor layer 534 may be provided on one surface (e.g., upper surface) of the second reflective layer 532. The third compound semiconductor layer 534 may be provided to cover the entire surface of the second reflective layer 532 and may be in contact with the entire surface of the second reflective layer 532. For example, the third compound semiconductor layer 534 may be provided so that an entire lower surface of the third compound semiconductor layer 534 is in contact with the entire surface of the second reflective layer 532. A horizontal length of the third compound semiconductor layer 534 may be the same or substantially the same as a horizontal length of the second reflective layer 532. Therefore, positions of both ends of the third compound semiconductor layer 534 and positions of both ends of the second reflective layer 532 in the horizontal direction may be the same. For example, a side surface of the third compound semiconductor layer 534 and a side surface of the second reflective layer 532 may form the same plane.

As a result, a total area of the lower surface of the third compound semiconductor layer 534 may be the same or substantially the same as a total area of the one surface of the corresponding second reflective layer 532.

The second active layer 536 may be provided on one surface (e.g., upper surface) of the third compound semiconductor layer 534. The second active layer 536 may be provided to cover an entire upper surface of the third compound semiconductor layer 534 and be in contact with the entire surface of the third compound semiconductor layer 534. For example, an entire surface (e.g., lower surface) of the second active layer 536 corresponding to the surface of the third compound semiconductor layer 534 may be covered with the surface of the third compound semiconductor layer 534, and may be in contact with the surface of the third compound semiconductor layer 534. A horizontal length of the second active layer 536 may be the same or substantially the same as the horizontal length of the third compound semiconductor layer 534. In the horizontal direction, positions of both ends of the second active layer 536 may be the same or substantially the same as the positions of both ends of the third compound semiconductor layer 534.

As a result, an area of the lower surface of the second active layer 536 may be the same or substantially the same as the area of the surface of the third compound semiconductor layer 534. Accordingly, a geometric shape of the second active layer 536 on a plane and a geometric shape of the third compound semiconductor layer 534 on a plane may be the same or substantially the same. Additionally, the geometrical shape of the third compound semiconductor layer 534 on the plane and a geometrical shape of the second reflective layer 532 may be the same or substantially the same on the plane.

The fourth compound semiconductor layer 538 may be provided on one surface (e.g., upper surface) of the second active layer 536. The fourth compound semiconductor layer 538 may be provided to cover the entire surface of the second active layer 536 and be provided to be in contact with the entire surface of the second active layer 536. An entire surface (e.g., lower surface) of the fourth compound semiconductor layer 538 facing the surface of the second active layer 536 may be covered with the surface of the second active layer 536 and may be in contact with the surface of the second active layer 536. An area of the lower surface of the fourth compound semiconductor 538 may be the same or substantially the same as the area of the surface of the second active layer 536. A horizontal length of the fourth compound semiconductor layer 538 may be the same or substantially the same as the horizontal length of the second active layer 536. Also, positions of both ends of the fourth compound semiconductor layer 538 in the horizontal direction may coincide or substantially coincide with the positions of both ends of the second active layer 536.

As a result, a geometric shape of the fourth compound semiconductor layer 538 on a plane may be the same or substantially the same as the geometric shape of the second active layer 536. This suggests that the fourth compound semiconductor layer 538 and the second active layer 536 may completely overlap or substantially overlap each other in the vertical direction.

A thickness of the fourth compound semiconductor layer 538 may be greater than the thickness of the second active layer 536 and the third compound semiconductor layer 534.

A second transparent electrode layer 542 may be provided on the fourth compound semiconductor layer 538. The second transparent electrode layer 542 may be provided to cover an entire surface (e.g., upper surface) of the fourth compound semiconductor layer 538 and may be provided to contact the entire surface of the fourth compound semiconductor layer 538.

An entire lower surface of the second transparent electrode layer 542 may be provided to face the entire surface of the fourth compound semiconductor layer 538 and to contact the entire surface of the fourth compound semiconductor layer 538. Additionally, a horizontal length of the second transparent electrode layer 542 may be the same or substantially the same as the horizontal length of the fourth compound semiconductor layer 538. As a result, a geometric shape of the second transparent electrode layer 542 on a plane may be the same or substantially the same as the geometric shape of the fourth compound semiconductor layer 538. For example, the entire second transparent electrode layer 542 may completely overlap or substantially overlap the entire fourth compound semiconductor layer 538.

A material (substance) of the second transparent electrode layer 542 may be the same as or different from the material (substance) of the first transparent electrode layer 526. For example, among a plurality of different transparent electrode material groups, the first and second transparent electrode layers 526 and 542 may include the same or different transparent electrode materials.

For example, the second LED 300B may also include the second reflective layer 532 and/or the second transparent electrode layer 542.

A third attachment layer 544 may be provided on the second transparent electrode layer 542. The third attachment layer 544 may be provided to cover an entire surface (e.g., upper surface) of the second transparent electrode layer 542 and may be provided to contact the entire surface of the second transparent electrode layer 542. An entire lower surface of the third attachment layer 544 may face the entire surface of the second transparent electrode layer 542. The entire lower surface of the third attachment layer 544 may be in contact with the entire surface of the second transparent electrode layer 542. A horizontal length of the third attachment layer 544 may be the same or substantially the same as the horizontal length of the second transparent electrode layer 542. As a result, a geometric shape of the third attachment layer 544 in a plane may be the same or substantially the same as the geometric shape of the second transparent electrode layer 542. Accordingly, the third attachment layer 544 and the second transparent electrode layer 542 may completely overlap or substantially overlap each other. For example, the third attachment layer 544 may have a thickness corresponding to the thickness of the fourth compound semiconductor layer 538 or may have a thickness greater or less than the thickness of the fourth compound semiconductor layer 538, but embodiments are not limited thereto. For example, the thickness of the third attachment layer 544 may be the same as or different from the thickness of the second attachment layer 528.

For example, a material of third attachment layer 544 may be the same as or different from the material of second attachment layer 528. For example, among a plurality of different attachment materials that are transparent to at least visible light and electrically insulating, the second attachment layer 528 and the third attachment layer 544 may include the same attachment material or different attachment materials.

A third reflective layer 546 may be provided on the third attachment layer 544.

The third reflective layer 546 may be provided to reflect light emitted downward from the third LED 300C provided on the third reflective layer 546 upward. The third reflective layer 546 may be provided to cover an entire surface (e.g., upper surface) of the third attachment layer 544 and to contact the entire surface of the third attachment layer 544. An entire lower surface of the third reflective layer 546 and the entire surface of the third attachment layer 544 may face each other and be in contact with each other. A horizontal length of the third reflective layer 546 may be the same or substantially the same as the horizontal length of the third attachment layer 544. Additionally, positions of both ends of the third reflective layer 546 may coincide or substantially coincide with the positions of both ends of the third attachment layer 544.

As a result, a geometric shape of the third reflective layer 546 in a plane may be the same or substantially the same as the geometric shape of the third adhesion layer 544. Also, the entire third reflective layer 546 and the entire third attachment layer 544 may completely overlap or substantially completely overlap each other.

Considering the above, the geometric shapes and sizes of the second reflective layer 532, the third compound semiconductor layer 534, the second active layer 536, the fourth compound semiconductor layer 538, the second transparent electrode layer 542, the third attachment layer 544, and the third reflective layer 546, which are sequentially stacked on a plane, are the same or substantially the same, and each of the layers 532, 534, 536, 538, 542, 544 and 546 may completely overlap a facing upper layer and/or a facing lower layer.

For example, the geometric shape and size of the second active layer 536 may be the same as the geometric shape and size of the second reflective layer 532 and may also be the same as the geometric shape and size of the third reflective layer 546. Additionally, the entire second active layer 536 may completely overlap the second reflective layer 532 and the third reflective layer 546. Accordingly, when light is generated from the second active layer 536, the lower side of the second active layer 536 may be blocked by the second reflective layer 532, and the upper side of the second active layer 536 may be blocked by the third reflective layer 546. For example, light emitted from the second LED 300B may not be emitted above or below the second LED 300B. This suggests that, in the case of the Pentile-shaped third micro-LED pixel 300, light may not be emitted from the second LED 300B. For example, the third micro-LED pixel 300 may be a micro-LED pixel in which light is not emitted from the second LED 300B, but only from the first and third LEDs 300A and 300C. Accordingly, in an interconnection electrode layer configuration of the third micro-LED pixel 300, voltage may not be applied to the second LED 300B. In the layer structure of the third micro-LED pixel 300, because the attachment layers 528 and 544 having a large thickness are provided above and below the second LED 300B, no voltage is applied to the second LED 300B in an operation of the third micro-LED pixel 300. In this regards, the second LED 300B may be considered a dummy micro-LED and may be expressed as a dummy LED or a dummy micro-LED. Accordingly, For example, the second transparent electrode layer 542 may be omitted.

A third LED 300C may be provided on the third reflective layer 546.

The third LED 300C may include an n-type fifth compound semiconductor layer 548, a third active layer 552, and a p-type sixth compound semiconductor layer 554 sequentially stacked in a direction perpendicular to the upper surface of the third reflection layer 546. For example, a thickness relationship between the fifth compound semiconductor layer 548, the third active layer 552, and the sixth compound semiconductor layer 554 may be the same as the thickness relationship between the first compound semiconductor layer 520, the first active layer 522, and the second compound semiconductor layer 524.

For example, horizontal lengths of the fifth compound semiconductor layer 548, the third active layer 552, and the sixth compound semiconductor layer 554 may be the same or substantially the same as each other. For example, positions of both ends of the fifth compound semiconductor layer 548, positions of both ends of the third active layer 552, and positions of both ends of the sixth compound semiconductor layer 554 may coincide or substantially coincide with each other. Accordingly, a side surface of the fifth compound semiconductor layer 548, a side surface of the third active layer 552, and a side surface of the sixth compound semiconductor layer 554 may form the same surface or the same plane.

On a plane, the fifth compound semiconductor layer 548, the third active layer 552, and the sixth compound semiconductor layer 554 may have the same geometric shape, may also have the same or substantially the same size, and may completely overlap with each other.

Horizontal lengths of the fifth compound semiconductor layer 548, the third active layer 552, and the sixth compound semiconductor layer 554 may be less than the horizontal length of the third reflective layer 546. The fifth compound semiconductor layer 548, the third active layer 552, and the sixth compound semiconductor layer 554 are stacked on a portion of the surface (e.g., upper surface) of the third reflective layer 546. A position of the left end of the fifth compound semiconductor layer 548 may coincide with a position of the left end of the third reflective layer 546. A position of the right end of the fifth compound semiconductor layer 548 does not match the position of the right end of the third reflective layer 546. The right end of the third reflective layer 546 may be positioned at a location further extended to the right from the right end of the fifth compound semiconductor layer 548. A first terminal of a power supply source that supplies an operating voltage may be connected to the third reflective layer 546 around and adjacent to the fifth compound semiconductor layer 548.

For example, a material of the fifth compound semiconductor layer 548 may be the same or substantially the same as the material of the third compound semiconductor layer 534. The third active layer 552 may include a material that emits light of a third wavelength or a material configured to emit light of the third wavelength. The third wavelength may be a wavelength different from the first and second wavelengths. For example, the third wavelength may be a wavelength included in a blue light band or a wavelength included in a red light band but embodiments are not limited thereto. For example, light of the third wavelength may be light included in blue light or include light included in blue light. For example, the third LED 300C may be a micro-LED that emits blue light or a micro-LED that emits blue light as a central light.

For example, a material of the sixth compound semiconductor layer 554 may be the same as the material of the fourth compound semiconductor layer 538, but the sixth compound semiconductor layer 554 and the fourth compound semiconductor layer 538 may also include n-type compound semiconductor materials different from each other.

A third transparent electrode layer 556 may be provided on the sixth compound semiconductor layer 554.

The third transparent electrode layer 556 may be provided to cover an entire surface (e.g., upper surface) of the sixth compound semiconductor layer 554 and may be provided to contact the entire surface of the sixth compound semiconductor layer 554. A horizontal length of the third transparent electrode layer 556 may be the same or substantially the same as the horizontal length of the sixth compound semiconductor layer 554. The geometric shape and size of the third transparent electrode layer 556 on a plane may be the same or substantially the same as the geometric shape and size of the sixth compound semiconductor layer 554. As a result, the third transparent electrode layer 556 may be provided to completely overlap or substantially completely overlap the sixth compound semiconductor layer 554.

For example, a material of the third transparent electrode layer 556 may be the same as the material of the second transparent electrode layer 542, but the materials may be different from each other. For example, among the plurality of transparent electrode materials, the third transparent electrode layer 556 and the second transparent electrode layer 542 may include the same transparent electrode material or different transparent electrode materials from each other.

For example, the third LED 300C may also include the third reflective layer 546 and/or the third transparent electrode layer 556.

Surfaces of the first to third LEDs 300A, 300B, and 300C, the first to third reflective layers 518, 532, and 546, the first to third transparent electrode layers 526, 542, and 556, and the first to third attachment layers 512, 528, and 544 may be covered with the second CBL 514. For example, the second CBL 514 may extend from an upper surface of the third transparent electrode layer 556 to the upper surface of the first attachment layer 512 while covering the side surface and/or upper surface of each layer. As an example, the second CBL 514 may be provided to cover the upper surface of the third transparent electrode layer 556, the side surfaces of the first to third transparent electrode layers 526, 542, and 556, the side surfaces of the first to third LEDs 300A, 300B, and 300C, the side surfaces of the first to third reflective layers 518, 532, and 546, and the side surfaces of the second and third attachment layers 528 and 544, and to contact the corresponding side surfaces. In addition, the second CBL 514 may be provided to cover a portion of the upper surface of each of the first and second attachment layers 512 and 528 and a portion of the upper surface of each of the first and third reflective layers 518 and 546 and may be provided to be in contact with the corresponding portions of the upper surfaces.

For example, the second CBL 514 may include a fourth through hole 54h1 through which the first electrode pad layer 32A is exposed at the same position as the first through hole 51h1 and a fifth through hole 54h2 exposing the second through hole 51h2 and a portion of the first reflective layer 518 around and adjacent to the second through hole 51h2. An entrance center of the fourth through hole 54h1 may coincide with a entrance center of the first through hole 51h1, and entrance diameters of the first and fourth through holes 51h1 and 54h1 may be the same or substantially the same. The fourth through hole 54h1 and the first reflective layer 518 are spaced apart from each other. The upper surface of the first attachment layer 512 around and adjacent to the first through hole 51h1 may be covered with the second CBL 514. The upper surface of the first attachment layer 512 between the fourth through hole 54h1 and the first reflective layer 518 may also be covered with the second CBL 514.

The fifth through hole 54h2 may include the second through hole 51h2. F, the second through hole 51h2 may be located inside the fifth through hole 54h2. A diameter of the fifth through hole 54h2 may be greater than a diameter of the second through hole 51h2. A portion of the first reflective layer 518 exposed through the fifth through hole 54h2 may be located between entrance edges of the second through hole 51h2 and the fifth through hole 54h2. The second CBL 514 may cover the upper surface of the first attachment layer 512 on the right side of the second through hole 51h2.

In addition, the second CBL 514 may include a sixth through hole 54h3 formed at the same location as the third through hole 52h1, a seventh through hole 54h4 exposing a portion of the upper surface of the third reflective layer 546, and an eighth through hole 54h5 located on the third transparent electrode layer 556 and exposing a portion of the third transparent electrode layer 556.

The sixth through hole 54h3 may be provided so that an entrance center of the sixth through hole 54h3 coincides with or substantially coincides with an entrance center of the third through hole 52h1. A diameter of the sixth through hole 54h3 may be the same as the diameter of the third through hole 52h1. The upper surface of the second attachment layer 528 around and adjacent to the third through hole 52h1 may be covered with the second CBL 514, and the corresponding upper surface may contact the second CBL 514. The sixth through hole 54h3 may be spaced apart from the second reflective layer 532.

The seventh through hole 54h4 may be provided to be spaced apart from the fifth compound semiconductor layer 548.

The entire third transparent electrode layer 556 around and adjacent to the eighth through hole 54h5 may be covered with the second CBL 514 and may be in contact with the second CBL 514. For example, a remaining portion of the third transparent electrode layer 556 except for the portion exposed through the eighth through hole 54h5 may be covered with the second CBL 514.

For example, surfaces between the fourth to eighth through holes 54h1 to 54h5 may be covered with the second CBL 514. For example, the fourth to eighth through holes 54h1 to 54h5 may be connected to the second CBL 514.

For example, a portion of the first electrode pad layer 32A exposed through the first through hole 51h1, a portion of the first transparent electrode layer 526 exposed through the sixth through hole 54h3, and a portion of the third transparent electrode layer 556 exposed through the eighth through hole 54h5 may be connected to each other through the first interconnection electrode layer 562. As an example, the first interconnection electrode layer 562 may be provided to cover an inner surface and a lower surface (upper surface of the first electrode pad layer 32A) of the first through hole 51h1 and an inner surface of the second CBL 514 exposed through the fourth through hole 54h1 and may extend onto the upper surface of the second CBL 514 around and adjacent to the fourth through hole 54h1. The first interconnection electrode layer 562 may extend onto the second CBL 514 between the fourth through hole 54h1 and the sixth through hole 54h3 to cover the inner surface of the second CBL 514 exposed through the sixth through hole 54h3, an inner surface of the second attachment layer 528 exposed through the third through hole 52h1, and the upper surface of the first transparent electrode layer 526, and may be provided to contact these surfaces. The first interconnection electrode layer 562 may be provided to extend onto the second CBL 514 between the sixth through hole 54h3 and the eighth through hole 54h5 to reach the eighth through hole 54h5 and to cover a portion of the third transparent electrode layer 556 and an inner surface of the second CBL 514 exposed through the eighth through hole 54h5.

For example, a material (substance) of the first interconnection electrode layer 562 may be the same as the material (substance) of the eighth interconnection electrode layer 40E2, and among the plurality of transparent electrode materials, the material (substance) of the first interconnection electrode layer 562 may be different from the material (substance) of the eighth interconnection electrode layer 40E2.

As a result, the n-type compound semiconductor layers 524 and 554 of the first and third LEDs 300A and 300C may be simply connected to the first electrode pad layer 32A of the second backplane 510 by the first interconnection electrode layer 562. For example, the first interconnection electrode layer 562 may be used as a common electrode for connecting the N-side electrodes of the first and third LEDs 300A and 300C to the first electrode pad layer 32A of the second backplane 510.

When following the existing connection method, the n-type compound semiconductor layers 524 and 554 of the first and third LEDs 300A and 300C may be individually connected to the backplane 510. Because the first interconnection electrode layer 562 is used, the n-type compound semiconductor layers 524 and 554 of the first and third LEDs 300A and 300C may be simply connected to the backplane 510. In terms of process, by using the first interconnection electrode layer 562, the process may be simpler than before.

A portion of the third reflective layer 546 exposed through the seventh through hole 54h4 may be in contact with the second interconnection electrode layer 564. The second interconnection electrode layer 564 may completely cover the exposed surface of the third reflective layer 546 and may be in direct contact with the exposed surface while filling the seventh through hole 54h4. The second interconnection electrode layer 564 may extend onto a portion of the second CBL 514 around and adjacent to the seventh through hole 54h4. For example, the second interconnection electrode layer 564 may be connected to other electrode pad layer provided on the second backplane 510. For example, the other electrode pad layer may be provided to be connected to a driving transistor provided on the second backplane 510 for driving the third LED 300C. A voltage for driving the third LED 300C may be applied to the p-type compound semiconductor layer 548 of the third LED 300C through the driving transistor, the other electrode pad layer, and the second interconnection electrode layer 564.

For example, a material (substance) of the second interconnection electrode layer 564 may be the same as that of the first interconnection electrode layer 562 but, among the plurality of transparent electrode materials, may be different from the first interconnection electrode layer 562.

A portion of the first reflective layer 518 exposed through the fifth through hole 54h2 may be in contact with a third interconnection electrode layer 566. The third interconnection electrode layer 566 may be provided to cover an upper surface of the second electrode pad layer 32B, an inner surface of the first attachment layer 512, an inner surface of the second CBL 514, and a right side of the first reflective layer 518 exposed through the fifth through hole 54h2, and to contact these surfaces. The third interconnection electrode layer 566 may be located around and adjacent to the second through hole 51h2, may extend onto the upper surface of the first reflective layer 518 exposed through the fifth through hole 54h2, and may be in direct contact with the exposed upper surface of the first reflective layer 518. In this way, the first reflective layer 518 may be connected to the second electrode pad layer 32B of the second backplane 510 through the third interconnection electrode layer 566. The first reflective layer 518 may be a conductive layer including a metal or may include such a conductive layer. The first reflective layer 518 may be in contact with the first compound semiconductor layer 520, which is a p-type compound semiconductor layer of the first LED 300A. As a result, the p-type compound semiconductor layer 520 of the first LED 300A and the second electrode pad layer 32B of the second backplane 510 are connected by the third interconnection electrode layer 566. The second electrode pad layer 32B may be connected to a driving transistor provided to drive the first LED 300A.

In the third micro-LED pixel 300 described above, the second LED 300B may be a dummy LED to which no voltage is applied during an operation of the third micro-LED pixel 300. Accordingly, the third micro-LED pixel 300 may be a pixel including a plurality of LEDs provided to emit blue light (B) and green light (G) in the vertical direction. Accordingly, the third micro-LED pixel 300 may be said to be a BG type Pentile micro-LED pixel.

The third micro-LED pixel 300 may be provided together with a fourth micro-LED pixel 400, which will be described later, and may emit R, G, and B.

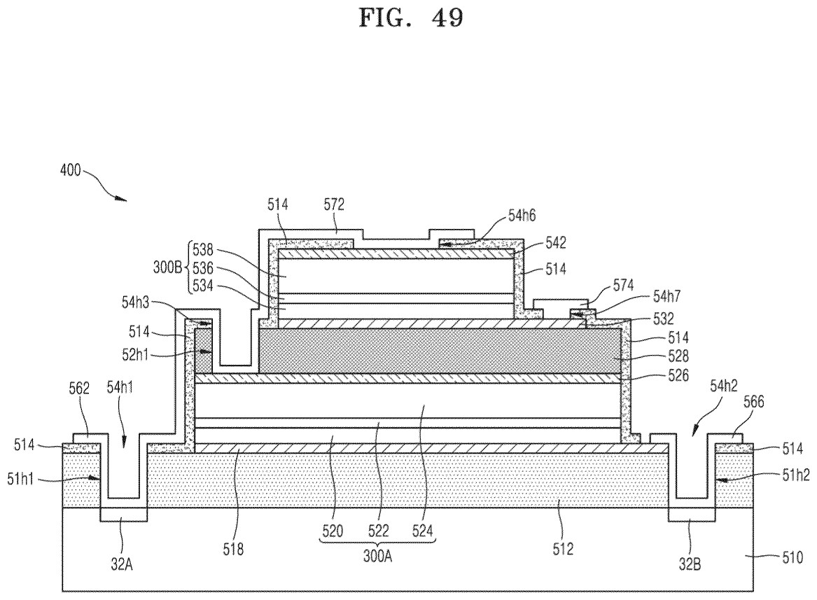

FIG. 49 shows a fourth type of vertically stacked micro-LED pixel 400 (hereinafter referred to as a fourth micro-LED pixel) according to one or more embodiments. The fourth micro-LED pixel 400 may be a second type Pentile micro-LED pixel having a different configuration from the first type Pentile micro-LED pixel.

In the description of FIG. 49, the same reference numbers as those mentioned in the description of FIG. 48 indicate the same members, and description thereof will be omitted. Additionally, only parts that are different from the third micro-LED pixel 300 of FIG. 48 will be described.

Referring to FIG. 49, the fourth micro-LED pixel 400 may correspond to a case in which the third LED 300C, which is an LED emitting B, that is, a B-LED, is removed from the third micro-LED pixel 300 of FIG. 48 and configured to apply a driving voltage to the second LED 300B.

For example, the third compound semiconductor layer 534, the second active layer 536, and the fourth compound semiconductor layer 538 of the second LED 300B are provided on a portion of the upper surface of the second reflective layer 532. a horizontal length of the third compound semiconductor layer 534, the second active layer 536, and the fourth compound semiconductor layer 538 may be less than a horizontal length of the second reflective layer 532. For example, a position of a left end of the second reflective layer 532 in the horizontal direction may be provided to coincide with a position of a left end of the third compound semiconductor layer 534, and a right end of the second reflective layer 532 may be positioned at the right of the right end of the third compound semiconductor layer 534. For example, the second reflective layer 532 may include a portion extending to the right beyond the right end of the third compound semiconductor layer 534. The extended portion of the second reflective layer 532 may be connected to the second backplane 510 through an interconnection electrode layer 574.

A second transparent electrode layer 542 may be provided on the fourth compound semiconductor layer 538. A horizontal length of the second transparent electrode layer 542 may be equal to a horizontal length of the fourth compound semiconductor layer 538.

A case in which the second CBL 514 is provided on one surface (e.g., upper surface) of the second transparent electrode layer 542 to cover side surfaces of the first and second LEDs 300A and 300B, the side surfaces of the first and second transparent electrode layers 526 and 542, side and/or upper surfaces of the first and second attachment layers 512 and 528, side and/or upper surfaces of the first and second reflective layers 518 and 532, and to contact the corresponding surfaces may be the same as described about the third micro-LED pixel 300 with reference to FIG. 48.

As described with respect to the third micro-LED pixel 300, the second CBL 514 may include a fourth through hole 54h1, a fifth through hole 54h2, and a sixth through hole 54h3. The second CBL 514 includes a ninth through hole 54h6 through which a portion of the second transparent electrode layer 542 is exposed on the second transparent electrode layer 542, and a tenth through hole 54h7 through which a portion of the second reflective layer 532 extended to the right side is exposed. Surfaces between the through holes 54h1, 54h2, 54h3, 54h6, and 54h7 may be covered with the second CBL 514.

An entire upper surface of the second transparent electrode layer 542 around and adjacent to the ninth through hole 54h6 may be covered with the second CBL 514 and may be in contact with the second CBL 514. The tenth through hole 54h7 may be provided to be spaced apart from the third compound semiconductor layer 534.

For example, a third attachment layer may be provided between the second transparent electrode layer 542 and the second CBL 514 on the upper surface of the second transparent electrode layer 542. In this case, the third attachment layer may include a through hole with a diameter corresponding to the ninth through hole 54h6 at the position of the ninth through hole 54h6, and the second transparent electrode layer 542 may be exposed through the through hole. For example, a thickness of the third attachment layer may be the same or substantially the same as the thickness of the first attachment layer 512 or the second attachment layer 528 but embodiments are not limited thereto.

A fourth interconnection electrode layer 572 is provided on the second CBL 514 between the fourth through hole 54h1, the sixth through hole 54h3, and the ninth through hole 54h6. The fourth interconnection electrode layer 572 may be continuously provided along a surface of the second CBL 514 between the fourth, sixth and ninth through holes 54h1, 54h3, and 54h6. The fourth interconnection electrode layer 572 may be provided to cover an inner surface of the second CBL 514 and the upper surface of the second transparent electrode layer 542 exposed through the ninth through hole 54h6 and be provided to contact the inner surface of the second CBL 514 and the upper surface of the second transparent electrode layer 542. A contact relationship between the fourth interconnection electrode layer 572 and the surfaces exposed through the fourth through hole 54h1 and the sixth through hole 54h3 may be the same as the contact relationship between the first interconnection electrode layer 562 of the third micro-LED pixel 300 and the surfaces exposed through the fourth through hole 54h1 and the sixth through hole 54h3.

For example, a material of the fourth interconnection electrode layer 572 may be the same as that of the first interconnection electrode layer 562 of the third micro-LED pixel 300, but the materials may be different from each other.

A fifth interconnection electrode layer 574 connected to the second reflective layer 532 may be provided on the second CBL 514 around and adjacent to the tenth through hole 54h7. The fifth interconnection electrode layer 574 may be provided to cover a surface of the second reflective layer 532 exposed through the tenth through hole 54h7 and be in contact with the exposed surface of the second reflective layer 532. For example, the fifth interconnection electrode layer 574 covers a portion (upper surface) of the second reflective layer 532 exposed through the tenth through hole 54h7 and an entire inner surface of the second CBL 514 exposed through the tenth through hole 54h7 and may be in contact with the surfaces.

The fifth interconnection electrode layer 574 may be connected to another electrode pad layer provided on the second backplane 510. The other electrode pad layer may be connected to a driving transistor provided to drive the second LED 300B. The second reflective layer 532 may include a conductive layer. Therefore, when driving the fourth micro-LED pixel 400, a driving voltage may be applied to the third compound semiconductor layer 534, which is a p-type compound semiconductor, of the second LED 300B through the driving transistor, the other electrode pad layer, and the fifth interconnection electrode layer 574.

As described above, the fourth micro-LED pixel 400 may include only the first LED 300A configured to emit green light (G) and the second LED 300B configured to emit red light (R). Accordingly, the fourth micro-LED pixel 400 may be said to be an RG type Pentile micro-LED pixel.

For example, the fourth-micro LED pixel 400 and the third micro-LED pixel 300 may be provided together to form a pixel that provides R, G, and B. For example, the third micro-LED pixel 300 and the fourth micro-LED pixel 400 may be provided together to form a unit pixel that emits R, G, and B of an LED display device.

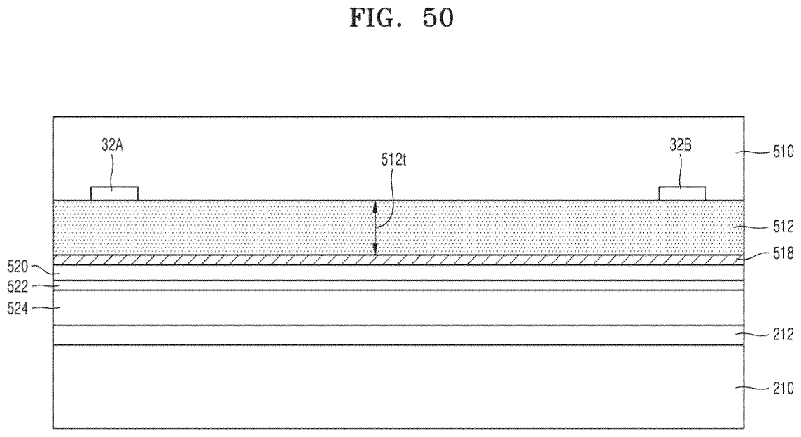

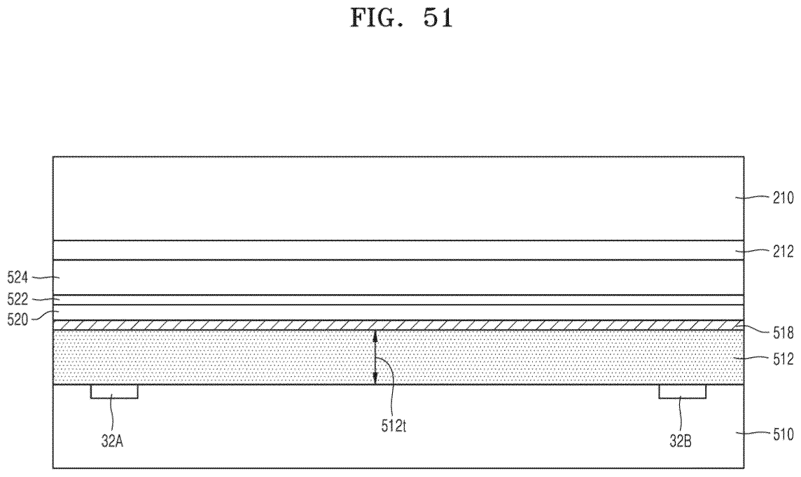

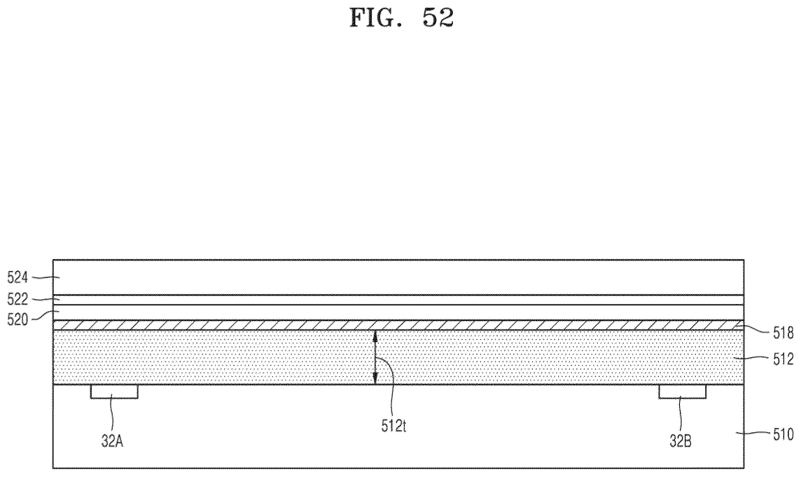

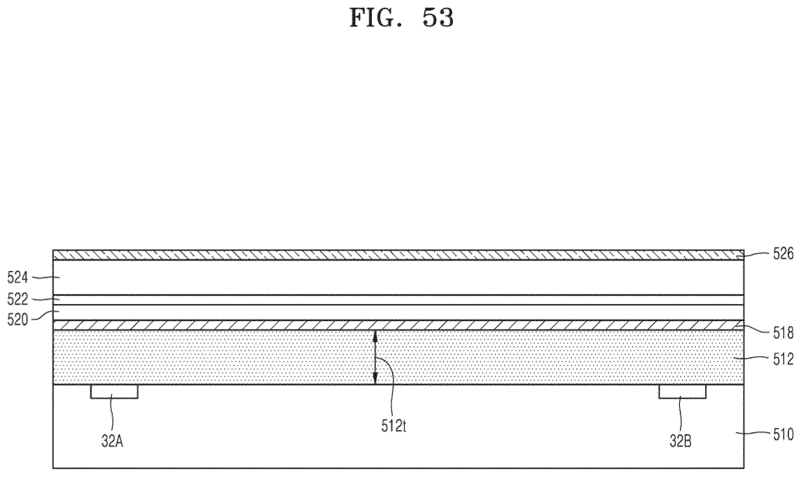

Next, a method of manufacturing the third micro-LED pixel 300, which is a BG type Pentile micro-LED pixel, will be described with reference to FIGS. 50 to 65. In this process, the same reference numbers as those mentioned in the above-described embodiments indicate the same members, and description thereof will be omitted.

All of the first to third LEDs 300A, 300B, and 300C included in the third micro-LED pixel 300, like the first to third LEDs 200A, 200B, and 200C included in the second micro-LED 200, have a flip structure in which a P-side electrode, that is, a p-type compound semiconductor layer is located below the active layer, and an N-side electrode, that is, an n-type compound semiconductor layer, is located above the active layer. In addition, in the vertical stacking structure of the third micro-LED pixel 300, an arrangement relationship between the LEDs 300A, 300B, and 300C, the attachment layers 512, 528, and 544, the reflective layers 518, 532, and 546, and transparent electrode layers 526, 542 and 556 may be the same as the arrangement relationship between the LEDs 200A, 200B, and 200C, the attachment layers 120, 220, and 320, the reflective layers 130, 230, and 330, and the transparent electrode layers 146, 246, and 346 of the second micro-LED pixel 200.

However, thicknesses of the attachment layers 512, 528, and 544 of the third micro-LED pixel 300 are much greater than the thickness of the attachment layers 120, 220, and 320 of the second micro-LED pixel 200.

Therefore, a process of sequentially transferring the LED stacks PST1, PST2, and PST3 onto the second backplane 510 illustrated in FIGS. 50 to 54 may be carried out along the process of sequentially transferring the LED stacks FST1, FST2, and FST3 onto the first backplane 110 as illustrated with reference to FIGS. 33 to 42 of the manufacturing method of the second micro-LED pixel 200. However, in this process, thicknesses 512t, 528t, and 544t of each of the attachment layers 512, 528, and 544 may be formed as the same as or different from the thickness of the LED stacks PST1, PST2, and PST3 corresponding to each of the attachment layers 512, 528, and 544. As an example, each of the attachment layers 512, 528, and 544 may be formed to be greater than the thickness of the greatest layer (e.g., n-type compound semiconductor layers 524, 538, and 554) of each of the LED stacks PST1, PST2, and PST3 or may be formed to have the same thickness as or greater than the thickness of each of the LED stacks PST1, PST2, and PST3. For example, each of the attachment layers 512, 528, and 544 may have a thickness in a range from about 0.4 μm to about 1.0 μm, in a range from about 0.5 μm to about 0.9 μm, or in a range from about 0.5 μm to about 0.8 μm, but embodiments are not limited thereto.

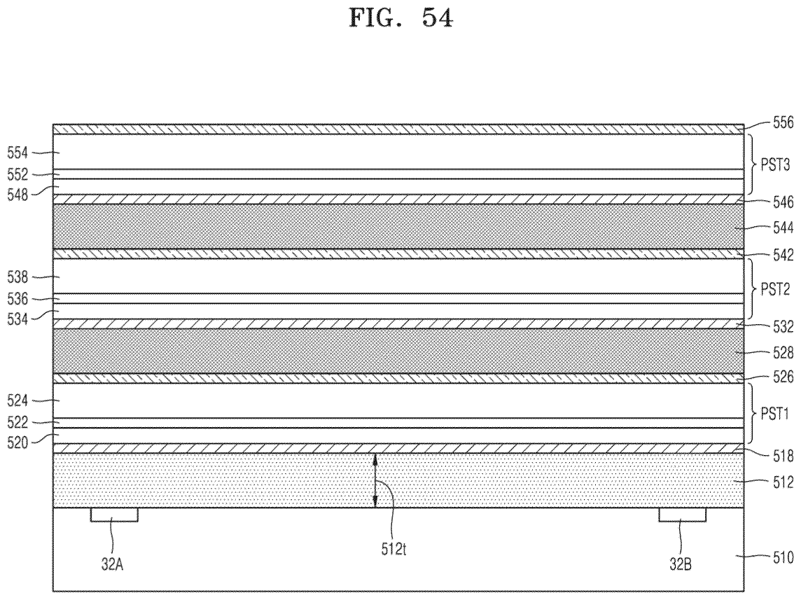

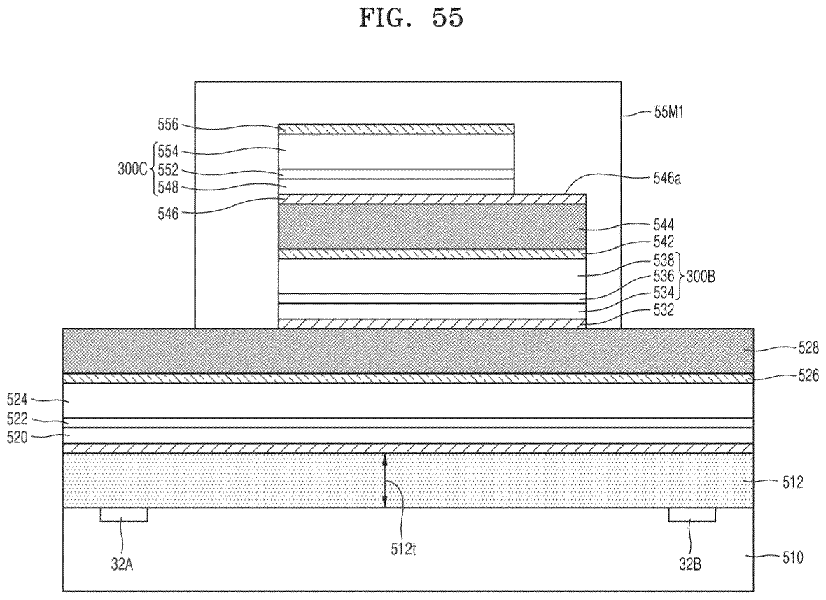

As shown in FIG. 54, after forming the first to third LED stacks FST1, FST2, and FST3, first, the third transparent electrode layer 556 and the third LED stack PST3 may be simultaneously (sequentially) patterned using a first photolithography process to remove a portion of the third transparent electrode layer 556 and the third LED stack PST3 on the third reflective layer 546 (hereinafter, first patterning). As a result, a portion of the upper surface of the third reflective layer 546 may be exposed, and as shown in FIG. 55, a pattern corresponding to the third LED 300C and the third transparent electrode layer 556 of FIG. 48 are formed on the portion of the upper surface of the third reflective layer 546.

Because the size of the third LED 300C may be determined in the first patterning, the first patterning may be performed taking the size into account.

After the first patterning, the third attachment layer 544, the second transparent electrode layer 542, the second LED stack PST2, and the second reflective layer 532 are simultaneously patterned by performing a second photolithography process with respect to the third reflective layer 546, the third attachment layer 544, the second transparent electrode layer 542, the second LED stack PST2, and the second reflective layer 532, thereby removing portions of the third reflective layer 546, the third adhesion layer 544, the second transparent electrode layer 542, second LED stack PST2, and second reflective layer 532 (hereinafter second patterning). By the second patterning, the third reflective layer 546, the third attachment layer 544, the second transparent electrode layer 542, the second LED stack PST2, and the second reflective layer 532 remain only on a portion of the second attachment layer 528, and a portion of the upper surface of the second attachment layer 528 may be exposed. In the second patterning, the second and third reflective layers 532 and 546, the second transparent electrode layer 542, the third attachment layer 544, and the second LED stack PST2 may be patterned at once using the same etch mask. Accordingly, a planar geometric shape and size of the second and third reflective layers 532 and 546, the second transparent electrode layer 542, the third attachment layer 544, and the second LED stack PST2 remaining after the second patterning may be identical to each other. In the second patterning, the third LED 300C and the third transparent electrode layer 556 may be protected by the etch mask. For example, in the second patterning, at least the entire upper surface of the third transparent electrode layer 556 may be covered with the etch mask.

In the second patterning, by controlling the formation position of the etch mask, positions of the left ends of the resultant products 532, 300B, 542, 544, and 546 formed after the second patterning may coincide or substantially coincide with positions of the left ends of the resultant products 300C and 556 formed after the first patterning, It may coincide or substantially coincide with the position of the left end, and the right ends of the resultant products 532, 300B, 542, 544, and 546 formed after the second patterning may extend further to the right beyond the right ends of the resultant products 300C and 556 formed after the first patterning.

As a result of the second patterning, as shown in FIG. 55, the second reflective layer 532, the second LED 300B, the second transparent electrode layer 542, the third attachment layer 544, and the third reflective layer 546 are vertically stacked on a portion of the upper surface of the second attachment layer 528, and the remainder of the upper surface of the second attachment layer 528 may be exposed. The exposed portion of the upper surface of the second attachment layer 528 may be a region where light emitted from the first LED 300A, which will be formed subsequently, is emitted.

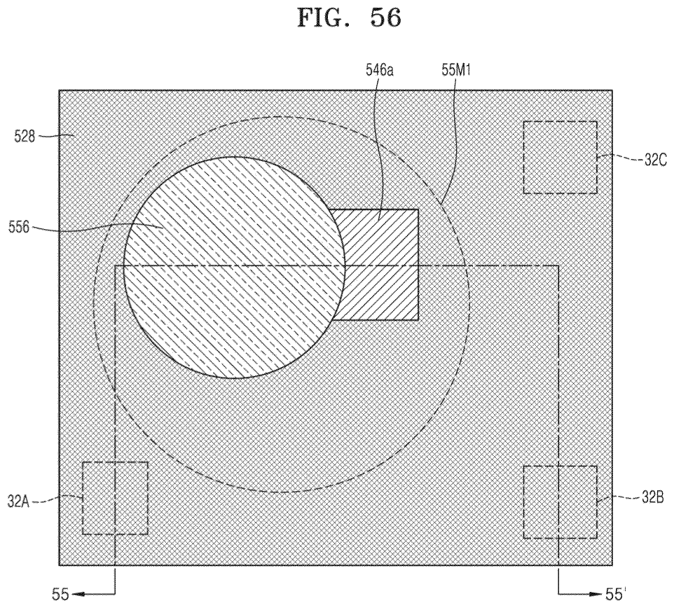

FIG. 56 is a plan view of the resultant product of FIG. 55. FIG. 55 may be a cross-sectional view taken along line 55-55′ of FIG. 56.

As shown in FIG. 56, the third transparent electrode layer 556 may be circular. As an example, the third transparent electrode layer 556 may be non-circular and may have a geometric shape with at least one angle. The plane geometric shape and size of the third LED 300C, which is patterned together with the third transparent electrode layer 556 in the first patterning, may also be the same as the third transparent electrode layer 556.

Referring to FIGS. 55 and 56 together, the third reflective layer 546 in contact with the fifth compound semiconductor layer 548 may have a circular portion of the same size as the third transparent electrode layer 556 and a portion 546a protruding or extending out of the third transparent electrode layer 556. Considering the second patterning, geometric shapes of the third attachment layer 544, the second transparent electrode layer 542, the second LED 300B, and the second reflective layer 532 provided below the third reflective layer 546 may have the same shape and size as that of the third reflective layer 546.

In FIG. 56, reference number 32C indicates a third electrode pad layer provided on the second backplane 510 together with the first and second electrode pad layers 32A and 32B. The third electrode pad layer 32C may be connected to the portion 546a of the third reflective layer 546 extending outside the third transparent electrode layer 556 through an interconnection electrode layer in a subsequent process. The third electrode pad layer 32C is not shown in FIG. 55. The first to third electrode pad layers 32A, 32B, and 32C may be provided at the corners of the second backplane 510, but are not limited thereto.

Subsequently, after the second patterning, a third photolithography process is performed on the second attachment layer 528, the first transparent electrode layer 526, and the first LED stack PST1 of FIG. 55. In the third photolithography process, the second attachment layer 528, the first transparent electrode layer 526, and the first LED stack PST1 may be patterned simultaneously. As a result, portions of the second attachment layer 528, the first transparent electrode layer 526, and the first LED stack PST1 may be removed on the first reflective layer 518 (hereinafter, third patterning). As a result of the third patterning, the second attachment layer 528, the first transparent electrode layer 526, and the first LED stack PST1 remain only on some regions of the first reflective layer 518, and a portion of the upper surface of the first reflective layer 518 may be exposed. The first LED stack PST1 remaining after the third patterning may correspond to the first LED 300A.

In the third patterning, the second attachment layer 528, the first transparent electrode layer 526, and the first LED stack PST1 may be patterned at once using the same etch mask 55M1. At this time, a size of the etch mask 55M1 on a plane may be greater than that of the third reflective layer 546, as may be seen in FIG. 56. For example, the etch mask 55M1 may have a size that covers the entire third reflective layer 546 and a portion of the second attachment layer 528 around and adjacent to the third reflective layer 546. Because the shape and size of the etch mask 55M1 limit the planar shape and size of the first LED 300A, the etch mask 55M1 may be formed taking the shape and size of the first LED 300A into account. For example, the planar shape of the etch mask 55M1 may be circular as illustrated in FIG. 56 but may also be non-circular or may have a shape including at least one angle.

In the third patterning, because the second attachment layer 528, the first transparent electrode layer 526, and the first LED stack PST1 are etched using the same etch mask 55M1, planar geometric shapes and sizes of the second attachment layer 528, the first transparent electrode layer 526, and the first LED stack PST1 remaining after the third patterning may be the same.

In the third patterning, the remaining stacks on the second attachment layer 528 after the first and second patterning may be protected by the etch mask 55M1. For example, in the third patterning, the entire upper surface of the third transparent electrode layer 556, the entire portion of the third reflective layer 546 extended outside the third transparent electrode layer 556, and an entire side surface of the stacked structures between the third transparent electrode layer 556 and the second reflective layers 532 may also be covered with the etch mask 55M1. In the third patterning using the etch mask 55M1, etching may be performed until the first reflective layer 518 is exposed. After the etching, the etch mask 55M1 may be removed.

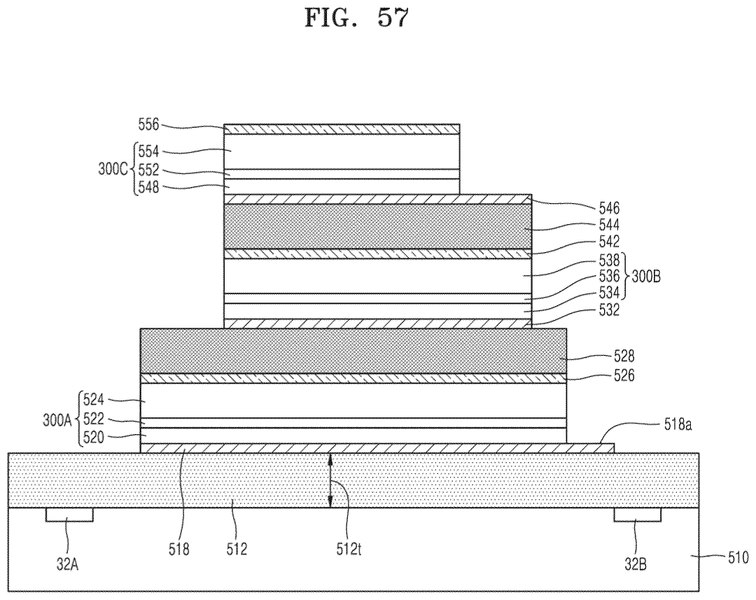

FIG. 57 shows the first LED 300A, the first transparent electrode layer 526, and the second attachment layer 528 formed on the first reflective layer 518 by the third patterning.

After the third patterning, the first reflective layer 518 may be patterned using a separate etch mask. The separate etch mask may be formed to cover all stacks remaining on the first reflective layer 518 after the first to third patterning. For example, the separate etch mask may be formed to cover the first LED 300A and a partial region of the first reflective layer 518 around and adjacent to the first LED 300A. A size of the portion 518a of the first reflective layer 518 extending out of the first LED 300A may be determined by the separate etch mask. The portion 518a of the first reflective layer 518 extending out of the first LED 300A is a portion connected to the second electrode pad layer 32B of the second backplane 510 by an interconnection electrode layer. Therefore, the separate etch mask may be formed taking the interconnection into account.

The first reflective layer 518 in FIG. 57 shows a result of being patterned using the separate etch mask. A left end of the first reflective layer 518 after patterning may coincide with a left end of the first LED 300A, and a right end of the first reflective layer 518 may be located to the right of a right end of the first compound semiconductor layer 520. For example, the first reflective layer 518 includes the portion 518a extending outside the first compound semiconductor layer 520. Accordingly, the upper surface of the first reflective layer 518 around and adjacent to the first LED 300A may be exposed.

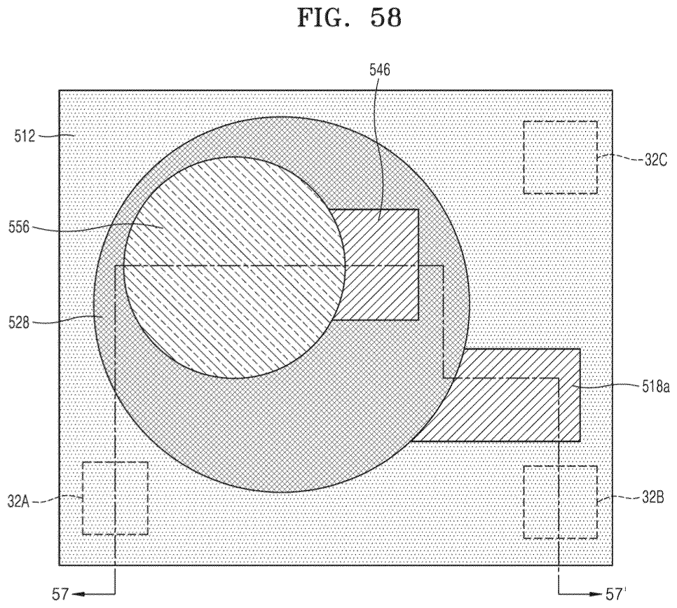

FIG. 58 is a plan view of FIG. 57. FIG. 57 may be a cross-sectional view taken along line 57-57′ of FIG. 58.

Referring to FIGS. 57 and 58 together, a size of the second attachment layer 528 on a plane may be greater than the third transparent electrode layer 556 and the third reflective layer 546 in any direction. For example, in a plane view, the third transparent electrode layer 556 and the third reflective layer 546 are within a region of the second attachment layer 528 and are spaced apart from a boundary of the second attachment layer 528. The extended portion 518a of the first reflective layer 518 may be provided closer to the second electrode pad layer 32B than to the other electrode pad layers 32A and 32C. The shape, size, and distance from the second electrode pad layer 31B of the extended portion 518a of the first reflective layer 518 may vary depending on the shape of the etch mask for patterning the first reflective layer 518. For example, the planar shape of the second attachment layer 528 may be circular but may be non-circular. For example, the geometric shape of the second attachment layer 528 on a plane may include at least one angle or a plurality of angles. Considering the third patterning, the planar shape and size of the first LED 300A and the first transparent electrode layer 526 below the second attachment layer 528 may also be the same as the second attachment layer 528. The second attachment layer 528 may be spaced apart from the first to third electrode pad layers 32A, 32B, and 32C on the periphery thereof.

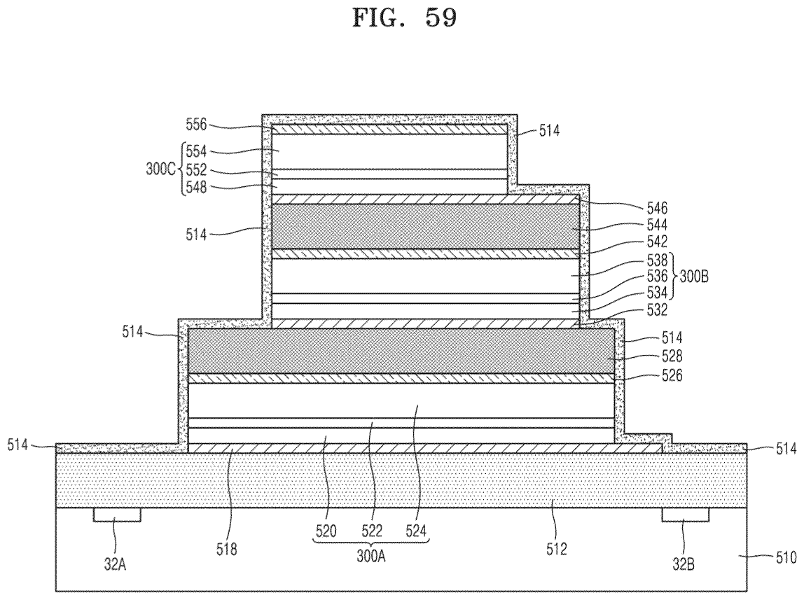

Subsequently, after patterning the first reflective layer 518, as shown in FIG. 59, the second CBL 514 may be formed on the upper surface of the first attachment layer 512 exposed as a result of patterning the first reflective layer 518. The second CBL 514 may be formed to cover exposed surfaces (side and/or upper surfaces) of the stacks remaining after the first to third patterning and the exposed surface of the first reflective layer 518 remaining after the patterning of the first reflective layer 518. The second CBL 514 may be formed to cover the entire upper surface of the first attachment layer 512 around and adjacent to the first reflective layer 518 but embodiments are not limited thereto.

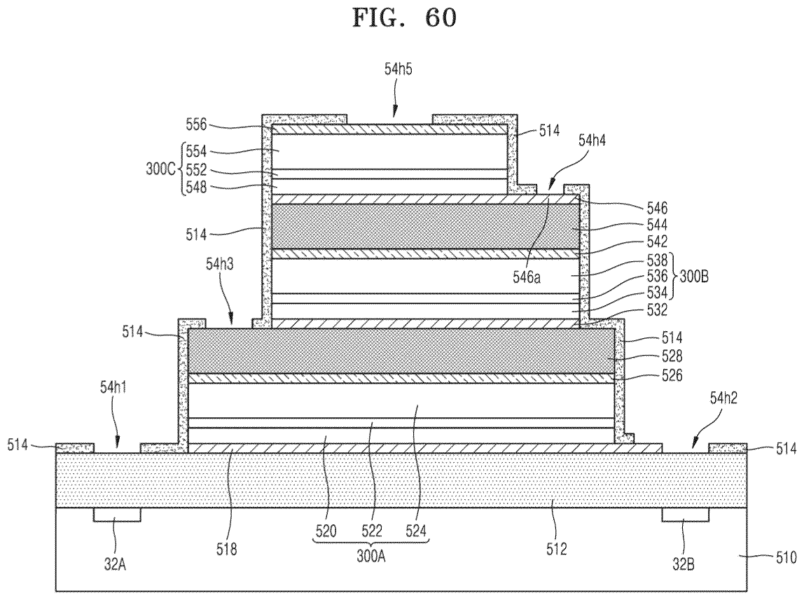

Next, as shown in FIG. 60, fourth to eighth through holes 54h1 to 54h5 are formed in the second CBL 514.

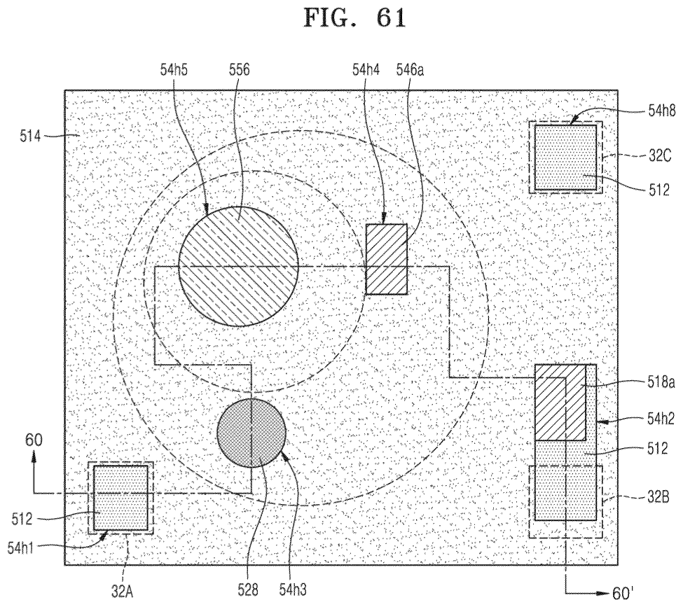

FIG. 61 is a plan view of FIG. 60. FIG. 60 may be a cross-sectional view taken along line 60-60′ of FIG. 61.

Referring to FIGS. 60 and 61 together, the first attachment layer 512 on the first and third electrode pad layers 32A and 32C is exposed through the fourth and eleventh through holes 54h1 and 54h8, and the expanded portion 518a of the first reflective layer 518 and the first attachment layer 512 on the second electrode pad layer 32B are exposed through the fifth through hole 54h2. The second attachment layer 528 is exposed through the sixth through hole 54h3, and the expanded portion 546a of the third reflective layer 546 is exposed through the seventh through hole 54h4. Additionally, the third transparent electrode layer 556 is exposed through the eighth through hole 54h5. The first attachment layer 512 around and adjacent to the fourth to ninth through holes 54h1 to 54h6 may be covered with the second CBL 514.

The first attachment layer 512 exposed through the fourth through hole 54h1, the fifth through hole 54h2, and the eleventh through hole 54h8 is etched, and the second attachment layer 528 exposed through the sixth through hole 54h3 is also etched. This etching may be performed until the first to third electrode pad layers 32A, 32B, and 32C are exposed and the first transparent electrode layer 526 is exposed. The first and third reflective layers 518 and 546 and the third transparent electrode layer 556 may have higher etch resistance and etch selectivity than the attachment layers 512 and 528. Therefore, during the etching, the first reflective layer 518 exposed through the fifth through hole 54h2, the third reflective layer 546 exposed through the seventh through hole 54h4, and the third transparent electrode layer 556 exposed through the eighth through hole 54h5 may not be etched or the etching rate may be very low. Accordingly, the physical properties (e.g., reflection or conduction properties) of the first and third reflective layers 518 and 546 and the properties (e.g., transparency or conduction properties) of the third transparent electrode layer 556 may not be affected by the etching.

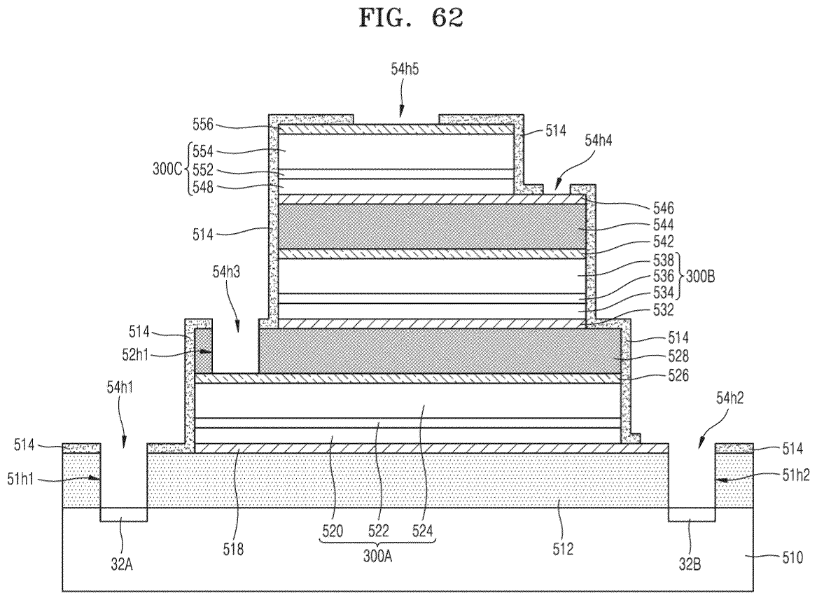

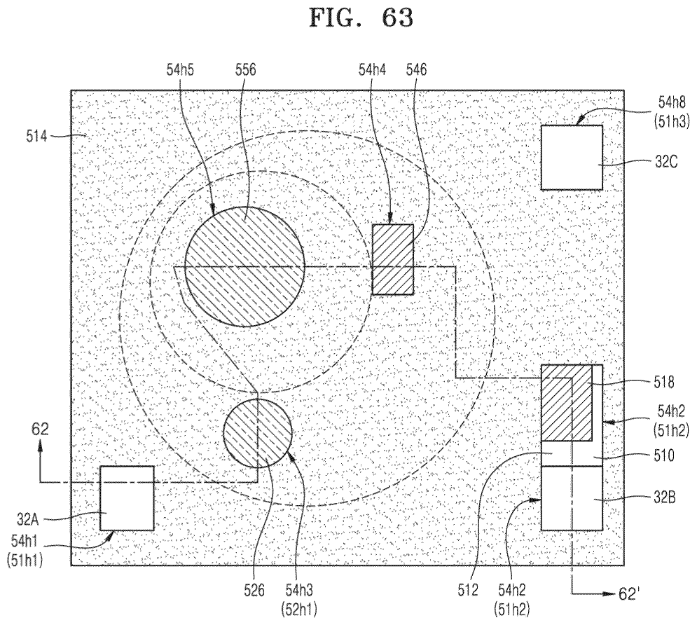

A result of etching may be seen in FIGS. 62 and 63. FIG. 63 is a plan view of FIG. 62, and FIG. 62 may be a cross-sectional view taken long line 62-62′ of FIG. 63.

Referring to FIGS. 62 and 63 together, as a result of the etching, a first through hole 51h1 through which the first electrode pad layer 32A is exposed, a second through hole 51h2 through which the second electrode pad layer 32B is exposed, and a through hole 51h3 through which the third electrode pad layer 32C is exposed are formed in the first attachment layer 512, and a third through hole 52h1 through which the first transparent electrode layer 526 is exposed is formed in the second attachment layer 528.

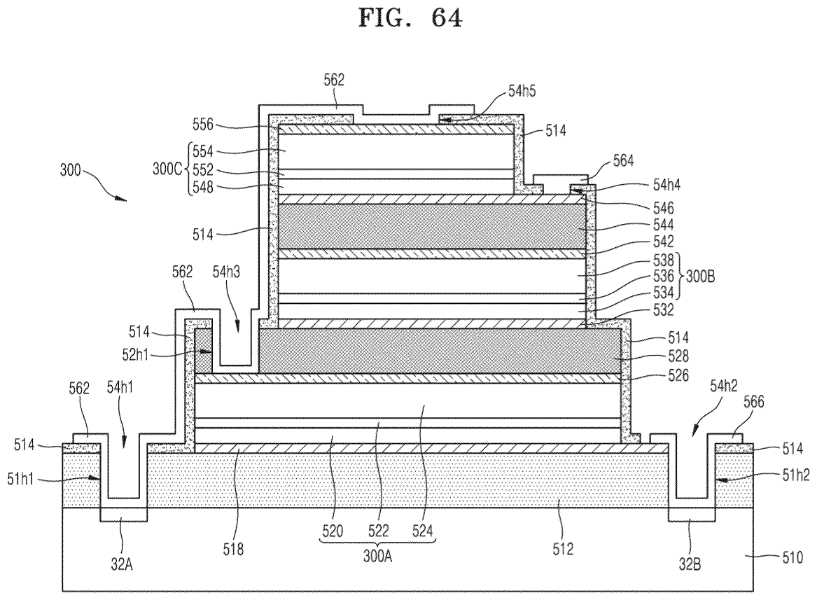

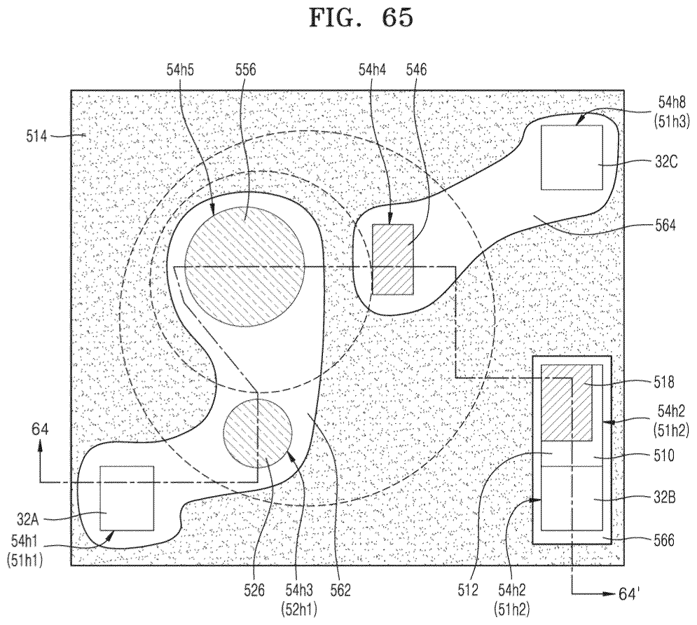

Next, as shown in FIGS. 64 and 65, an interconnection electrode layer that interconnects the first and third LEDs 300A and 300C to the first to third electrode pad layers 32A, 32B, and 32C of the second backplane 510 is formed.

FIG. 65 is a plan view of FIG. 64, and FIG. 64 may be a cross-sectional view taken along line 64-64′ of FIG. 65.

Referring to FIGS. 64 and 65 together, a first interconnection electrode layer 562 provided to connect the first electrode pad layer 32A exposed through the first through hole 51h1, the first transparent electrode layer 526 exposed through the third through hole 52h1, and the third transparent electrode layer 556 exposed through the eighth through hole 54h5 to each other on the second CBL 514. For example, the first interconnection electrode layer 562 may be formed using an ALD method, and other deposition methods (e.g., CVD-based methods) may be used. The first interconnection electrode layer 562 may cover an entire exposed surface of the first electrode pad layer 32A, an entire exposed surface of the first transparent electrode layer 526, and an entire exposed surface of the third transparent electrode layer 556. The first interconnection electrode layer 562 may be provided to cover the entire surfaces exposed through the first and fourth through holes 51h and 54h1, the entire surfaces exposed through the third and sixth through holes 52h1 and 54h3, and the entire surface exposed through the eighth through hole 54h5. The first interconnection electrode layer 562 connects the N-side electrode of the first and third LEDs 300A and 300C, that is, the n-type compound semiconductor layers 524 and 554 to the first electrode pad layer 32A connected to a ground electrode of the second backplane 510. Accordingly, the first interconnection electrode layer 562 may be expressed as an N-type common electrode layer or an N-type common electrode pad layer. In this way, because the N-side electrodes of all driving LEDs 300A and 300C included in a pixel are connected to the ground electrode of the backplane 510 using one common electrode layer, the connection process may be more simplified.

A second interconnection electrode layer 564 may be provided on the second CBL 514 to connect the third reflective layer 546 exposed through the seventh through hole 54h4 and the third electrode pad layer 32C exposed through the through hole 51h3. The second interconnection electrode layer 564 may cover entire surfaces exposed through the seventh through hole 54h4, entire surfaces exposed through the eleventh through hole 54h8, and entire surfaces exposed through the through hole 51h3 of the backplane 510 and may be in contact with these surfaces.

A third interconnection electrode layer 566 provided to connect the second reflective layer 518 exposed through the fifth through hole 54h2 and the second electrode pad layer 32B exposed through the second through hole 51h2 may be formed on the second CBL 514. The third interconnection electrode layer 566 may be formed to contact entire surfaces exposed through the second through hole 51h2 and entire surfaces exposed through the fifth through hole 54h2.

The method of connecting the P-side electrode of each LED 300A and 300C and the driving transistors of the backplane 510 using the second and third interconnection electrode layers 564 and 566 is simple compared to the conventional copper-to-copper connection method in which the P-side electrode of each of the LEDs 300A and 300C is connected to the driving transistors of the backplane 510, so there is no difficulty in the connection process.

The first to third interconnection electrode layers 562, 564, and 566 may be spaced apart from each other and formed simultaneously but are not limited thereto.

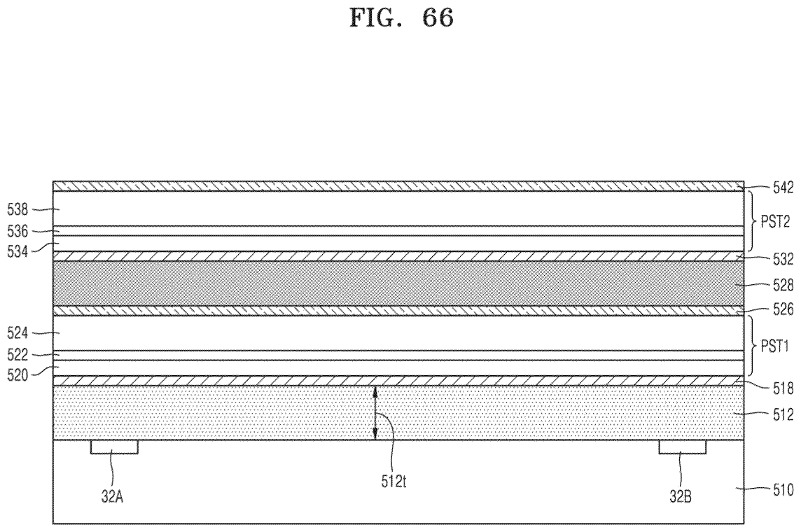

Next, a method of manufacturing the fourth micro-LED pixel 400, which is an RG type Pentile micro-LED pixel, will be described with reference to FIGS. 66 to 71. In this process, the same reference numbers as those mentioned in the above-described embodiments indicate the same members, and description thereof will be omitted.

First, as shown in FIG. 66, a first attachment layer 512 covering the first and second electrode pad layers 32A and 32B may be formed on the second backplane 510. Another electrode pad layer formed on the second backplane 510 may also be covered with the first attachment layer 512. A first reflective layer 518, a first LED stack PST1, a first transparent electrode layer 526, a second attachment layer 528, a second reflective layer 532, a second LED stack PST2, and a second transparent electrode layer 542 may be formed sequentially in a direction perpendicular to one surface (e.g., upper surface) of the first attachment layer 512.

A resultant product shown in FIG. 66 may be obtained by removing the stacks 544, 546, and PST3 formed on the second transparent electrode layer 542 from a resultant product shown in FIG. 54. Therefore, the resultant product shown in FIG. 66 may be formed through the process illustrated in FIGS. 50 to 54 among the methods of manufacturing the third micro-LED pixel 300.

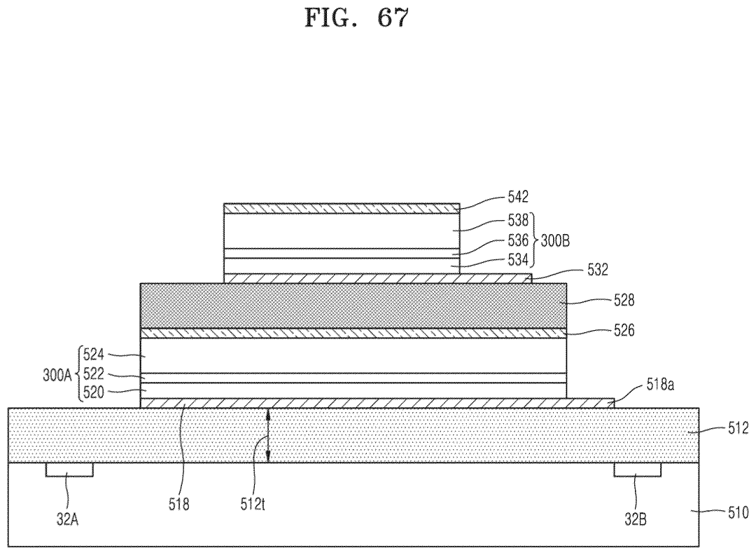

Next, the second transparent electrode layer 542 and the second LED stack PST2 are simultaneously (sequentially) patterned using a first photolithography process to remove the second transparent electrode layer 542 and the second LED stack PST2 on the second reflective layer 532 (hereinafter, fourth patterning). As a result, a portion of the upper surface of the second reflective layer 532 may be exposed, and as shown in FIG. 67, a pattern corresponding to the second LED 300B and the second transparent electrode layer 542 of FIG. 49 is formed on a portion of a region of the upper surface of the second reflective layer 532.

Because a size of the second LED 300B may be determined in the fourth patterning, the fourth patterning may be performed taking the size of the second LED 300B into account.

After the fourth patterning, the second reflective layer 532 is patterned. The patterning with respect to the second reflective layer 532 may be performed so that a portion of the second reflective layer 532 is exposed outside the second LED 300B and the upper surface of the second reflective layer 532 is exposed. As shown in FIG. 67, a left end of the patterned second reflective layer 532 may coincide with a position of a left end of the second LED 300B, and a right end of the patterned second reflective layer 532 may be in a position extending further to the right from the right end of the second LED 300B.

As a result of the fourth patterning and the patterning of the second reflective layer 532, as shown in FIG. 67, the second reflective layer 532 exists only on a region of the upper surface of the second attachment layer 528. Accordingly, after patterning the second reflective layer 532, a portion of the upper surface of the second attachment layer 528 is exposed.

After patterning the second reflective layer 532, patterning on the second attachment layer 528, the first transparent electrode layer 526, and the first LED stack PST1 is performed (hereinafter referred to as fifth patterning). For example, the fifth patterning may be performed in the same manner as the third patterning using the etch mask 55M1 described with reference to FIG. 55.

FIG. 67 shows the first LED 300A, the first transparent electrode layer 526, and the second attachment layer 528 formed on the first reflective layer 518 by the fifth patterning. The first LED 300A may be located between the first and second electrode pad layers 32A and 32B.

After the fifth patterning, patterning with respect to the first reflective layer 518 may be performed. For example, the patterning with respect to the first reflective layer 518 may be performed in the same manner as the patterning of the first reflective layer 518 using a separate etch mask after the third patterning described with reference to FIG. 55. As a result of the patterning with respect to the first reflective layer 518, as shown in FIG. 67, the first reflective layer 518 may include a portion 518a extending to the right of the first LED 300A. The patterned first reflective layer 518 may be positioned between the first and second electrode pad layers 32A and 32B. Accordingly, the upper surface of the first attachment layer 512 around and adjacent to the first reflective layer 518 may be exposed.

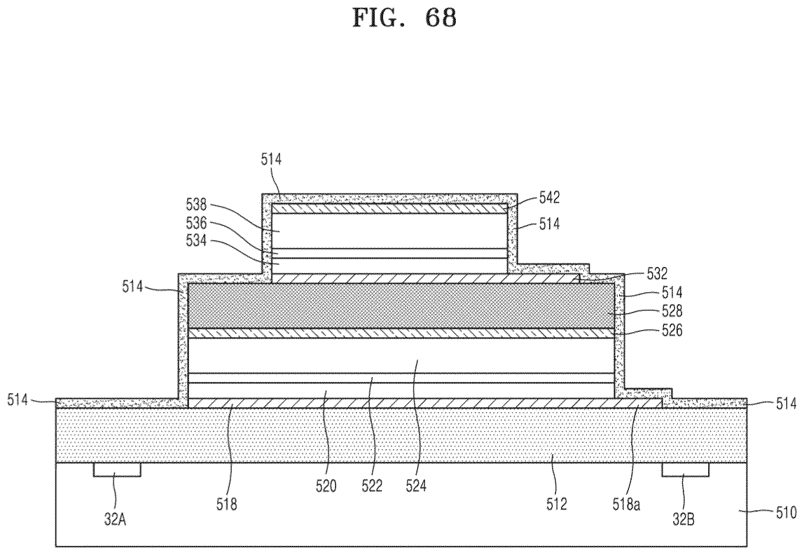

Next, as shown in FIG. 68, a second CBL 514 covering exposed surfaces of the stacks formed on a region of the upper surface of the first attachment layer 512 may be formed on the exposed upper surface of the first attachment layer 512. For example, the second CBL 514 may be formed to cover the entire upper surface of the first attachment layer 512 around and adjacent to the first reflective layer 518, and may be formed to cover exposed side and upper surfaces of the first reflective layer 518, side surfaces of the first LED 300A, side surfaces of the first transparent electrode layer 526, side and exposed upper surface of the second attachment layer 528, side and exposed upper surface of the second reflective layer 532, side surfaces of the second LED 300B, and side and upper surfaces of the second transparent electrode layer 542.

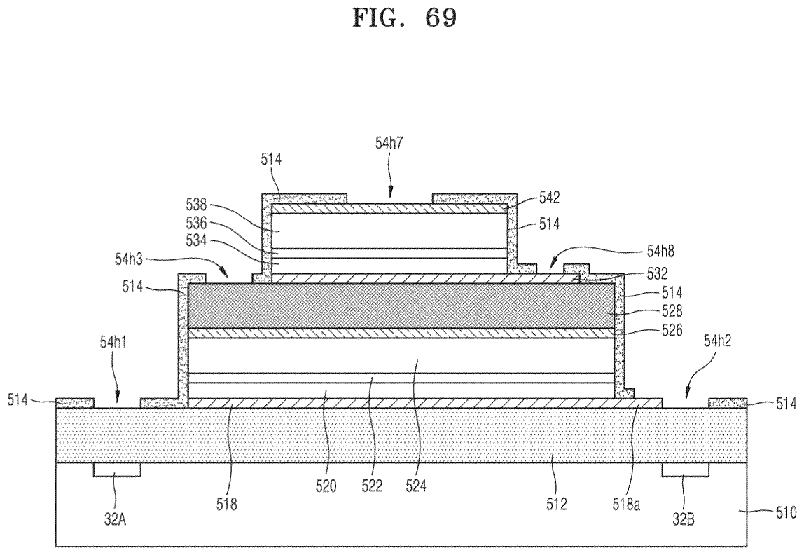

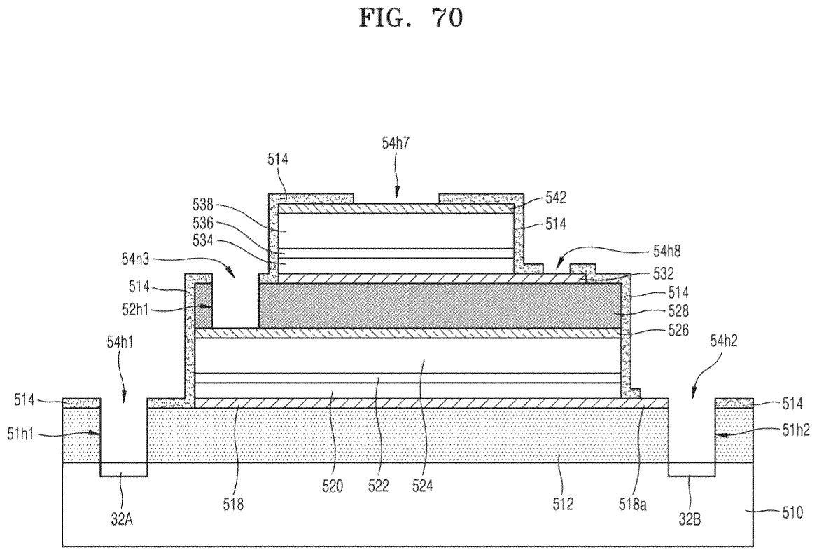

Next, as shown in FIG. 69, fourth to sixth through holes 54h1 to 54h3 and tenth and eleventh through holes 54h7 and 54h8 are formed in the second CBL 514. Next, the portion of the first attachment layer 512 exposed through the fourth through hole 54h1 and the portion exposed through the fifth through hole 54h2 are etched. Also, the second attachment layer 528 exposed through the sixth through hole 54h3 is etched. In the etching, the second CBL 514 may be used as an etch mask. The etching may be performed until the first and second electrode pad layers 32A and 32B and the first transparent electrode layer 526 are exposed. As a result of the etching, as shown in FIG. 70, a first contact hole 51h1 through which the first electrode pad layer 32A is exposed and a second contact hole 51h2 through which the second electrode pad layer 32B is exposed may be formed. A third through hole 52h1 through which the first transparent electrode layer 526 is exposed is formed in the second attachment layer 528.

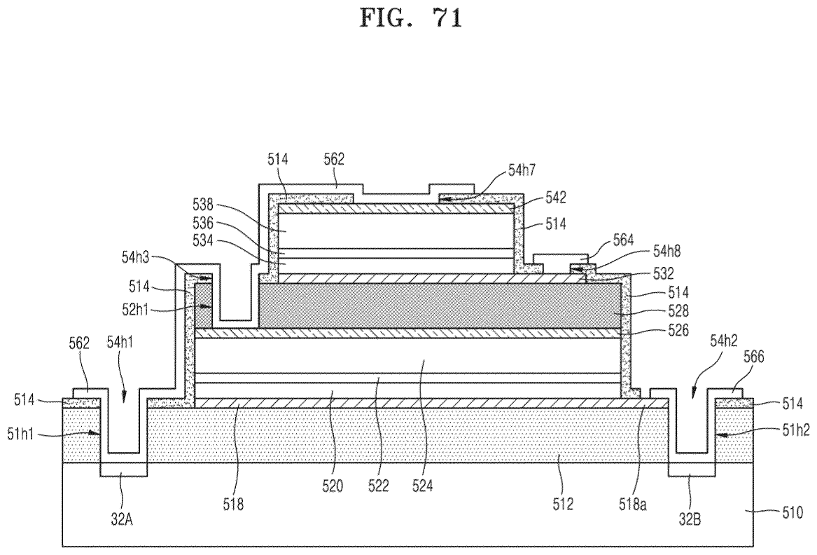

Next, as shown in FIG. 71, first to third interconnection electrode layers 562, 564, and 566 spaced apart from each other are formed on the second CBL 514. The first interconnection electrode layer 562 may be formed so that the first electrode pad layer 32A exposed through the first through hole 51h1, the first transparent electrode layer 526 exposed through the third through hole 52h1, and the second transparent electrode layer 542 exposed through the tenth through hole 54h7 are connected to each other. The first interconnection electrode layer 562 may be formed to be in contact with the upper surface of the first electrode pad layer 32A exposed through the first through hole 51h1, an exposed portion of the first transparent electrode layer 526 exposed through the third through hole 52h1, and an exposed portion of the second transparent electrode layer 542 exposed through the tenth through hole 54h7. For example, the first interconnection electrode layer 562 may be formed to cover entire surfaces exposed through the first through hole 51h1, entire surfaces exposed through the third through hole 52h1, and entire surfaces exposed through the tenth through hole 54h7, and may be in contact with the entire surfaces. The second interconnection electrode layer 564 may be formed to contact the second reflective layer 532 exposed through the eleventh through hole 54h8. The second interconnection electrode layer 564 may be formed to connect the second reflective layer 532 and another electrode pad layer provided on the second backplane 510 to each other. The third interconnection electrode layer 566 may be formed so that the second electrode pad layer 32B exposed through the second through hole 51h2 is connected to the expended portion 518a of the first reflective layer 518 exposed through the fifth through hole 54h2.

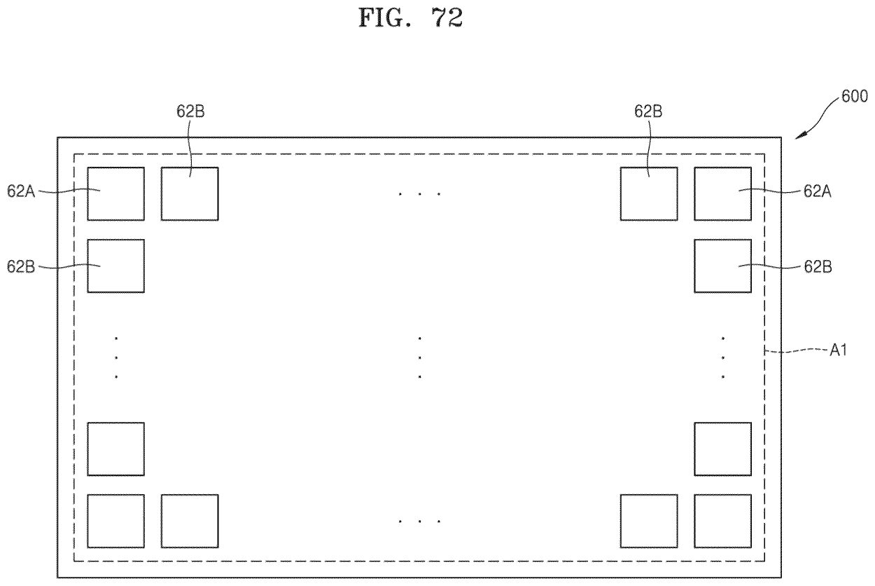

FIG. 72 is a schematic diagram showing an LED display 600 according to one or more embodiments. The LED display 600 may be expressed as an LED display device.

Referring to FIG. 72, the LED display 600 includes a plurality of pixels 62A and 62B arranged in a region A1 where an image is displayed. For example, the LED display 600 may include a display driver IC (DDI) to drive the plurality of pixels 62A and 62B under or around and adjacent to the display region A1.

The plurality of pixels 62A and 62B may be arranged at a given pitch in horizontal and vertical directions. For example, the plurality of pixels 62A and 62B may be arranged to form a matrix. For example, the horizontal and vertical pitches of the plurality of pixels 62A and 62B may be the same or different from each other.

The plurality of pixels 62A and 62B may include a plurality of first pixels 62A and a plurality of second pixels 62B. The plurality of first pixels 62A and the plurality of second pixels 62B may be arranged alternately in the horizontal and vertical directions. For example, the first pixel 62A may include a plurality of micro-LEDs. For example, the second pixel 62B may include a plurality of micro-LEDs. For example, the first and second pixels 62A and 62B may each include a plurality of vertically stacked micro-LEDs. For example, the configuration and layer structure of the plurality of micro-LEDs included in the first pixel 62A may be the same as or different from those of the second pixels 62A and 62B. For example, the first and second pixels 62A and 62B may include the same number of micro-LEDs, but the vertically stacked layer structure of the micro-LEDs in each of the pixels 62A and 62B may be the same or different. For example, in the first pixel 62A, three micro-LEDs may be vertically stacked in the order of R-LED, G-LED, and B-LED, and in the second pixel 62B, the three micro-LEDs may be vertically stacked in the same order as above, but may also be vertically stacked in a different order (e.g., G-LED, R-LED, B-LED order).

For example, the first pixel 62A may include one of the first to fourth micro-LED pixels 100, 200, 300, and 400 described above. For example, the second pixel 62A may include one of the first to fourth micro-LED pixels 100, 200, 300, and 400 described above.

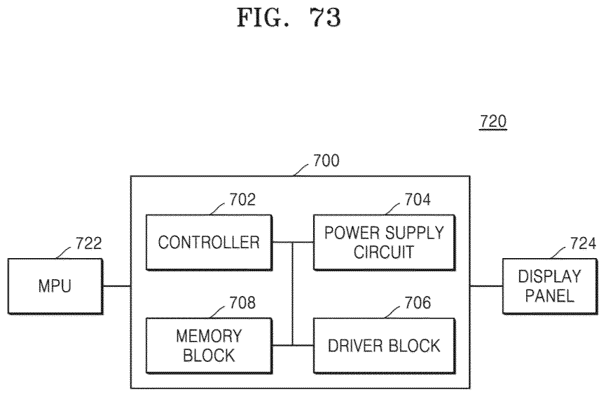

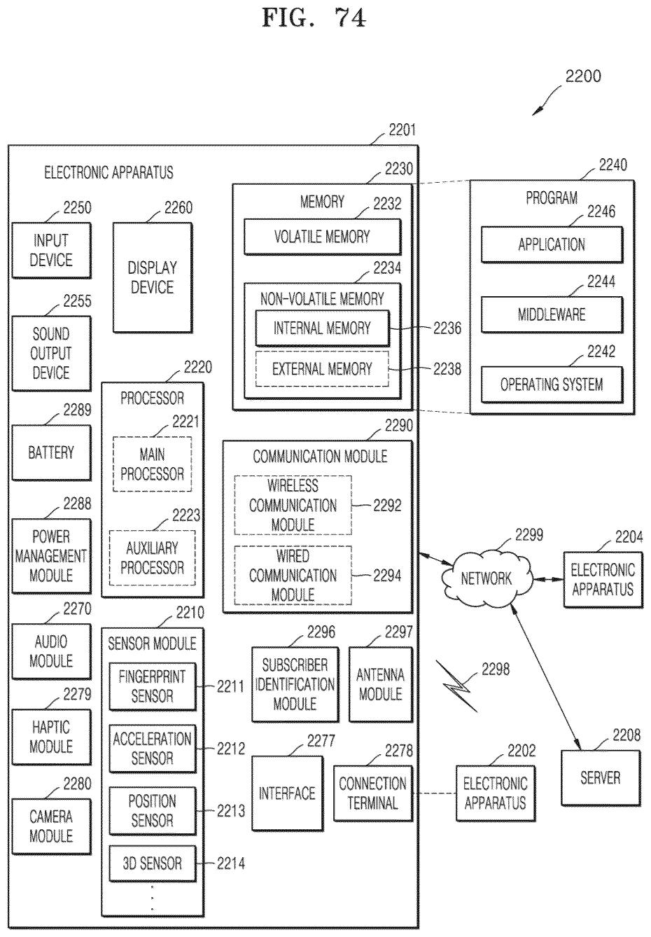

The vertical micro-LED pixels and/or LED displays according to one or more embodiments described above may be applied to various electronic apparatuses (e.g., light detection and ranging (LiDAR), mobile phones, recognition devices, various identification devices, radar, etc.) having an image display function, and FIGS. 73 and 74 show an example of the apparatus.

FIG. 73 is a schematic block diagram of a display driver IC (DDI) 700 and a display device 720 including the DDI 700 according to one or more embodiments.

Referring to FIG. 73, the DDI 700 may include a controller 702, a power supply circuit 704, a driver block 706, and a memory block 708. The controller 702 receives and decodes a command issued from a main processing unit (MPU) 722, and controls each block of the DDI 700 to implement an operation according to the command. Power supply circuit 704 generates a drive voltage in response to control of controller 702. The driver block 706 drives a display panel 724 using a driving voltage generated by the power supply circuit 704 in response to the control by the controller 702. For example, the display panel 724 may include a liquid crystal display panel, an organic light emitting device (OLED) display panel, a plasma display panel, or an LED display panel including a micro-LED pixels. For example, the pixel included in the LED display panel may include one of the first to fourth micro-LED pixels 100, 200, 300, and 400 described above.

The memory block 708 is a block that temporarily stores commands input to the controller 702 or control signals output from the controller 702, or stores necessary data, and may include a memory such as RAM or ROM.

For example, the display device 720 may include the LED display 600 of FIG. 72.

FIG. 74 is a block diagram showing a schematic configuration of an electronic apparatus 2201 according to one or more embodiments. Some of modules and devices included in the electronic apparatus 2201 may be omitted.

Referring to FIG. 74, in a network environment 2200, the electronic apparatus 2201 may communicate with another electronic apparatus 2202 through a first network 2298 (a short-range wireless communication network, etc.) or may communicate with another electronic apparatus 2204 and/or a server 2208 through a second network 2299 (a long-distance wireless communication network). The electronic apparatus 2201 may communicate with the electronic apparatus 2204 through the server 2208. The electronic apparatus 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297.

In the electronic apparatus 2201, some of these components (such as the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (a display, etc.).

The processor 2220 may execute software (such as a program 2240) to control one or a plurality of other components (hardware, software components, etc.) of the electronic apparatus 2201 connected to the processor 2220 and may perform various data processing or operations. As part of data processing or operations, the processor 2220 may load commands and/or data received from other components (the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (a central processing unit, an application processor, etc.) and an auxiliary processor 2223 (a graphics processing unit, an image signal processor, a sensor hub processor, a communication processor, etc.) that may be operated independently or together with the main processor 2221. The auxiliary processor 2223 uses less power than the main processor 2221 and may perform specialized functions.

The auxiliary processor 2223 may control functions and/or states related to some of the components (e.g., the display device 2260, the sensor module 2210, the communication module 2290) of the electronic apparatus 2201 instead of the main processor 2221 while the main processor 2221 is in an inactive state (sleep state), or together with the main processor 2221 while the main processor 2221 is in an active state (application execution state). The auxiliary processor 2223 (an image signal processor, a communication processor, etc.) may be implemented as a part of other functionally related components (the camera module 2280, the communication module 2290, etc.).

The memory 2230 may store various data required by components of the electronic apparatus 2201 (the processor 2220, the sensor module 2276, etc.). The data may include, for example, input data and/or output data for software (such as the program 2240) and instructions related to the command. The memory 2230 may include a volatile memory 2232 and/or a non-volatile memory 2234. The non-volatile memory 2234 may include an internal memory 2236 and an external memory 2238. The program 2240 may be stored as software in the memory 2230, and may include an operating system 2242, middleware 2244, and/or an application 2246.

The input device 2250 may receive commands and/or data to be used in a component (e.g., the processor 2220) of the electronic apparatus 2201 from the outside of the electronic apparatus 2201 (e.g., a user). The input device 2250 may include a microphone, a mouse, a keyboard, and/or a digital pen (such as a stylus pen).

The sound output device 2255 may output a sound signal to the outside of the electronic apparatus 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic apparatus 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.). For example, the display device 2260 may include one of the first to fourth micro-LED pixels 100, 200, 300, and 400 described above. For example, the display device 2260 may include the LED display 600 illustrated in FIG. 72 or the display device 720 illustrated in FIG. 73.

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic apparatus (e.g., the electronic apparatus 2202) directly or wirelessly connected to electronic apparatus 2201.

The sensor module 2210 may detect an operating state (power, temperature, etc.) of the electronic apparatus 2201 or an external environmental state (user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may sense a shape and movement of an object by irradiating a predetermined light to the object and analyzing light reflected from the object and may include a meta-optical device.

The interface 2277 may support one or more designated protocols that may be used by the electronic apparatus 2201 to connect directly or wirelessly with another electronic apparatus (e.g., the electronic apparatus 2102). The interface 2277 may include a High Definition Multimedia Interface (HDMI), a Universal Serial Bus (USB) interface, an SD card interface, and/or an audio interface.

The connection terminal 2278 may include a connector through which the electronic apparatus 2201 may be physically connected to another electronic apparatus (e.g., the electronic apparatus 2202). The connection terminal 2278 may include an HDMI connector, a USB connector, an SD card connector, and/or an audio connector (e.g., a headphone connector).

The haptic module 2279 may convert an electrical signal into a mechanical stimulus (vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly included in the camera module 2280 may collect light emitted from an object, which is an imaging target. For example, the camera module 2280 may be configured to capture at least one of a visible light image and an infrared image of the object. For example, the image signal processor included in the camera module 2280 may be responsible for converting a captured infrared image into a visible light image and superimposing the captured infrared image on the visible light image. For example, the camera module 2280 may include an infrared camera for recognizing an object or obtaining information about the object.

The power management module 2288 may manage power supplied to the electronic apparatus 2201. The power management module 2288 may be implemented as part of a Power Management Integrated Circuit (PMIC).

The battery 2289 may supply power to components of the electronic apparatus 2201. The battery 2289 may include a non-rechargeable primary cell, a rechargeable secondary cell, and/or a fuel cell.

The communication module 2290 may establish a direct (wired) communication channel and/or wireless communication channel between the electronic apparatus 2201 and other electronic apparatuses (the electronic apparatus 2202, an electronic apparatus 2204, server 2208, etc.) and may support the performance of communication through the established communication channels. The communication module 2290 may include one or more communication processors that operate independently of the processor 2220 (e.g., an application processor) and support direct communication and/or wireless communication. The communication module 2290 may include a wireless communication module 2292 (a cellular communication module, a short-range wireless communication module, a Global Navigation Satellite System (GNSS, etc.) communication module) and/or a wired communication module 2294 (a Local Area Network (LAN) communication module, or a power line communication module, etc.). Among these communication modules, a corresponding communication module may communicate with other electronic apparatuses through the first network 2298 (a short-range communication network, such as Bluetooth, WiFi Direct, or Infrared Data Association (IrDA)) or the second network 2299 (a telecommunication network, such as a cellular network, the Internet, or a computer network (LAN) and WAN, etc.). The various types of communication modules may be integrated into one component (a single chip, etc.) or implemented as a plurality of components (plural chips) separate from each other. For example, the chip of the communication module may include a chip for optical communication.

The wireless communication module 2292 may identify and authenticate the electronic apparatus 2201 within a communication network, such as the first network 2298 and/or the second network 2299 by using subscriber information (such as, International Mobile Subscriber Identifier (IMSI)) stored in a subscriber identification module 2296.

The antenna module 2297 may transmit or receive signals and/or power to and from the outside (other electronic apparatuses, etc.). The antenna may include a radiator having a conductive pattern formed on a substrate (PCB, etc.). The antenna module 2297 may include one or a plurality of antennas. When a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic apparatus through the selected antenna. In addition to the antenna, other components (an RFIC, etc.) may be included as a part of the antenna module 2297.

Some of the components are connected to each other through a communication method between peripheral devices (a bus, a General Purpose Input and Output (GPIO), a Serial Peripheral Interface (SPI), a Mobile Industry Processor Interface (MIPI), etc.), and may interchange signals (commands, data, etc.).

The command or data may be transmitted or received between the electronic apparatus 2201 and the external electronic apparatus 2204 through the server 2208 connected to the second network 2299. The other electronic apparatuses 2202 and 2204 may be the same or different types of electronic apparatus 2201. All or some of operations performed in the electronic apparatus 2201 may be performed in one or more of the other electronic apparatuses 2202, 2204, and 2208. For example, when the electronic apparatus 2201 needs to perform a function or service, the electronic apparatus 2201 may request one or more other electronic apparatuses to perform part or all function or service instead of executing the function or service itself. One or more other electronic apparatuses receiving the request may execute an additional function or service related to the request, and transmit a result of the execution to the electronic apparatus 2201. For this purpose, cloud computing, distributed computing, and/or client-server computing technologies may be used.

The illustrated micro-LED pixel including vertically stacked micro-LEDs is provided with a reflective layer below the micro-LED, so light emitted downward may be reflected upward. Accordingly, the amount of light emitted from the micro-LED pixel may be increased. For example, because a reflective layer is provided, the light efficiency or light emission efficiency of the micro-LED pixel may be increased. Accordingly, a display including the illustrated micro-LED pixels may provide brighter and clearer images. Also, the illustrated micro-LED pixel may have increased light efficiency compared to existing micro-LED pixels of the same size, and thus the same light efficiency may be obtained even in a smaller size than before. This suggests that when the illustrated micro-LED pixels are used, the pixel density of the display, that is, PPI (pixel per inch), may be increased.

In addition, in the illustrated micro-LED pixel, a plurality of vertically stacked micro-LEDs are formed such that, after separately forming a micro-LED layer including an electrode layer, the separately formed micro-LED layer is transferred onto a backplane using an attachment layer and a layer transferring method, and then the transferred micro-LED layer is patterned. Therefore, when the method of manufacturing the micro-LED pixel described above is used, bonding efficiency may be increased while simplifying the process and etch damage to the p-type compound semiconductor layer (e.g., p-GaN) may be prevented or minimized, thereby increasing the manufacturing efficiency of the micro-LED pixels.

Also, in the illustrated micro-LED pixel, a plurality of vertically stacked micro-LEDs and a backplane are connected using a transparent electrode film, and because this process is not complicated, mass production with improved efficiency is possible.

While many matters have been described in detail in the above description, they should be construed as illustrative of embodiments rather than to limit the scope of the present disclosure. Therefore, the scope of the disclosure should not be defined by the embodiments described above, but should be determined by the technical spirit described in the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A micro-light emitting diode (micro-LED) pixel comprising:
a first micro-LED;
a second micro-LED on the first micro-LED, a level of the first micro-LED and a level of the second micro-LED being different from each other in a vertical direction; and
a first reflective layer on the first micro-LED opposite to the second micro-LED, the first reflective layer being configured to reflect light incident from at least one of the first micro-LED and the second micro-LED in a direction opposite to the incident direction,
wherein on a plane from a top plan view, a size of the first micro-LED and a size of the second micro-LED are different from each other in a horizontal direction, and
wherein the first micro-LED and the second micro-LED are aligned in vertical direction corresponding to a main emission direction of light.

2. The micro-LED pixel of claim 1, further comprising:
a first attachment layer on the first reflective layer opposite to the first micro-LED;
a second attachment layer between the first micro-LED and the second micro-LED;
a second reflective layer between the second micro-LED and the second attachment layer, the second reflective layer being in contact with a p-type compound semiconductor layer included in the second micro-LED; and
a first transparent electrode layer between the second attachment layer and the first micro-LED, the first transparent electrode layer being in contact with an n-type compound semiconductor layer included in the first micro-LED.

3. The micro-LED pixel of claim 2, wherein at least one of a thickness of the first attachment layer and a thickness of the second attachment layer in the vertical direction is greater than or equal to one of a thickness of the first micro-LED and a thickness of the second micro-LED or is greater than the thickness of the thickest layer among the layers included in the first micro-LED and the second micro-LED.

4. The micro-LED pixel of claim 3, further comprising:
a backplane comprising transistors corresponding to each of the first micro-LED and the second micro-LED,
wherein the backplane further comprises electrode pad layers spaced apart from each other and respectively connected to the transistors,
wherein the first attachment layer comprises through holes through which the electrode pad layers are exposed,
wherein the second attachment layer comprises a through hole through which the first transparent electrode layer is exposed,
wherein the first reflective layer is in contact with the p-type compound semiconductor layer included in the first micro-LED, and
wherein the micro-LED pixel further comprises:
a first interconnection electrode layer connecting a portion of the first transparent electrode layer exposed through the second attachment layer, a grounded first electrode pad layer among the electrode pad layers, and an n-type compound semiconductor layer of the second micro-LED;
a second interconnection electrode layer connecting a second electrode pad layer, connected to a transistor corresponding to the first micro-LED, among the electrode pad layers to the first reflective layer; and
a third interconnection electrode layer connecting a third electrode pad layer, connected to a transistor corresponding to the second micro-LED, among the electrode pad layers to the second reflective layer,
wherein the first interconnection electrode layer, the second interconnection electrode layer, and the third interconnection electrode layer are spaced apart from each other, and each of the first interconnection electrode layer, the second interconnection electrode layer, and the third interconnection electrode layer is a single layer and continuous transparent electrode film, and
wherein the third interconnection electrode layer is spaced apart from a side surface of the first micro-LED and a side surface of the second micro-LED.

5. The micro-LED pixel of claim 3, further comprising:
a third micro-LED at a level that is higher position than the level of the second micro-LED in the vertical direction;
a third attachment layer between the third micro-LED and the second micro-LED;
a third reflective layer between the third micro-LED and the third attachment layer; and
a second transparent electrode layer between the third attachment layer and the second micro-LED,
wherein a thickness of the third attachment layer is same as the thickness of the first attachment layer or the thickness of the second attachment layer,
wherein the micro-LED pixel further comprises an interconnection electrode layer configured to connect the first micro-LED and the third micro-LED to a power source among the first micro-LED, the second micro-LED, and the third micro-LED, and
wherein the interconnection electrode layer is a transparent electrode film that is continuous without disconnection.

6. The micro-LED pixel of claim 5, wherein a length of the second reflective layer, a length of the second micro-LED, a length of the second transparent electrode layer, a length of the third attachment layer, and a length of the third reflective layer in the horizontal direction are same, and a geometric shape and an area of the second reflective layer, a geometric shape and an area of the second micro-LED, a geometric shape and an area of the second transparent electrode layer, a geometric shape and an area of the third attachment layer, and a geometric shape and an area of the third reflective layer in the plane are same.

7. The micro-LED pixel of claim 2, further comprising:
a third micro-LED at a level that is higher than the level of the second micro-LED in the vertical direction, a size of the third micro-LED being different from the a size of the first micro-LED and a size of the second micro-LED on the plane;
a third attachment layer between the third micro-LED and the second micro-LED;
a third reflective layer between the third micro-LED and the third attachment layer, the third reflective layer being in contact with the p-type compound semiconductor layer included in the third micro-LED; and
a second transparent electrode layer between the third attachment layer and the second micro-LED,
wherein the first micro-LED, the second micro-LED, and the third micro-LED are sequentially stacked on a backplane in the vertical direction,
wherein, on the plane, a size of the first micro-LED is greater than a size of the second micro-LED, the size of the second micro-LED is greater than a size of the third micro-LED,
wherein the first reflective layer is in contact with the p-type compound semiconductor layer included in the first micro-LED, and
wherein the micro-LED pixel further comprises:
a first interconnection electrode layer configured to commonly connect n-type compound semiconductor layers of the first micro-LED, the second micro-LED, and the third micro-LED to a first terminal of a power source;
a second interconnection electrode layer connecting the first reflective layer to a second terminal of the power source;
a third interconnection electrode layer connecting the second reflective layer to the second terminal of the power source; and
a fourth interconnection electrode layer connecting the third reflective layer to the second terminal of the power source,
wherein each of the first interconnection electrode layer, the second interconnection electrode layer, the third interconnection electrode layer, and the fourth interconnection electrode layer is a single layer and a continuous transparent electrode film.

8. The micro-LED pixel of claim 1, further comprising:
a first attachment layer at a level lower than a level of the first reflective layer in the vertical direction;
a second attachment layer between the first micro-LED and the second micro-LED;
a second reflective layer between the second micro-LED and the second attachment layer, the second reflective layer being in contact with the n-type compound semiconductor layer included in the second micro-LED;
a first transparent electrode layer between the second attachment layer and the first micro-LED, the first transparent electrode layer being in contact with the p-type compound semiconductor layer included in the first micro-LED;
a third micro-LED at a level different from the level of first micro-LED and the level of the second micro-LED in the vertical direction and having a size different from the size of first micro-LED and the size of the second micro-LED on the plane;
a third attachment layer between the third micro-LED and the second micro-LED;
a third reflective layer between the third micro-LED and the third attachment layer, the third reflective layer being in contact with the n-type compound semiconductor layer included in the third micro-LED;
a second transparent electrode layer between the third attachment layer and the second micro-LED, the second transparent electrode layer being in contact with the p-type compound semiconductor layer included in the second micro-LED;
a third transparent electrode layer in contact with the p-type compound semiconductor layer included in the third micro-LED;
a first interconnection electrode layer commonly connecting n-type compound semiconductor layers of the first micro-LED, the second micro-LED, and the third micro-LED to a first terminal of a power source;
a second interconnection electrode layer connecting the p-type compound semiconductor layer included in the first micro-LED to a second terminal of the power source;
a third interconnection electrode layer connecting the p-type compound semiconductor layer included in the second micro-LED to the second terminal of the power source; and
a fourth interconnection electrode layer connecting the p-type compound semiconductor layer included in the third micro-LED to the second terminal of the power source,
wherein the first micro-LED, the second micro-LED, and the third micro-LED are sequentially stacked on a backplane,
wherein a size of the first micro-LED is greater than a size of the second micro-LED, and the side of the second micro-LED is greater than a size of the third micro-LED,
wherein the first reflective layer is in contact with the n-type compound semiconductor layer included in the first micro-LED, and
wherein each of the first interconnection electrode layer, the second interconnection electrode layer, the third interconnection electrode layer, and the fourth interconnection electrode layer is a transparent electrode film that is continuous without disconnection.

9. The micro-LED pixel of claim 8, wherein a horizontal length of the third attachment layer and a horizontal length of the third reflective layer are equal to each other and are less than a horizontal length of the second transparent electrode layer, an entire portion of third attachment layer is on the second transparent electrode layer, and the third attachment layer is spaced apart from the second micro-LED.

10. The micro-LED pixel of claim 8, wherein a horizontal length of the second attachment layer and a horizontal length of the second reflective layer are equal to each other and are less than a horizontal length of the first transparent electrode layer, an entire portion of second attachment layer is on the first transparent electrode layer, and the second attachment layer is spaced apart from the first micro-LED.

11. The micro-LED pixel of claim 8, wherein the horizontal length of the second attachment layer and the horizontal length of the second reflective layer are equal to each other and are greater than the horizontal length of the first transparent electrode layer, and the second attachment layer contacts the first micro-LED.

12. The micro-LED pixel of claim 8, wherein the horizontal length of the third attachment layer and the horizontal length of the third reflective layer are equal to each other and are greater than a horizontal length of the second transparent electrode layer, and the third attachment layer contacts the second micro-LED.

13. The micro-LED pixel of claim 12, wherein the horizontal length of the second attachment layer and the horizontal length of the second reflective layer are equal to each other and are greater than the horizontal length of the first transparent electrode layer, and the second attachment layer contacts the first micro-LED.

14. A method of manufacturing a micro-light emitting diode (micro-LED) pixel, the method comprising:
forming a first light emitting diode (LED) stack comprising a first reflective layer on a first substrate;
separating the first LED stack from the first substrate;
transferring the first LED stack onto a backplane;
forming a second LED stack on a second substrate;
separating the second LED stack from the second substrate;
transferring the separated second LED stack onto the first LED stack; and
patterning the transferred first LED stack and the second LED stack into first micro-LED and second micro-LED, respectively,
wherein the first LED stack is transferred such that the first reflective layer is between the backplane and the first micro-LED.

15. The method of claim 14, further comprising:
forming a third LED stack on a third substrate;
separating the third LED stack from the third substrate;
transferring the separated third LED stack onto the second LED stack; and
patterning the first LED stack, the second LED stack, and the third LED stack into the first micro-LED, the second micro-LED, and third micro-LED, respectively.

16. The method of claim 14, further comprising:
forming a second reflective layer on the second LED stack such that the second reflective layer is between the first micro-LED and the second micro-LED,
wherein the first reflective layer is formed to contact an n-type compound semiconductor layer included in the first micro-LED or a p-type compound semiconductor layer included in the first micro-LED, and
wherein the second reflective layer is formed to contact an n-type compound semiconductor layer included in the second micro-LED or a p-type compound semiconductor layer included in the second micro-LED.

17. The method of claim 15, further comprising:
forming a second reflective layer on the second LED stack such that the second reflective layer is between the first micro-LED and the second micro-LED; and
forming a third reflective layer on the third LED stack such that the third reflective layer is between the second micro-LED and the third micro-LED,
wherein the first reflective layer is formed to contact the n-type compound semiconductor layer included in the first micro-LED or the p-type compound semiconductor layer included in the first micro-LED,
wherein the second reflective layer is formed to contact the n-type compound semiconductor layer included in the second micro-LED or the p-type compound semiconductor layer included in the second micro-LED, and
wherein the third reflective layer is formed to contact an n-type compound semiconductor layer included in the third micro-LED or a p-type compound semiconductor layer included in the third micro-LED.

18. The method of claim 16, further comprising:
forming an interconnection electrode layer connecting each of the first micro-LED, the second micro-LED, and the third micro-LED and the backplane,
wherein the interconnection electrode layer comprises:
a first interconnection electrode layer commonly connecting n-type compound semiconductor layers included in each of the first micro-LED, the second micro-LED, and the third micro-LED to a first electrode pad layer on the backplane; and
a plurality of second interconnection electrode layers connecting the p-type compound semiconductor layers included in each of the first micro-LED, the second micro-LED, and the third micro-LED to different electrode pad layers on the backplane,
wherein the plurality of second interconnection electrode layers are spaced apart from each other and spaced apart from the first interconnection electrode layer, and
wherein each of the first interconnection electrode layer and the second interconnection electrode layer is a transparent electrode film that is continuous without disconnection.

19. The method of claim 17, wherein the first reflective layer is in contact with the n-type compound semiconductor layer included in the first micro-LED, the second reflective layer is in contact with the n-type compound semiconductor layer included in the second micro-LED, and the third reflective layer is in contact with the n-type compound semiconductor layer included in the third micro-LED, and
wherein the method further comprises:
forming a first attachment layer between the first reflective layer and the backplane;
forming a first transparent electrode layer and a second attachment layer between the first micro-LED and the second reflective layer; and
forming a second transparent electrode layer and a third attachment layer between the second micro-LED and the third reflective layer,
wherein the method further comprises:
at least one method among forming the first transparent electrode layer and the second attachment layer sequentially on the first micro-LED or forming both the first transparent electrode layer and the second attachment layer to contact the first micro-LED; and
forming the second transparent electrode layer and the third attachment layer sequentially on the second micro-LED or forming both the second transparent electrode layer and the third attachment layer to contact the second micro-LED.

20. An electronic apparatus comprising:
an image display device, the image display device comprising a plurality of pixels respectively comprising a plurality of vertically stacked micro light emitting diodes (micro-LEDs),
wherein each micro-LED of the plurality of micro-LEDs comprises:
a first micro-LED;
a second micro-LED at a level different from a level of the first micro-LED in a vertical direction; and
a first reflective layer at a level lower than the level of the first micro-LED and the level of the second micro-LED in the vertical direction, and
wherein on a plane from a top plan view, a size of the first micro-LED and a size of the second micro-LED are different from each other,
wherein the first micro-LED and the second micro-LED are aligned in the vertical direction corresponding to a main emission direction of light, and
wherein the first reflective layer is configured to reflect light incident from at least one of the first micro-LED and the second micro-LED in a direction opposite to the incident direction.
